(19) United States
(12) Patent Application Publication
(10) Pub. No.: US 2016/0233428 A1
(43) Pub. Date: Aug. 11, 2016

(54) ORGANIC LIGHT-EMITTING DEVICE

(71) Applicant: SAMSUNG DISPLAY CO., LTD., Yongin-City (KR)

(72) Inventors: Kwanghyun KIM, Yongin-City (KR); Sooyon KIM, Yongin-City (KR); Youngkook KIM, Yongin-City (KR); Seokhwan HWANG, Yongin-City (KR)

(21) Appl. No.: 14/789,498

(22) Filed: Jul. 1, 2015

(30) Foreign Application Priority Data
Feb. 11, 2015 (KR) 10-2015-0020963

(51) Int. Cl. H01L 51/00; C09K 11/02; C09K 11/06

(52) U.S. Cl. CPC H01L 51/0061; C09K 11/06; C09K 11/025; H01L 51/0058; H01L 51/006; H01L 51/5012

(57) ABSTRACT

An organic light-emitting device including a first electrode; a second electrode facing the first electrode; and an organic layer between the first electrode and the second electrode, the organic layer including an emission layer, wherein the organic layer includes a first compound and a second compound, the first compound includes a compound represented by the following Formula 1, and the second compound includes a compound represented by one of the following Formulae 2-1 to 2-4:

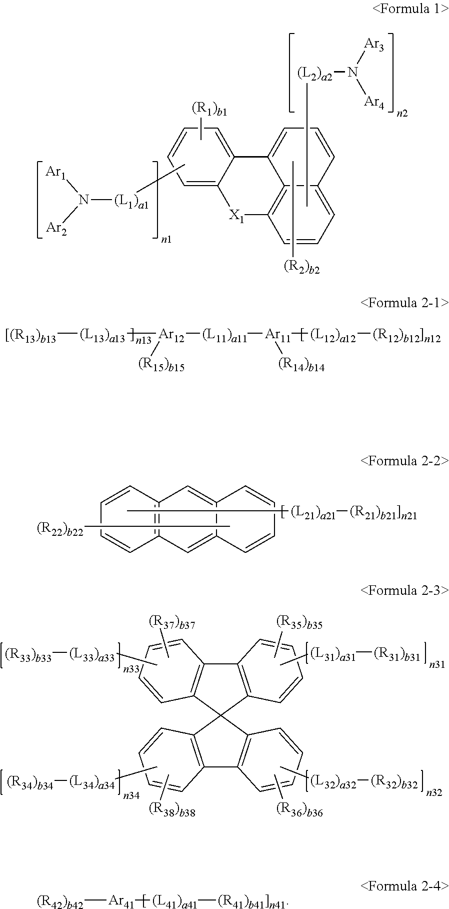

### CROSS-REFERENCE TO RELATED APPLICATION

Korean Patent Application No. 10-2015-0020963, filed on Feb. 11, 2015, in the Korean Intellectual Property Office, and entitled: “Organic Light-Emitting Device,” is incorporated by reference herein in its entirety.

### BACKGROUND

1. Field

Embodiments relate to an organic light-emitting device.

2. Description of the Related Art

Organic light-emitting devices (OLEDs) are self-emission devices that have wide viewing angles, high contrast ratios, and short response times. In addition, OLEDs exhibit excellent luminance, driving voltage, and response speed characteristics, and produce full-color images.

An OLED may include a first electrode disposed on a substrate, and a hole transport region, an emission layer, an electron transport region, and a second electrode, which are sequentially disposed on the first electrode. Holes provided from the first electrode may move toward the emission layer through the hole transport region, and electrons provided from the second electrode may move toward the emission layer through the electron transport region. The holes and the electrons are recombined in the emission layer to produce excitons. These excitons change from an excited state to a ground state to thereby generate light.

### SUMMARY

Embodiments are directed to an organic light-emitting device.

One or more exemplary embodiments include an organic light-emitting device having high efficiency and a long lifespan.

Additional aspects will be set forth in part in the description which follows and, in part, will be apparent from the description, or may be learned by practice of the presented embodiments.

According to one or more exemplary embodiments, an organic light-emitting device includes

a first electrode;

a second electrode facing the first electrode; and

an organic layer between the first electrode and the second electrode, wherein the organic layer includes an emission layer, and a first compound and a second compound;

wherein the first compound includes at least one compound represented by Formula 1, and the second compound includes at least one compound represented by Formulae 2-1 to 2-4:

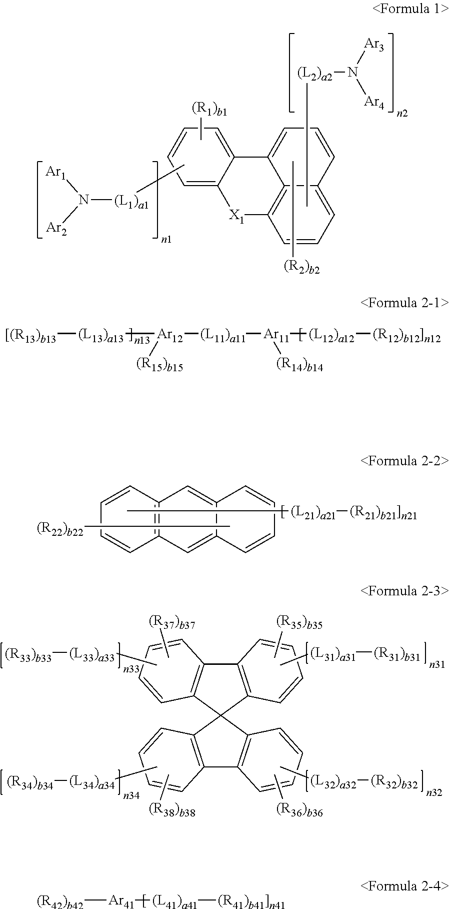

wherein in Formulae 1 and 2-1 to 2-4,

X₁ may be O or S;

Ar₁₁ and Ar₁₂ may be selected from a naphthalene group, an anthracene group, a triphenylene group, a pyrene group, a chrysene group, and a perylene group;

Ar₄₁ is a C₆-C₄₀ arylene;

L₁, L₂, L₁₁ to L₁₃, L₂₁, L₃₁ to L₃₄, and L₄₁ are each independently selected from a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed heteropolycyclic group;

a1, a2, a11 to a13, a21, a31 to a34, and a41 may be each independently selected from 0, 1, 2, and 3, when a1 is 2 or more, a plurality of L₁ may be identical or different, when a2 is 2 or more, a plurality of L₂ may be identical or different, a11 is 2 or more, a plurality of L₁₁ may be identical or different, when a12 is 2 or more, a plurality of L₁₂ may be identical or different, when a13 is 2 or more, a plurality of L₁₃ may be identical or different, when a21 is 2 or more, a plurality of L₂₁ may be identical or different, when a31 is 2 or more, a plurality of L₃₁ may be identical or different, when a32 is 2 or more, a plurality of L₃₂ may be identical or different, when a33 is 2 or more, a plurality of L₃₃ may be identical or different, and when a34 is 2 or more, a plurality of L₃₄ may be identical or different, when a41 is 2 or more, a plurality of L₄₁ may be identical or different;

Ar₁ to Ar₄ may be each independently selected from a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group;

R₁, R₂, R₁₂ to R₁₅, R₂₁, R₂₂, R₃₁ to R₃₈, R₄₁, and R₄₂ may be each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, and —Si(Q₁)(Q₂)(Q₃);

b1, b12, b13, b21, b31 to b38, b41, and b42 may be each independently 0, 1, 2, and 3, when b1 is 2 or more, a plurality of R₁ may be identical or different, when b12 is 2 or more, a plurality of R₁₂ may be identical or different, when b13 is 2 or more, a plurality of R₁₃ may be identical or different, when b31 is 2 or more, a plurality of R₃₁ may be identical or different, when b32 is 2 or more, a plurality of R₃₂ may be identical or different, when b33 is 2 or more, a plurality of R₃₃ may be identical or different, when b34 is 2 or more, a plurality of R₃₄ may be identical or different, when b35 is 2 or more, a plurality of R₃₅ may be identical or different, when b36 is 2 or more, a plurality of R₃₆ may be identical or different, when b37 is 2 or more, a plurality of R₃₇ may be identical or different, when b38 is 2 or more, a plurality of R₃₈ may be identical or different, when b41 is 2 or more, a plurality of R₄₁ may be identical or different, and when b42 is 2 or more, a plurality of R₄₂ may be identical or different;

b2 may be selected from 0, 1, 2, 3, 4 and 5, when b2 is 2 or more, a plurality of R₂ may be identical or different;

b14 and b15 may be each independently selected from 0, 1, 2, 3, 4, 5, and 6, when b14 is 2 or more, a plurality of R₁₄ may be identical or different, when b15 is 2 or more, a plurality of R₁₅ may be identical or different;

b22 may be selected from 0, 1, 2, 3, 4, 5, 6, 7, 8, and 9, when b22 is 2 or more, a plurality of R₂₂ may be identical or different;

n1, n2, n12, n13, n21, n31 to n34 may be each independently selected from 0, 1, 2, and 3, and n41 is selected from 0, 1, 2, 3, 4, 5, 6, 7, 8, and 9; and

at least one substituent of the substituted benzene ring, substituted naphthalene ring, substituted C₃-C₁₀ cycloalkylene group, substituted C₁-C₁₀ heterocycloalkylene group, substituted C₃-C₁₀ cycloalkenylene group, substituted C₁-C₁₀ heterocycloalkenylene group, substituted C₆-C₆₀ arylene group, substituted C₁-C₆₀ heteroarylene group, substituted divalent non-aromatic condensed polycyclic group, substituted divalent non-aromatic condensed heteropolycyclic group, substituted C₁-C₆₀ alkyl group, substituted C₂-C₆₀ alkenyl group, substituted C₂-C₆₀ alkynyl group, substituted C₁-C₆₀ alkoxy group, substituted C₃-C₁₀ cycloalkyl group, substituted C₁-C₁₀ heterocycloalkyl group, substituted C₃-C₁₀ cycloalkenyl group, substituted C₁-C₁₀ heterocycloalkenyl group, substituted C₆-C₆₀ aryl group, substituted C₆-C₆₀ aryloxy group, substituted C₆-C₆₀ arylthio group, substituted C₁-C₆₀ heteroaryl group, substituted monovalent non-aromatic condensed polycyclic group and substituted monovalent non-aromatic condensed heteropolycyclic group may be selected from

a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₂-C₆₀ alkenyl group, a C₂-C₆₀ alkynyl group, and a C₁-C₆₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group(aryloxy), a C₆-C₆₀ arylthio group(arylthio), a C₁-C₆₀ heteroaryl group, a monovalent non-aromatic condensed polycyclic group, a monovalent non-aromatic condensed heteropolycyclic group, —Si(Q₁₁)(Q₁₂)(Q₁₃), —B(Q₁₄)(Q₁₅), and —N(Q₁₆)(Q₁₇);

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₂₁)(Q₂₂)(Q₂₃), —B(Q₂₄)(Q₂₅), and —N(Q₂₆)(Q₂₇); and

—Si(Q₃₁)(Q₃₂)(Q₃₃), —B(Q₃₄)(Q₃₅), and —N(Q₃₆)(Q₃₇);

wherein Q₁₁ to Q₁₇, Q₂₁ to Q₂₇ and Q₃₁ to Q₃₇ may be each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group.

### BRIEF DESCRIPTION OF THE DRAWING

Features will be apparent to those of skill in the art by describing in detail exemplary embodiments with reference to the attached drawing in which:

FIG. 1 illustrates a schematic view of an organic light-emitting device according to an exemplary embodiment.

### DETAILED DESCRIPTION

Example embodiments will now be described more fully hereinafter with reference to the accompanying drawing; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing FIGURE, the dimensions of layers and regions may be exaggerated for clarity of illustration. Like reference numerals refer to like elements throughout.

As used herein, the term “and/or” includes any and all combinations of one or more of the associated listed items. Expressions such as “at least one of,” when preceding a list of elements, modify the entire list of elements and do not modify the individual elements of the list.

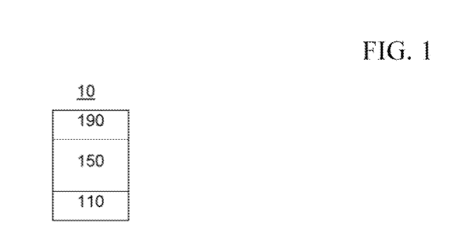

FIG. 1 illustrates a schematic cross-sectional view of an organic light-emitting device 10 according to an exemplary embodiment.

Referring to FIG. 1, the organic light-emitting device 10 according to the present embodiment may include a first electrode 110, a second electrode 190, and an organic layer 150 therebetween. A substrate may be additionally disposed under the first electrode 110 or above the second electrode 190. The substrate may be a glass substrate or transparent plastic substrate, each with excellent mechanical strength, thermal stability, transparency, surface smoothness, ease of handling, and water resistance.

The first electrode 110 may be formed by depositing or sputtering a material for forming the first electrode on the substrate. When the first electrode 110 is an anode, the material for the first electrode may be selected from materials with a high work function to facilitate hole injection. The first electrode 110 may be a reflective electrode, a semi-transmissive electrode, or a transmissive electrode. The material for the first electrode 110 may be a transparent and highly conductive material, and examples of such a material may include indium tin oxide (ITO), indium zinc oxide (IZO), tin oxide (SnO₂), and zinc oxide (ZnO). When the first electrode 110 is a semi-transmissive electrode or a reflective electrode, as a material for forming the first electrode 110, at least one selected from magnesium (Mg), aluminum (Al), aluminum-lithium (Al—Li), calcium (Ca), magnesium-indium (Mg—In), and magnesium-silver (Mg—Ag) may be used.

The first electrode 110 may have a single-layer structure, or a multi-layer structure including a plurality of layers. For example, the first electrode 110 may have a triple-layer structure of ITO/Ag/ITO.

The organic layer 150 may include an emission layer, and the organic layer 150 may be disposed on the first electrode 110. The organic layer 150 may include a hole transport region disposed between the first electrode 110 and the emission layer and an electron transport region disposed between the emission layer and the second electrode 190.

The organic layer 150 may include a first compound and a second compound. The first compound may include at least one compound represented by Formula 1, and the second compound may include at least one compound represented by one of Formulae 2-1 to 2-4.

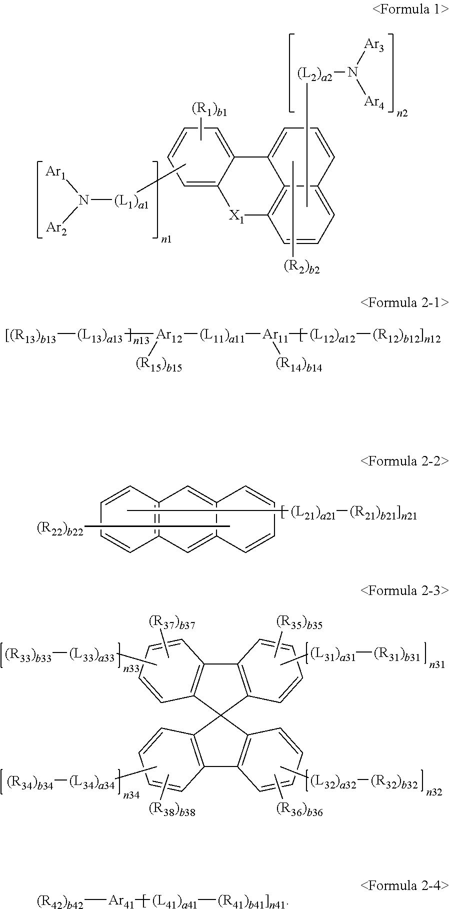

X₁ in Formula 1 may be, e.g., O or S. For example, X₁ in Formula 1 may be O.

Ar₁₁ and Ar₁₂ in Formula 2-1 may be selected from, e.g., a naphthalene group, an anthracene group, a triphenylene group, a pyrene group, a chrysene group, and a perylene group. For example, each of Ar₁₁ and Ar₁₂ may be a naphthalene group.

Ar₄₁ in Formula 2-4 may be, e.g., a C₆-C₄₀ arylene. For example, Ar₄₁ may be a benzene or a triphenylene.

L₁, L₂, L₁₁ to L₁₃, L₂₁, L₃₁ to L₃₄, and L₄₁ in Formulae 1 and 2-1 to 2-4 may each independently be selected from or include, e.g., a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed heteropolycyclic group.

For example, L₁, L₂, L₁₁ to L₁₃, L₂₁, L₃₁ to L₃₄, and L₄₁ in Formulae 1 and 2-1 to 2-4 may each independently be selected from:

a phenylene group, a pentalenylene group, an indenylene group, a naphthylene group, an azulenylene group, a heptalenylene group, an indacenylene group, an acenaphthylene group, a fluorenylene group, a spiro-fluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, a pentacenylene group, a rubicenylene group, a coronenylene group, an ovalenylene group, a pyrrolylene group, a thiophenylene group, a furanylene group, an imidazolylene group, a pyrazolylene group, a thiazolylene group, an isothiazolylene group, an oxazolylene group, an isoxazolylene group, a pyridinylene group, a pyrazinylene group, a pyrimidinylene group, a pyridazinylene group, an isoindolylene group, an indolylene group, an indazolylene group, a purinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a carbazolylene group, a phenanthridinylene group, an acridinylene group, a phenanthrolinylene group, a phenazinylene group, a benzoimidazolylene group, a benzofuranylene group, a benzothiophenylene group, an isobenzothiazolylene group, a benzoxazolylene group, an isobenzoxazolylene group, a triazolylene group, a tetrazolylene group, an oxadiazolylene group, a triazinylene group, a dibenzofuranylene group, a dibenzothiophenylene group, a benzocarbazolylene group, a dibenzocarbazolylene group, a thiadiazolylene group, an imidazopyridinylene group, and an imidazopyrimidinylene group; and

a phenylene group, a pentalenylene group, an indenylene group, a naphthylene group, an azulenylene group, a heptalenylene group, an indacenylene group, an acenaphthylene group, a fluorenylene group, a spiro-fluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, a pentacenylene group, a rubicenylene group, a coronenylene group, an ovalenylene group, a pyrrolylene group, a thiophenylene group, a furanylene group, an imidazolylene group, a pyrazolylene group, a thiazolylene group, an isothiazolylene group, an oxazolylene group, an isoxazolylene group, a pyridinylene group, a pyrazinylene group, a pyrimidinylene group, a pyridazinylene group, an isoindolylene group, an indolylene group, an indazolylene group, a purinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a carbazolylene group, a phenanthridinylene group, an acridinylene group, a phenanthrolinylene group, a phenazinylene group, a benzoimidazolylene group, a benzofuranylene group, a benzothiophenylene group, an isobenzothiazolylene group, a benzoxazolylene group, an isobenzoxazolylene group, a triazolylene group, a tetrazolylene group, an oxadiazolylene group, a triazinylene group, a dibenzofuranylene group, a dibenzothiophenylene group, a benzocarbazolylene group, a dibenzocarbazolylene group, a thiadiazolylene group, an imidazopyridinylene group, and an imidazopyrimidinylene group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazopyridinyl group, and an imidazopyrimidinyl group.

In an embodiment, L₁, L₂, L₁₁ to L₁₃, L₂₁, L₃₁ to L₃₄, and L₄₁ in Formulae 1 and 2-1 to 2-4 may each independently be a group represented by one of the following Formulae 3-1 to 3-22.

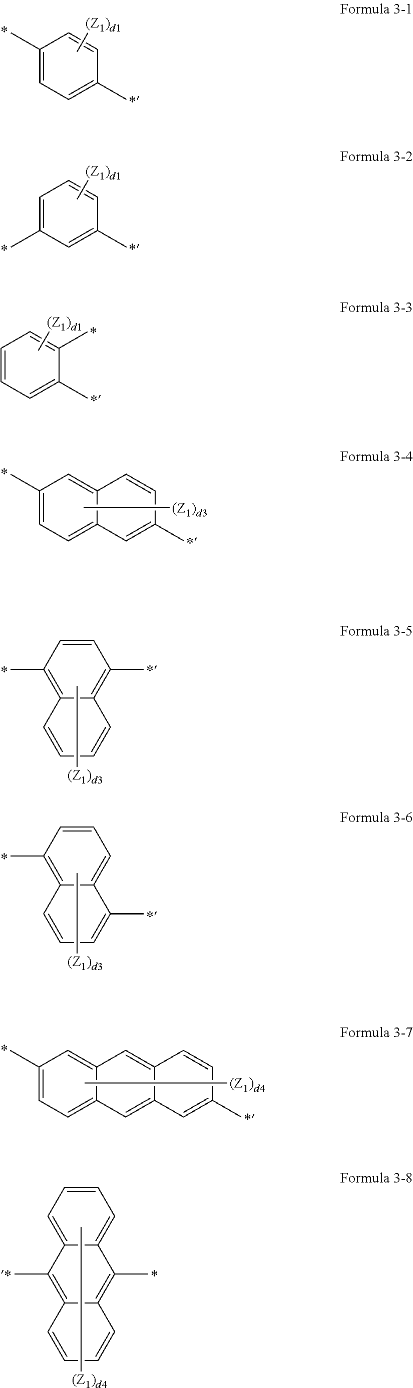

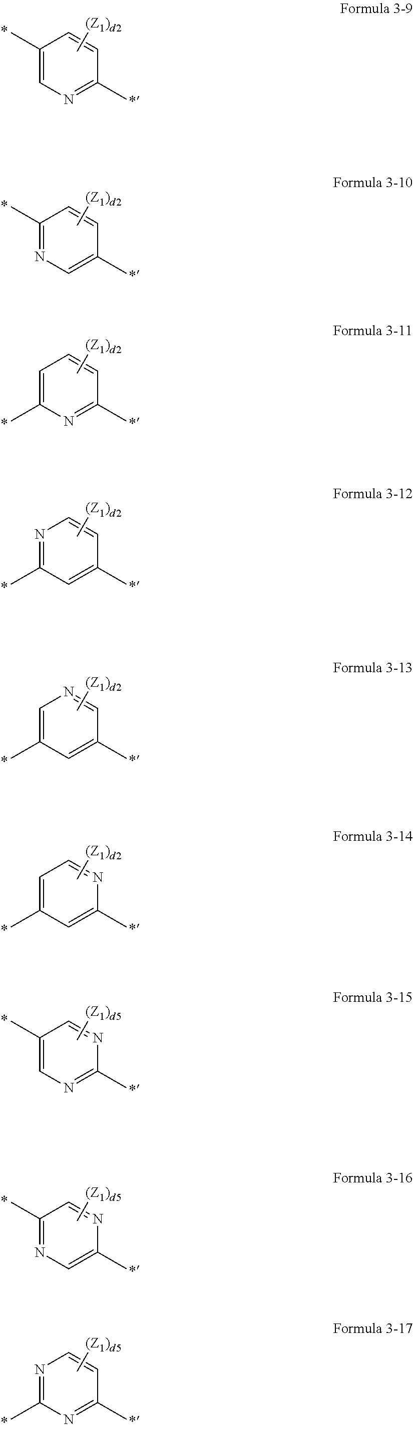

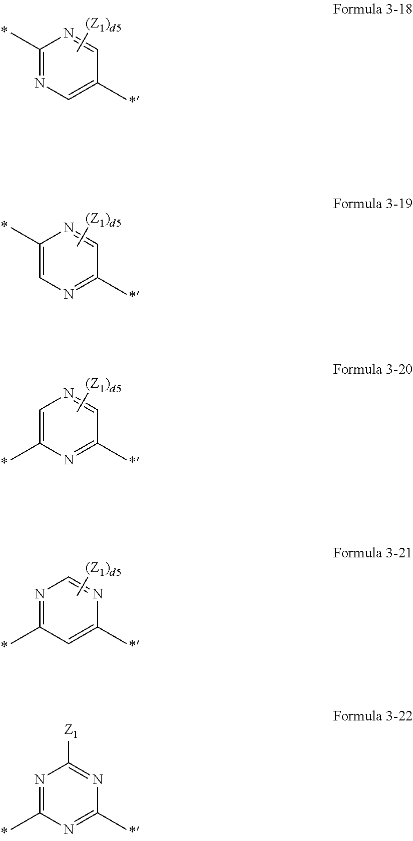

In Formulae 3-1 to 3-22,

Z₁ may be selected from a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group,

d1 may be an integer selected from 1 to 4, d2 may be an integer selected from 1 to 3, d3 may be an integer selected from 1 to 6, d4 may be an integer selected from 1 to 8, d5 may be an integer selected from 1 and 2, and each of * and *′ indicates a binding site to a neighboring atom.

For example, L₁, and L₂ in Formula 1 may each independently be a group represented by one of Formulae 3-1 to 3-14.

For example, L₁₁ to L₁₃, L₂₁, L₃₁ to L₃₄, and L₄₁ in Formulae 2-1 to 2-4 may each independently be a group represented by one of Formulae 3-1 to 3-8.

In some embodiments, L₁, L₂, L₁₁ to L₁₃, L₂₁, L₃₁ to L₃₄, and L₄₁ in Formulae 1 and 2-1 to 2-4 may each independently be a group represented by one of Formulae 4-1 to 4-6.

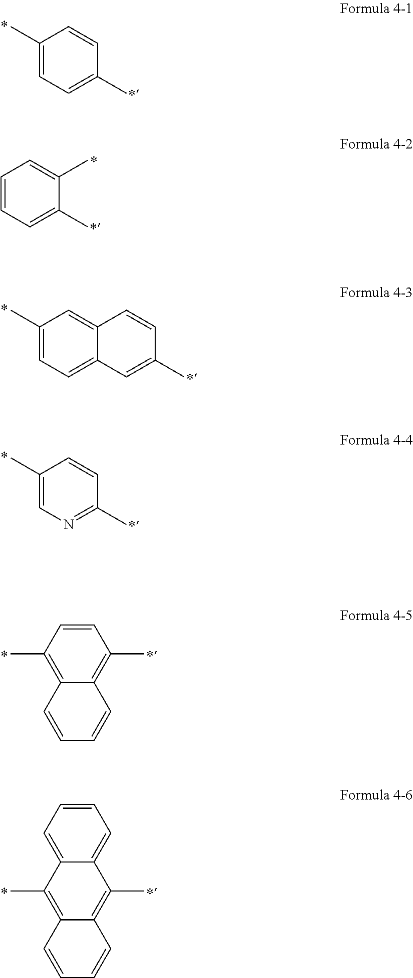

Each of * and *′ in Formulae 4-1 to 4-6 may be a binding site to a neighboring atom.

a1 in Formula 1 indicates the number of L₁(s), and may be selected from 0, 1, 2, and 3. When a1 is 0, *-(L₁)ₐ₁-*′ is a single bond. When a1 is 2 or more, a plurality of L₁(s) may be identical or different. a2, a11 to a13, a21, a31 to a34, and a41 in Formulae 1 and 2-1 to 2-4 may be understood by referring to the descriptions of a1 and the structures of Formulae 1 and 2-1 to 2-4.

In an embodiment, a1, a2, a11 to a13, a21, a31 to a34, and a41 in Formulae 1 and 2-1 to 2-4 may each independently be 0 or 1.

In some embodiments, in Formula 1, a1 may be 0 and a2 may be 0; a1 may be 1 and a2 may be 0; a1 may be 0 and a2 may be 1; or a1 may be 1 and a2 may be 1.

Ar₁ to Ar₄ in Formulae 1 and 2-1 to 2-4 may each independently be selected from or include, e.g., a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group.

In an embodiment, in Formulae 1 and 2-1 to 2-4, Ar₁ to Ar₄ may each independently be selected from a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a benzocarbazolyl group, a dibenzocarbazolyl group, a thiadiazolyl group, an imidazopyridinyl group, and an imidazopyrimidinyl group; and

a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a benzocarbazolyl group, a dibenzocarbazolyl group, a thiadiazolyl group, an imidazopyridinyl group, and an imidazopyrimidinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a benzocarbazolyl group, a dibenzocarbazolyl group, a thiadiazolyl group, an imidazopyridinyl group, an imidazopyrimidinyl group, and —Si(Q₃₁)(Q₃₂)(Q₃₃),

Q₃₁ to Q₃₃ may be each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group.

In some embodiments, Ar₁ to Ar₄ may each independently be a group represented by one of the following Formulae 5-1 to 5-20.

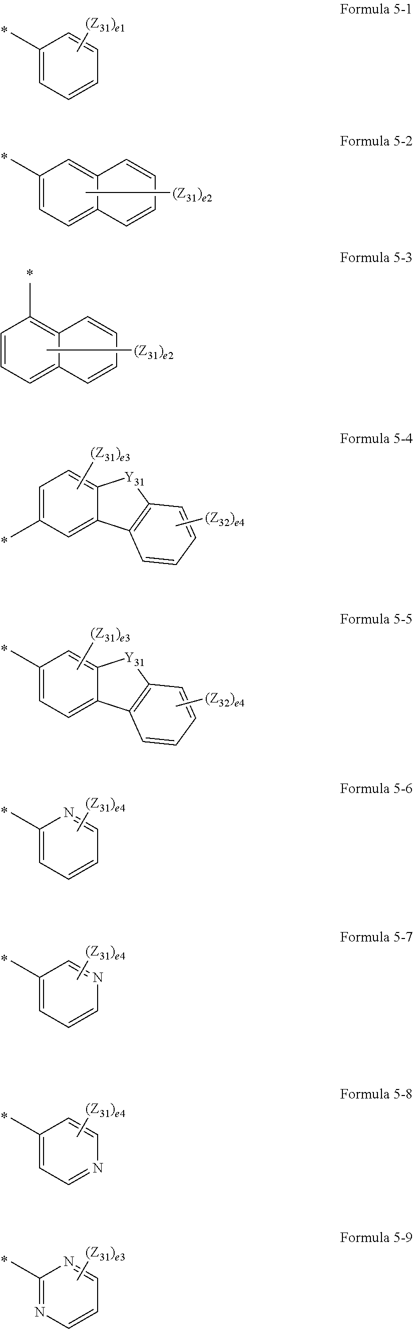

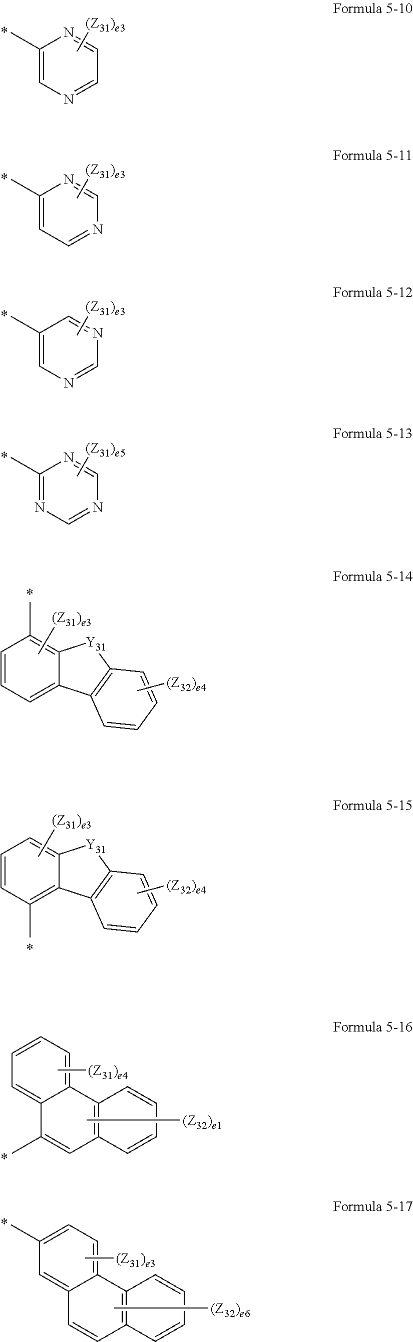

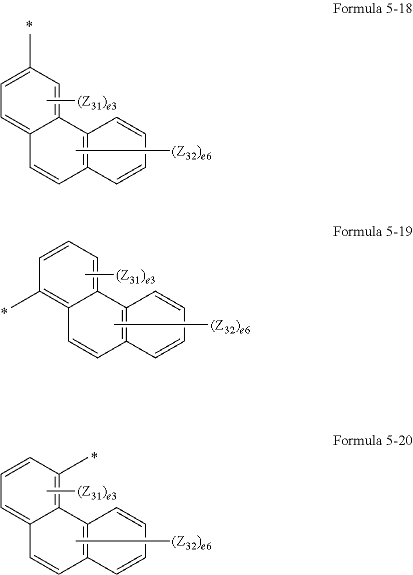

In Formulae 5-1 to 5-20,

Y₃₁ may be O, S, C(Z₃₃)(Z₃₄), or N(Z₃₅);

Z₃₁ to Z₃₅ may each independently be selected from:

a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, and a C₁-C₂₀ alkoxy group;

a C₁-C₂₀ alkyl group and C₁-C₂₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, and a phosphoric acid group or a salt thereof;

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a carbazolyl group, a benzocarbazolyl group, and a dibenzocarbazolyl group;

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a carbazolyl group, a benzocarbazolyl group, and a dibenzocarbazolyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, and a naphthyl group; and

—Si(Q₃₁)(Q₃₂)(Q₃₃),

wherein Q₃₁ to Q₃₃ may each independently be selected from a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, and a carbazolyl group;

e1 may be an integer selected from 1 to 5, e2 may be an integer selected from 1 to 7, e3 may be an integer selected from 1 to 3, e4 may be an integer selected from 1 to 4, e5 may be an integer selected from 1 and 2, e6 may be an integer selected from 1 to 6, and * may be a binding site to a neighboring atom.

For example, Z₃₁ to Z₃₅ in Formulae 5-1 to 5-20 may each independently be selected from a hydrogen, a deuterium, —F, —Cl, —Br, —I, a hydroxyl group, a cyano group, a nitro group, an amino group, an amidino group, a hydrazine group, a hydrazone group, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a carbazolyl group, a benzocarbazolyl group, a dibenzocarbazolyl group, and —Si(Q₃₁)(Q₃₂)(Q₃₃),

wherein Q₃₁ to Q₃₃ may each independently be selected from a C₁-C₂₀ alkyl group, a phenyl group, and a naphthyl group.

In some embodiments, Ar₁ to Ar₄ in Formulae 1 and 2-1 to 2-4 may each independently be a group represented by one of Formulae 6-1 to 6-21.

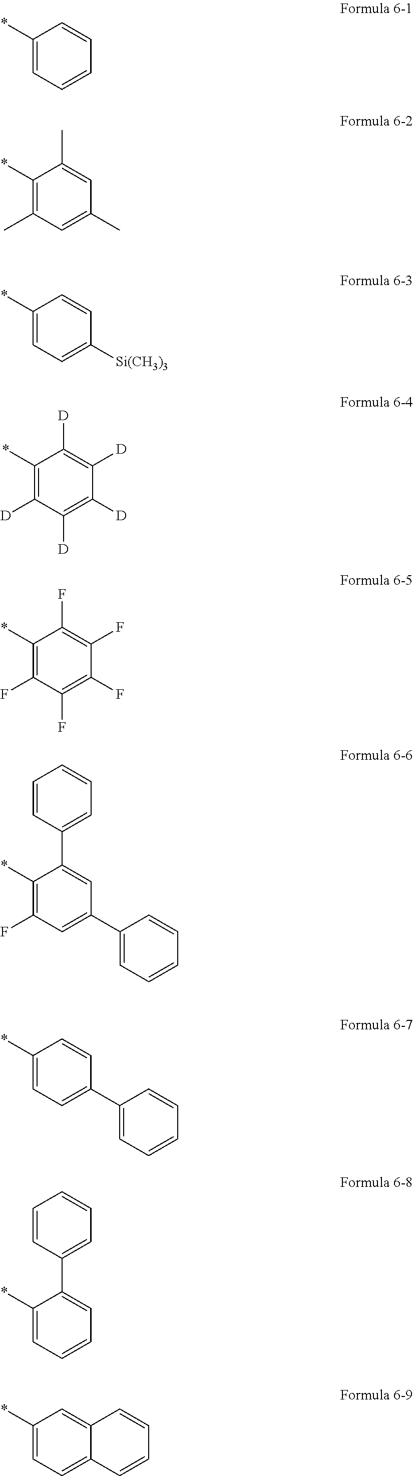

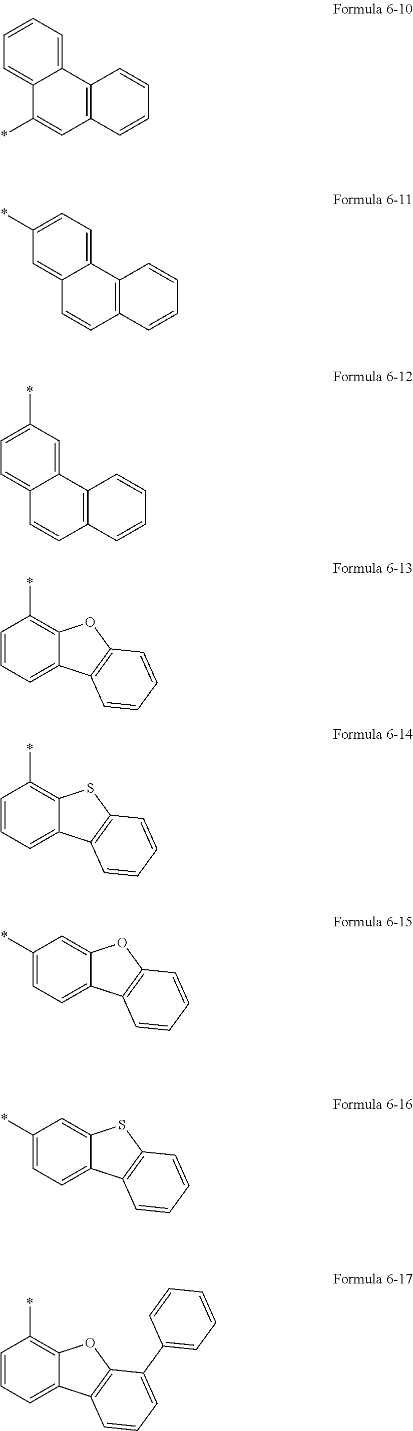

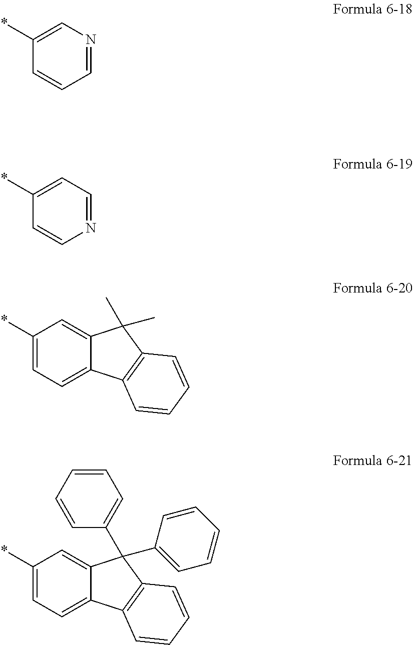 [SMILES: *c1cccnc1 ; *c1ccncc1 ; *c1ccc2c(c1)C(C)(C)c1ccccc1-2 ; *c1ccc2c(c1)C(c1ccccc1)(c1ccccc1)c1ccccc1-2]

* in Formulae 6-1 to 6-21 indicates a binding site to a neighboring atom.

R₁, R₂, R₁₂ to R₁₅, R₂₁, R₂₂, R₃₁ to R₃₈, R₄₁, and R₄₂ in Formulae 1 and 2-1 to 2-4 may each independently be selected from or include, e.g., a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, and —Si(Q₁)(Q₂)(Q₃). Q₁ to Q₃ are described in greater detail below.

In an embodiment, R₁ and R₂ in Formula 1 may each independently be selected from a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a phenyl group, a naphthyl group, and an anthracenyl group.

R₁₂ to R₁₅, R₂₁, R₂₂, R₃₅ to R₃₈, and R₄₂ in Formulae 2-1 to 2-4 may each independently be selected from:

a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₆₀ alkenyl group and a C₁-C₂₀ alkoxy group;

a C₁-C₂₀ alkyl group, a C₂-C₆₀ alkenyl group and C₁-C₂₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a phenyl group, a naphthyl group, a pyridinyl group, and a pyrimidinyl group;

a phenoxy group, a phenylthio group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, and an imidazopyrimidinyl group;

a phenoxy group, a phenylthio group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, and an imidazopyrimidinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —Si(Q₃₁)(Q₃₂)(Q₃₃), —B(Q₃₄)(Q₃₅), and N(Q₃₆)(Q₃₇); and

—Si(Q₁)(Q₂)(Q₃), —B(Q₄)(Q₅), and N(Q₆)(Q₇).

Q₁ to Q₇ and Q₃₁ to Q₃₇ may each independently be selected from a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, and a carbazolyl group.

In an embodiment, R₁₂ to R₁₅, R₂₁, R₂₂, R₃₅ to R₃₈, and R₄₂ in Formulae 2-1 to 2-4 may each independently be selected from a hydrogen, a deuterium, —F, —Cl, —Br, —I, a methyl group, an ethyl group, a propyl group, an iso-propyl group, a butyl group, an iso-butyl group, a sec-butyl group, a tert-butyl group, a methoxy group, an ethoxy group, an iso-a propoxy group, a butoxy group, an iso-butoxy group, a sec-butoxy group, a tert-butoxy group, —Si(CH₃)₃, —Si(Ph)₃, —N(Ph₂)₂, —B(Ph)₂, and a group represented by one of the following Formulae 7-1 to 7-21.

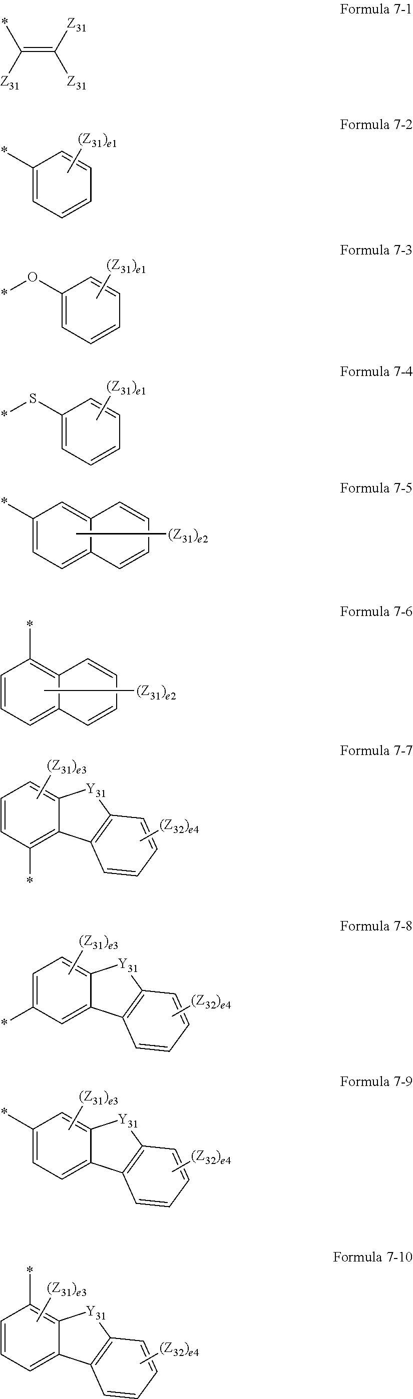

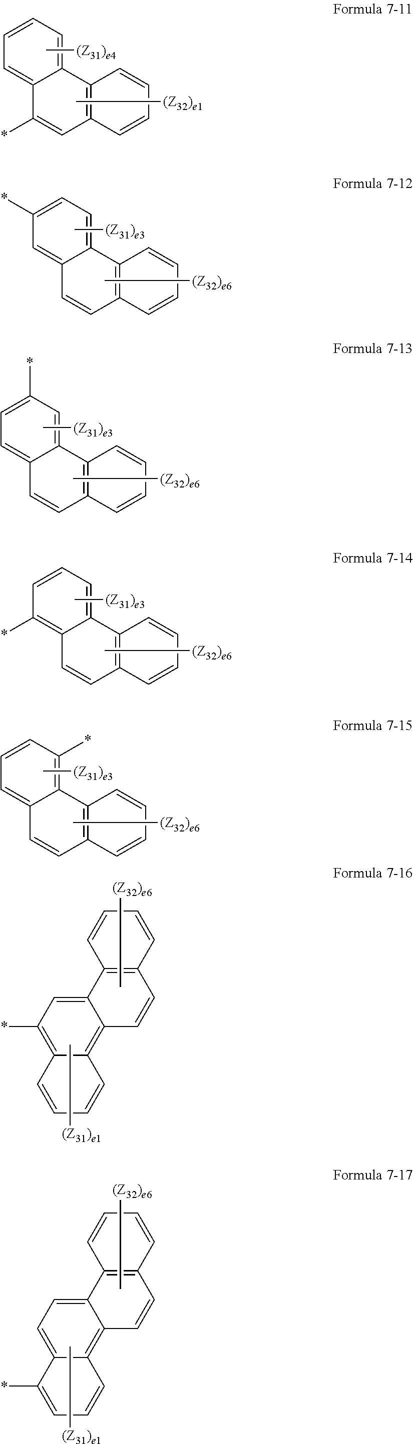

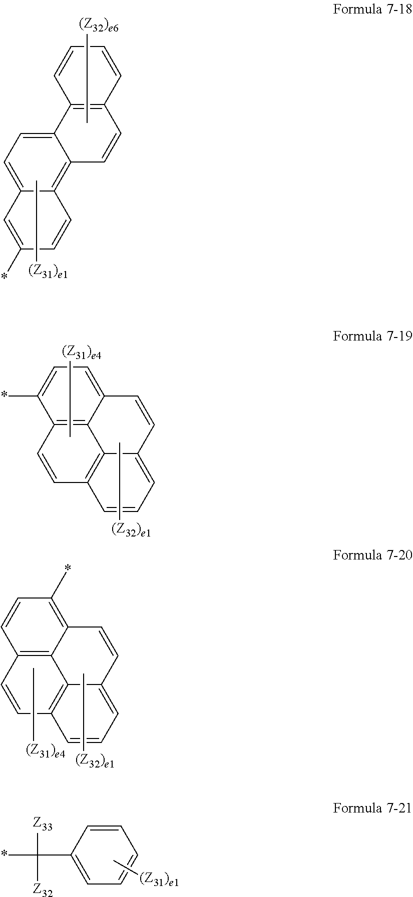

In Formulae 7-1 to 7-21,

Y₃₁ may be O, S, C(Z₃₄)(Z₃₅) or N(Z₃₆);

Z₃₁ to Z₃₆ may each independently be selected from:

a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, and a C₁-C₂₀ alkoxy group;

a C₁-C₂₀ alkyl group and C₁-C₂₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, and a phosphoric acid group or a salt thereof;

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a carbazolyl group, a benzocarbazolyl group, and a dibenzocarbazolyl group;

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a carbazolyl group, a benzocarbazolyl group, and a dibenzocarbazolyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, and a naphthyl group; and

—Si(Q₃₁)(Q₃₂)(Q₃₃), —B(Q₃₄)(Q₃₅), and N(Q₃₆)(Q₃₇),

wherein Q₃₁ to Q₃₇ may each independently be selected from a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, and a carbazolyl group;

e1 may be an integer selected from 1 to 5, e2 may be an integer selected from 1 to 7, e3 may be an integer selected from 1 to 3, e4 may be an integer selected from 1 to 4, e6 may be an integer selected from 1 to 6, and * may be a binding site to a neighboring atom.

For example, Z₃₁ to Z₃₆ in Formulae 7-1 to 7-21 may each independently be selected from a hydrogen, a deuterium, —F, —Cl, —Br, —I, a hydroxyl group, a cyano group, a nitro group, an amino group, an amidino group, a hydrazine group, a hydrazone group, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a carbazolyl group, a benzocarbazolyl group, a dibenzocarbazolyl group, —Si(Q₃₁)(Q₃₂)(Q₃₃), —B(Q₃₄)(Q₃₅), and N(Q₃₆)(Q₃₇),

wherein Q₃₁ to Q₃₇ may each independently be selected from a C₁-C₂₀ alkyl group, a phenyl group, and a naphthyl group.

In some embodiments, R₁₂ to R₁₅, R₂₁, R₂₂, R₃₅ to R₃₈, and R₄₂ may each independently be selected from a hydrogen, a deuterium, —F, —Cl, —Br, —I, a methyl group, an ethyl group, a propyl group, an iso-propyl group, a butyl group, an iso-butyl group, a sec-butyl group, a tert-butyl group, a methoxy group, an ethoxy group, an iso-a propoxy group, a butoxy group, an iso-butoxy group, a sec-butoxy group, a tert-butoxy group, —Si(CH₃)₃, —Si(Ph)₃, —N(Ph₂)₂, —B(Ph)₂, and a group represented by one of the following Formulae 8-1 to 8-18.

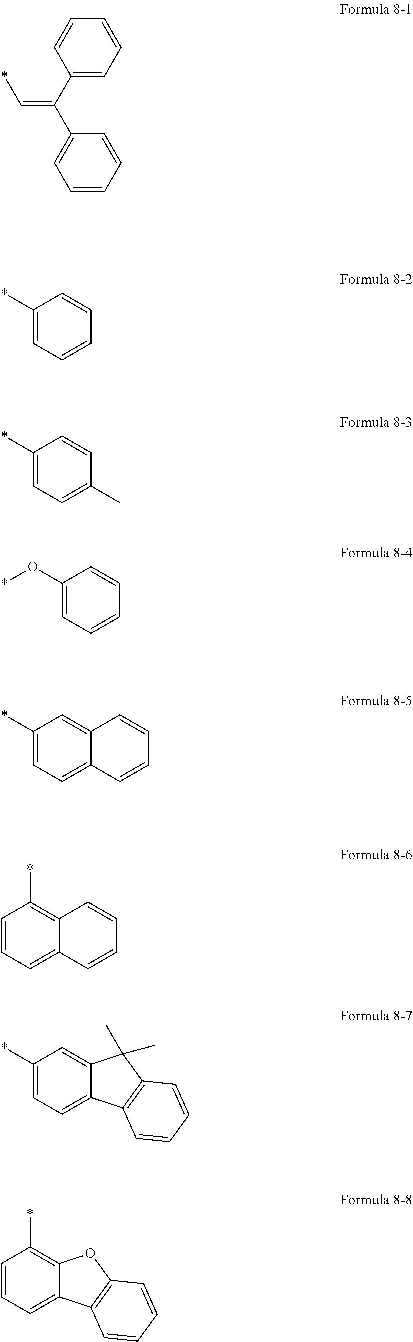

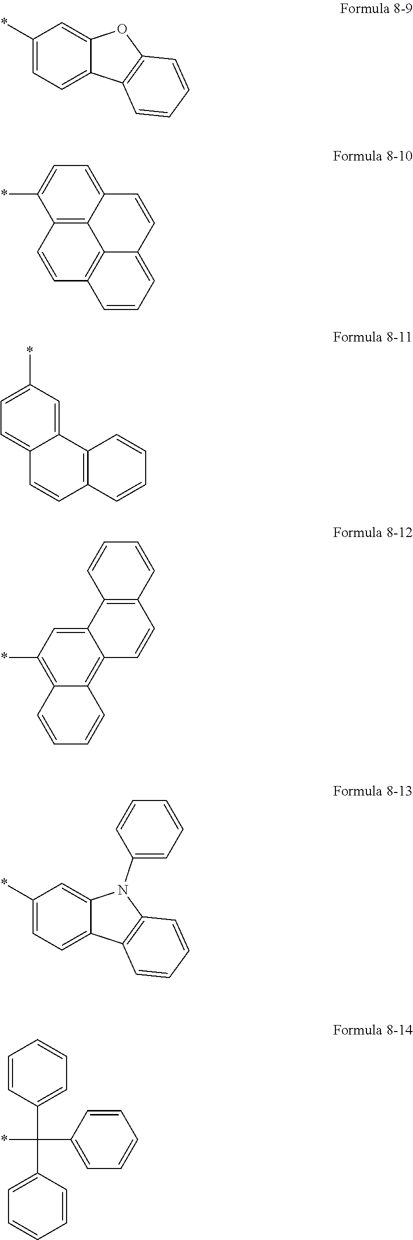

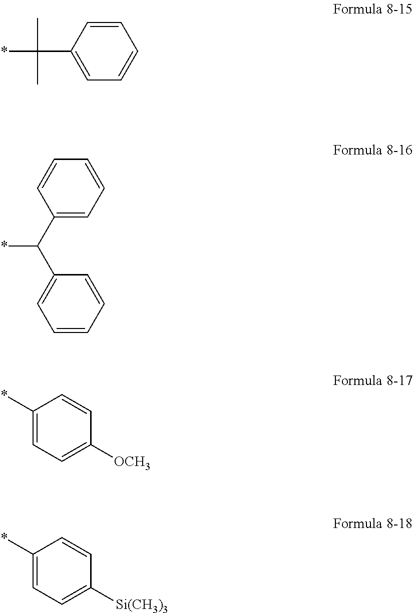

* in Formulae 8-1 to 8-18 indicates a binding site to a neighboring atom.

R₃₁ to R₃₄ and R₄₁ in Formulae 2-3 and 2-4 may each independently be selected from:

a hydrogen, a deuterium, —F, —Cl, —Br, —I, a hydroxyl group, a cyano group, a nitro group, an amino group, an amidino group, a hydrazine group, a hydrazone group, a C₁-C₂₀ alkyl group, a C₁-C₂₀ alkoxy group;

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, a triazinyl group, a benzocarbazolyl group, and a dibenzocarbazolyl group; and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, a triazinyl group, a benzocarbazolyl group, and a dibenzocarbazolyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, a triazinyl group, a benzocarbazolyl group, a dibenzocarbazolyl group, and —Si(Q₃₁)(Q₃₂)(Q₃₃),

wherein Q₃₁ to Q₃₃ may each independently be selected from a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group.

In an embodiment, R₃₁ to R₃₄ and R₄₁ in Formulae 2-3 and 2-4 may each independently be selected from a hydrogen, a deuterium, —F, —Cl, —Br, —I, a hydroxyl group, a cyano group, a nitro group, an amino group, an amidino group, a hydrazine group, a hydrazone group, a C₁-C₂₀ alkyl group, a C₁-C₂₀ alkoxy group, and a group represented by one of the following Formulae 9-1 to 9-16.

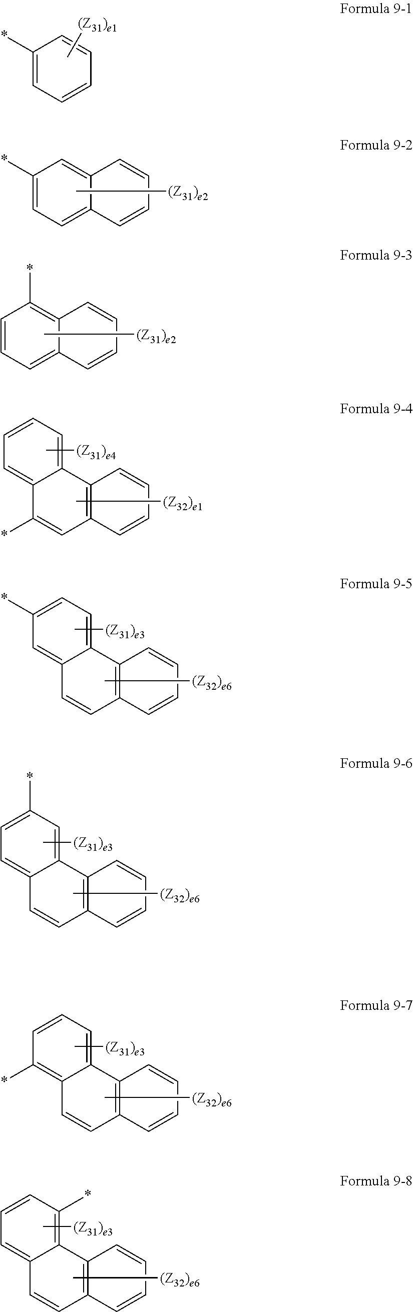

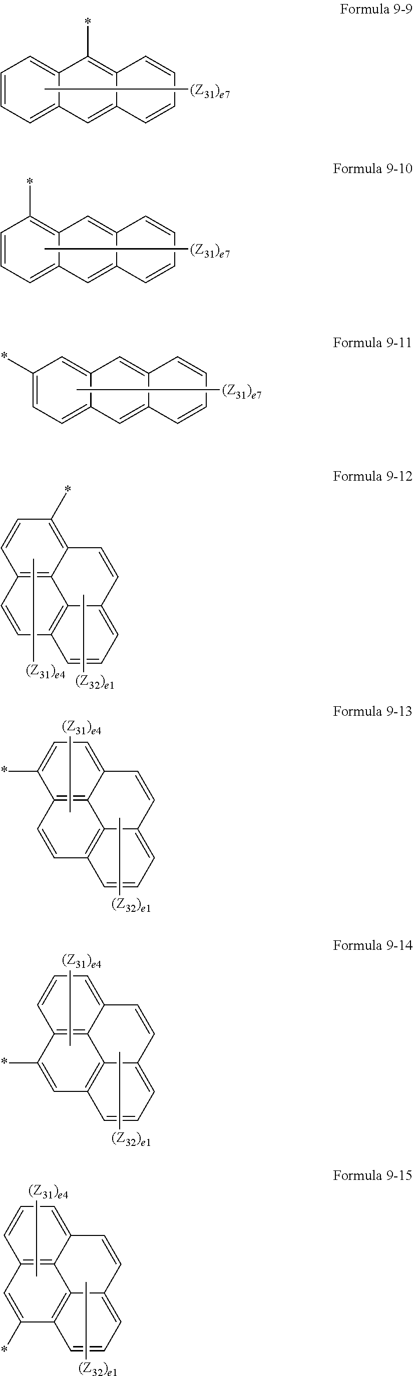

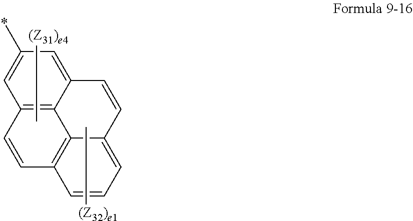

In Formulae 9-1 to 9-16,

Z₃₁ to Z₃₅ may each independently be selected from:

a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, and a C₁-C₂₀ alkoxy group;

a C₁-C₂₀ alkyl group and C₁-C₂₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, and a phosphoric acid group or a salt thereof;

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a carbazolyl group, a benzocarbazolyl group, and a dibenzocarbazolyl group;

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a carbazolyl group, a benzocarbazolyl group, and a dibenzocarbazolyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, and a naphthyl group; and

—Si(Q₃₁)(Q₃₂)(Q₃₃),

wherein Q₃₁ to Q₃₃ may each independently be selected from a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, and a carbazolyl group;

e1 may be an integer selected from 1 to 5, e2 may be an integer selected from 1 to 7, e3 may be an integer selected from 1 to 3, e4 may be an integer selected from 1 to 4, e6 may be an integer selected from 1 to 6, e7 may be an integer selected from 1 to 9, and * may be a binding site to a neighboring atom.

For example, Z₃₁ to Z₃₅ in Formulae 9-1 to 9-16 may each independently be selected from a hydrogen, a deuterium, —F, —Cl, —Br, —I, a hydroxyl group, a cyano group, a nitro group, an amino group, an amidino group, a hydrazine group, a hydrazone group, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a carbazolyl group, a benzocarbazolyl group, and a dibenzocarbazolyl group.

In some embodiments, R₃₁ to R₃₄ and R₄₁ in Formulae 2-3 and 2-4 may each independently be selected from a hydrogen, a deuterium, —F, —Cl, —Br, —I, a hydroxyl group, a cyano group, a nitro group, an amino group, an amidino group, a hydrazine group, a hydrazone group, a C₁-C₂₀ alkyl group, a C₁-C₂₀ alkoxy group, and a group represented by one of the following Formulae 10-1 to 10-10.

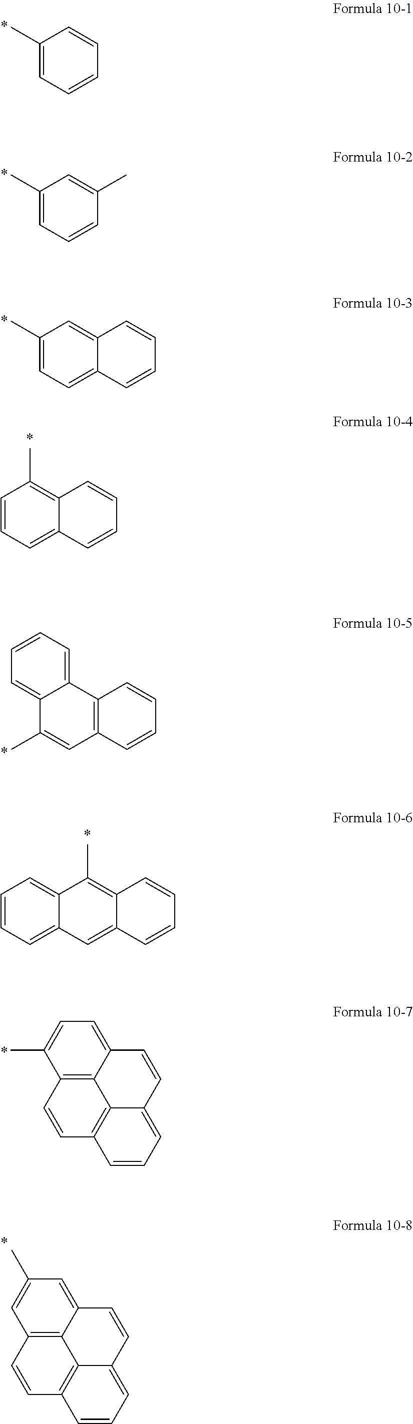

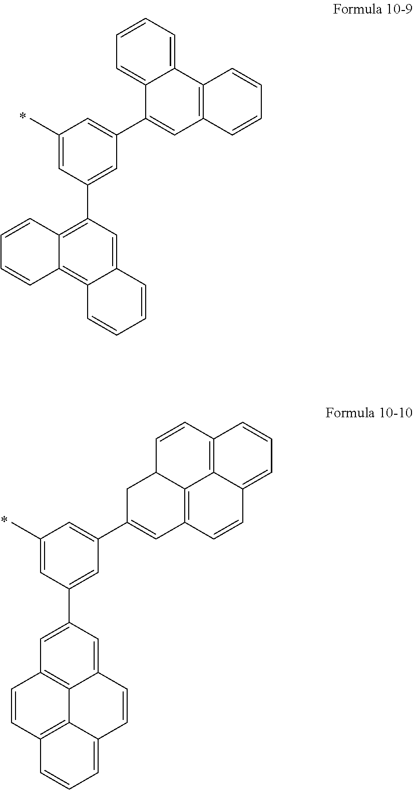

* in Formulae 10-1 to 10-10 indicates a binding site to a neighboring atom.

b1 in Formulae 1 and 2-1 to 2-4 indicates the number of R₁, and may be selected from 0, 1, 2, and 3. For example, b1 may be 0 or 1. In some embodiments, b1 may be 1. When b1 is 2 or more, 2 or more R may be identical or different. Descriptions of b2, b12 to b14, b21, b22, b31 to b38, b41, and b42 may be understood by referring to descriptions provided in connection with b1 and the structures of Formulae 1 and 2-1 to 2-4.

In an embodiment, b2 may be selected from 0, 1, 2, 3, 4, and 5. For example, b2 may be 0 or 1. In some embodiments, b2 may be 1.

In an embodiment, b14 and b15 may be each independently selected from 0, 1, 2, 3, 4, 5, and 6. For example, b14 and b15 may be 0 or 1. In some embodiments, b14 and b15 may be 1.

In an embodiment, b22 may be selected from 0, 1, 2, 3, 4, 5, 6, 7, 8, and 9. For example, b2 may be 0 or 1.

n1 in Formula 1 indicates the number of *-[(L₁)ₐ₁-(Ar₁)(Ar₂)], and may be selected from 0, 1, 2, and 3. For example, n12 may be 1 or 2. In some embodiments, n1 may be 1. When n1 is 2 or more, a plurality of *-[(L₁)ₐ₁-(Ar₁)(Ar₂)] may be identical or different. Descriptions of n2, n12, n13, and n31 to n34 in Formulae 1 and 2-1 to 2-4 may be understood by referring to descriptions provided in connection with n1 and the structures of Formulae 1 and 2-1 to 2-4.

n21 in Formula 2-2 indicates the number of *-[(L₂₁)₂₁-(R₂₁)_{b21}], and may be selected from 0, 1, 2, and 3. For example, n21 may be 1 or 2. In some embodiments, n21 may be 2.

n41 in Formula 2-4 indicates the number of *-[(L₄₁)₄₁-(R₄₁)_{b41}], and may be selected from 0, 1, 2, 3, 4, 5, 6, 7, 8, and 9. For example, n41 may be selected from 3, 4, 5, and 6. In some embodiments, n41 may be selected from 3, 4, and 6.

In some embodiments, the first compound may be represented by one of the following Formulae 1A to 1C, and the second compound may be represented by one of the following Formulae 2-1A to 2-1C, 2-2A, 2-3A, and 2-4A to 2-4D.

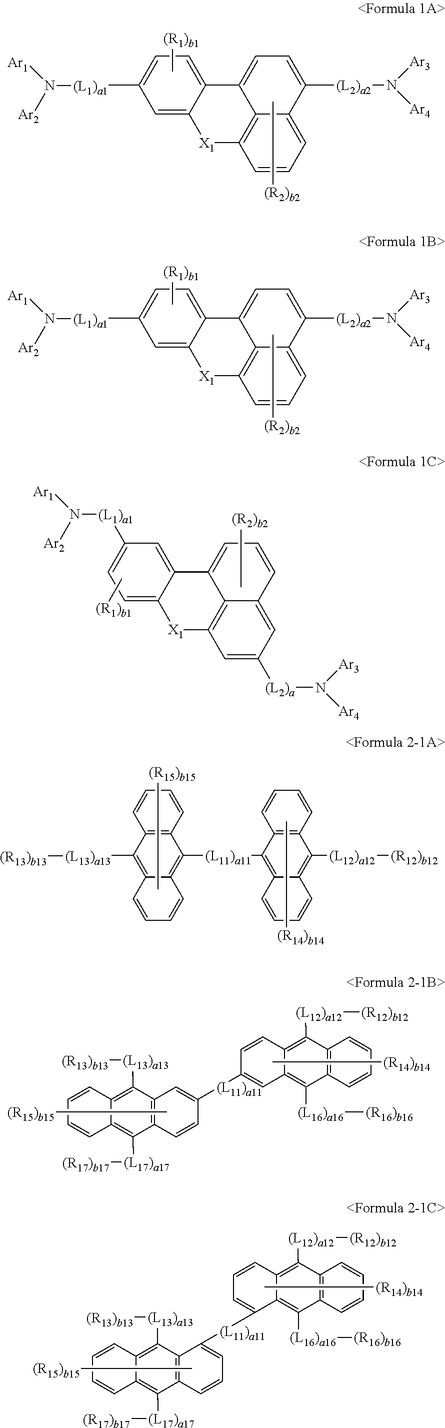

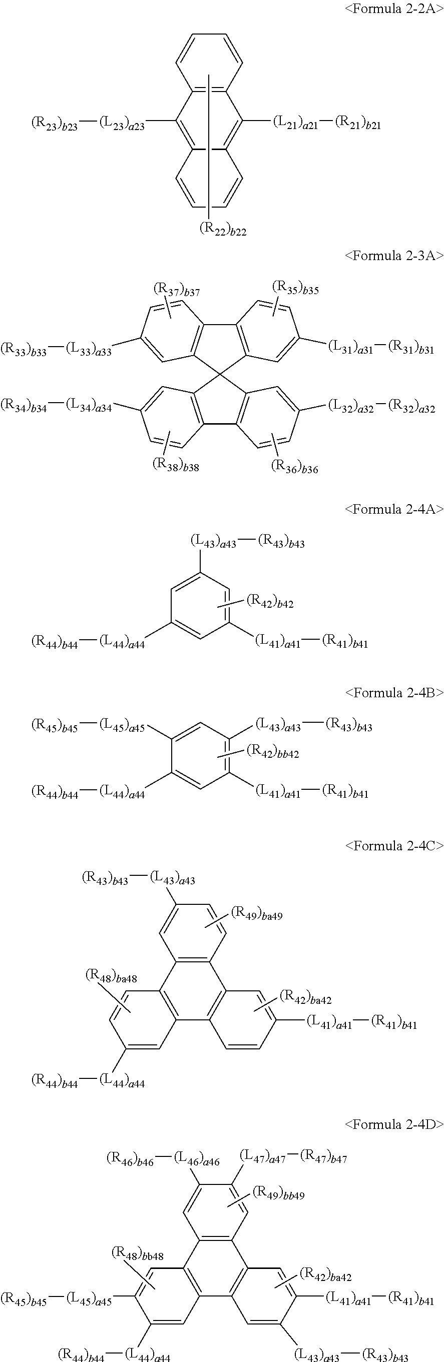

X₁, L₁, L₂, L₁₁ to L₁₃, L₂₁, L₃₁ to L₃₄, L₄₁, a1, a2, a11 to a13, a21, a31 to a34, a41, Ar₁ to Ar₄, R₁, R₂, R₁₂ to R₁₅, R₂₁, R₂₂, R₃₁ to R₃₈, R₄₁, R₄₂, b1, b2, b22, and b35 to b37 in Formulae 1A to 1C, 2-1A to 2-1C, 2-2A, 2-3A, and 2-4A to 2-4D are already described above.

L₁₆, L₁₇, and L₄₃ to L₄₇ may each independently be defined in the same manner as used to define L₁₁; and a16, a17, and a43 to a47 may each independently be defined in the same manner as used to define a11;

R₁₃, R₁₆ and/or R₁₇ may each independently be defined in the same manner as used to define R₁₁; and R₄₃ to R₄₇ may each independently be defined in the same manner as used to define R₄₁;

ba42, ba48, and ba49 may each independently be selected from 1, 2, and 3, and bb42, bb48, and bb49 may each independently be selected from 1 and 2.

In some embodiments, the first compound may be one of the following Compounds 1 to 83, and the second compound may be one of the following Compounds H-1 to H-65.

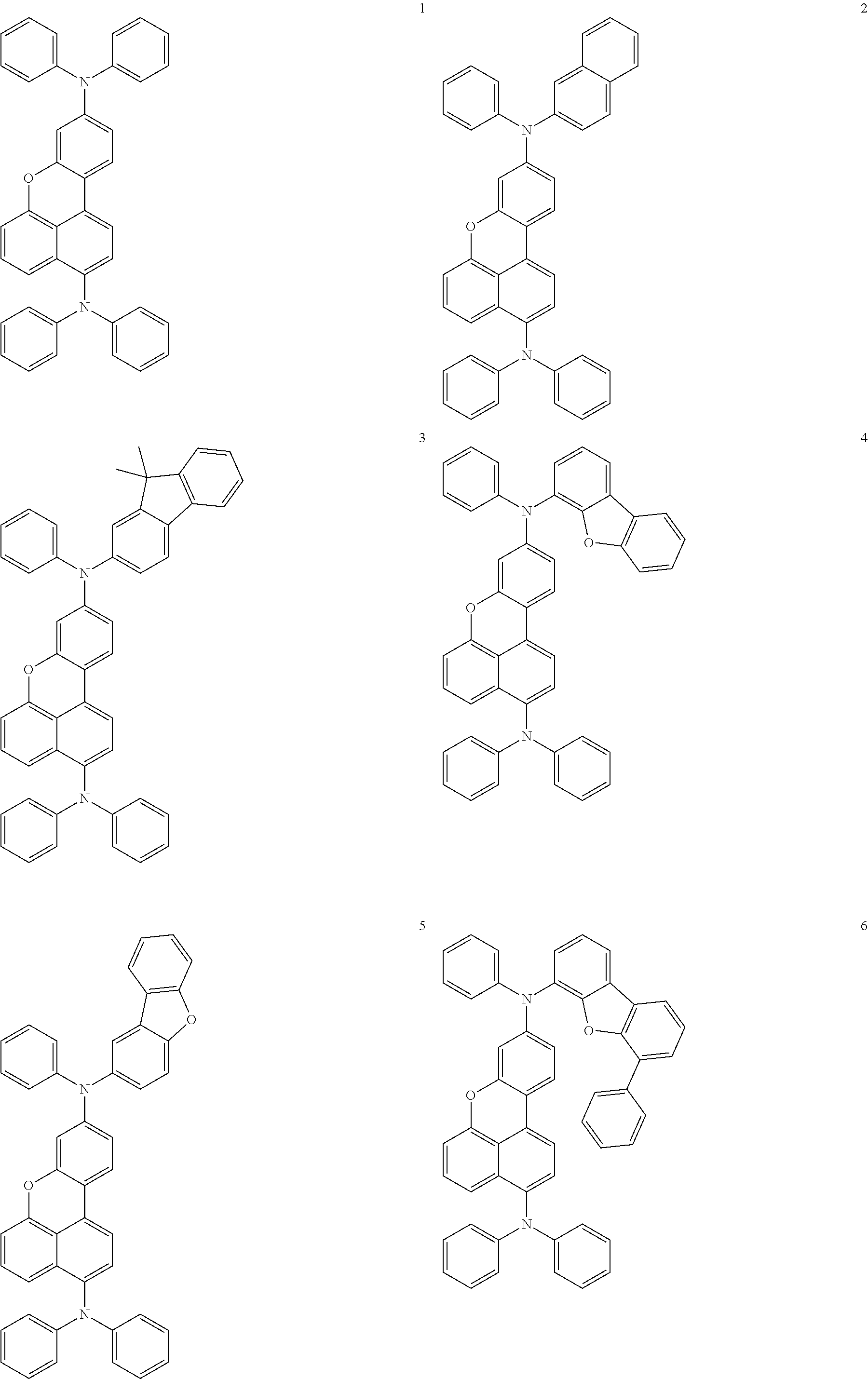

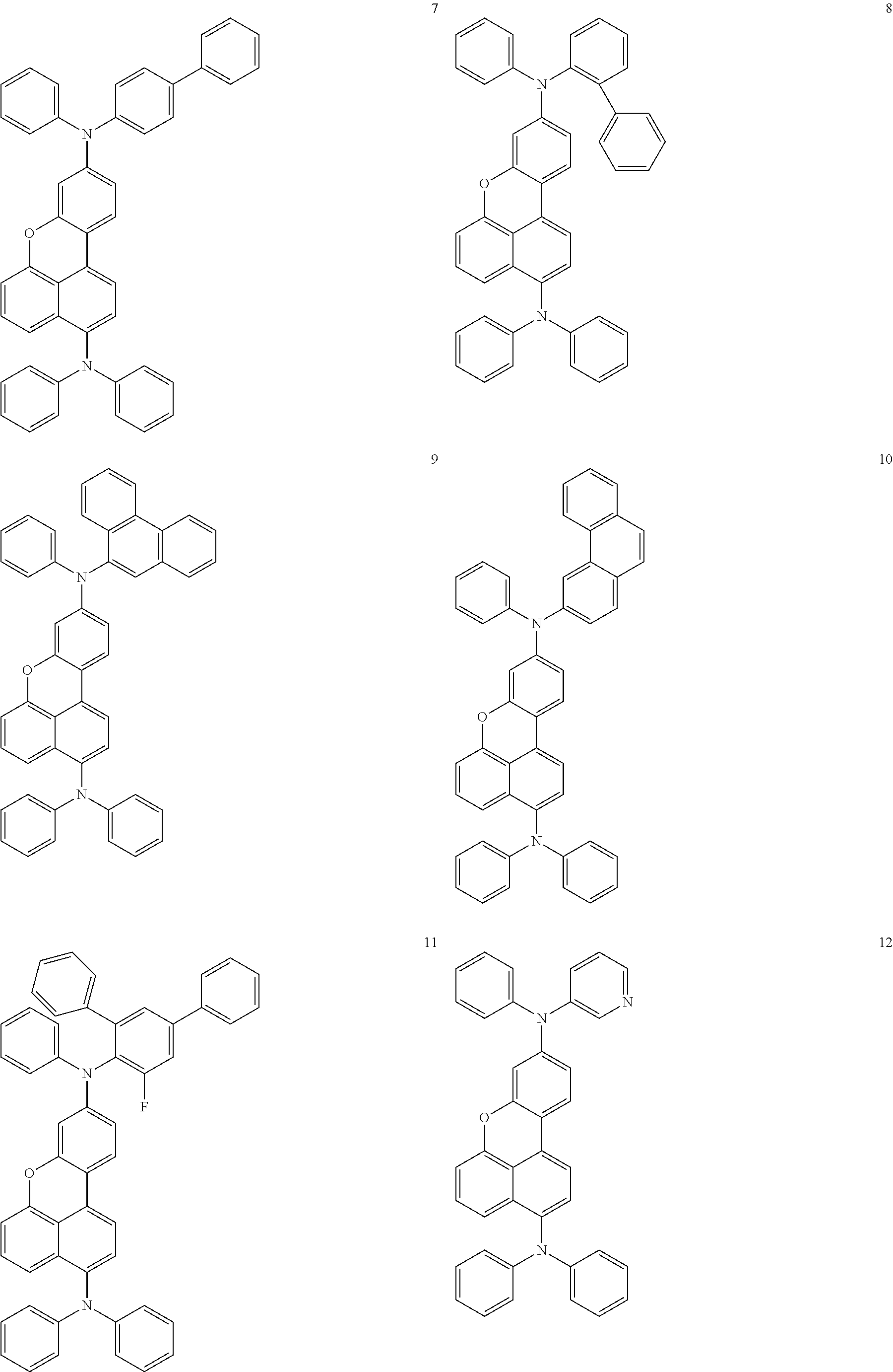 [SMILES: c1ccc(-c2ccc(N(c3ccccc3)c3ccc4c(c3)Oc3cccc5c(N(c6ccccc6)c6ccccc6)ccc-4c35)cc2)cc1 ; c1ccc(-c2ccccc2N(c2ccccc2)c2ccc3c(c2)Oc2cccc4c(N(c5ccccc5)c5ccccc5)ccc-3c24)cc1 ; c1ccc(N(c2ccccc2)c2ccc3c4c(cccc24)Oc2cc(N(c4ccccc4)c4cc5ccccc5c5ccccc45)ccc2-3)cc1 ; c1ccc(N(c2ccc3c(c2)Oc2cccc4c(N(c5ccccc5)c5ccccc5)ccc-3c24)c2ccc3ccc4ccccc4c3c2)cc1 ; Fc1cc(-c2ccccc2)cc(-c2ccccc2)c1N(c1ccccc1)c1ccc2c(c1)Oc1cccc3c(N(c4ccccc4)c4ccccc4)ccc-2c13 ; c1ccc(N(c2cccnc2)c2ccc3c(c2)Oc2cccc4c(N(c5ccccc5)c5ccccc5)ccc-3c24)cc1]

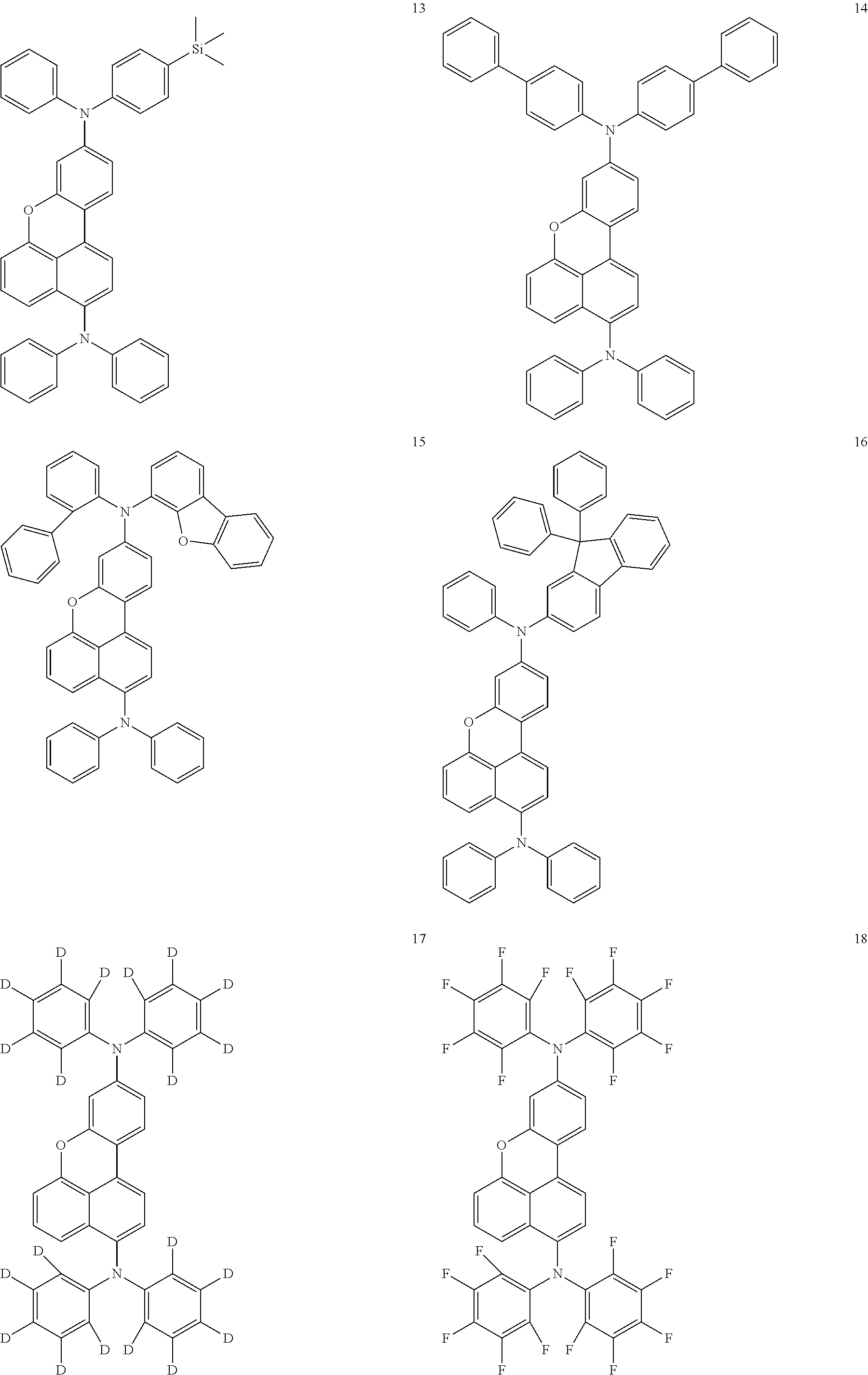

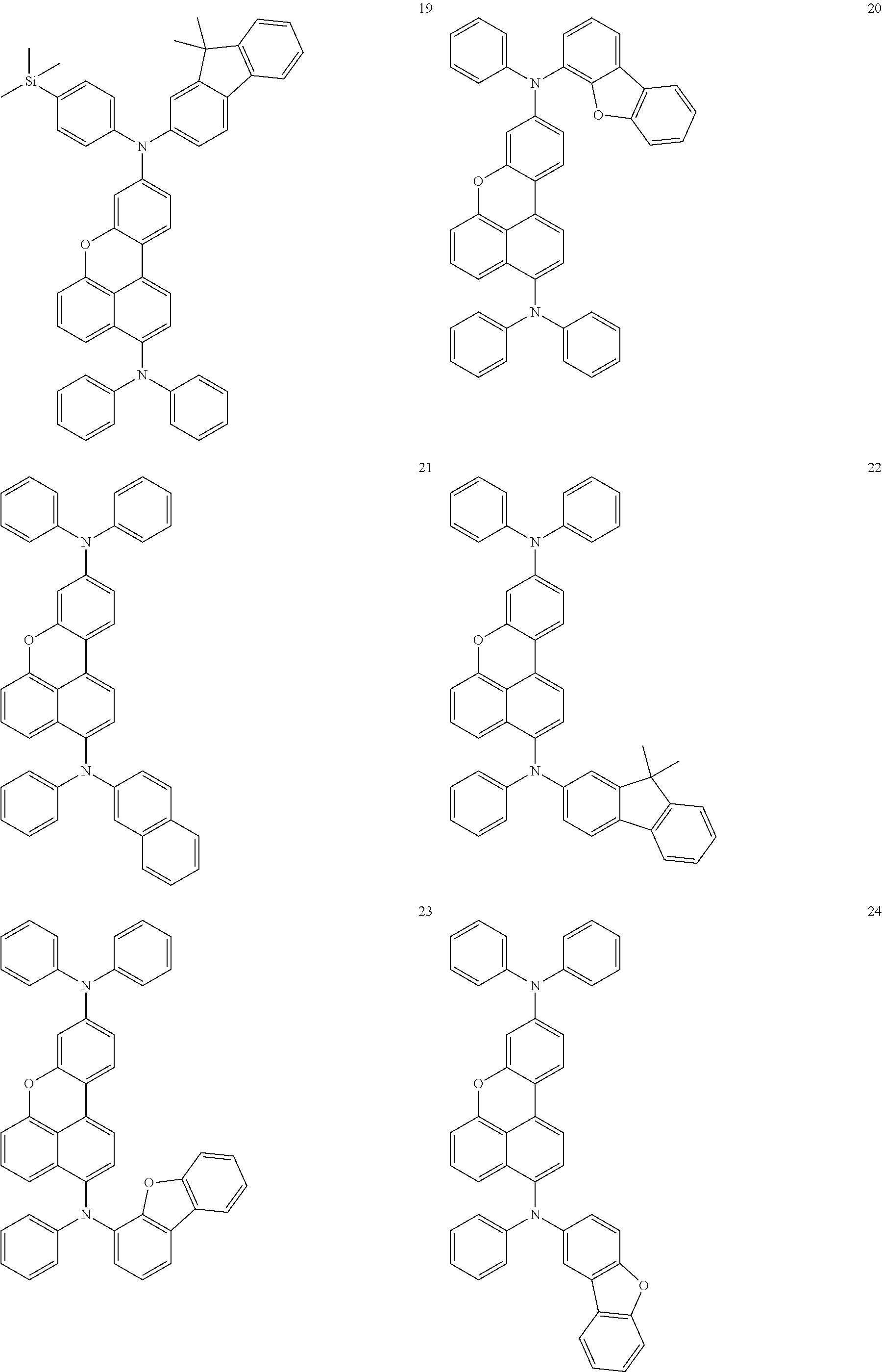

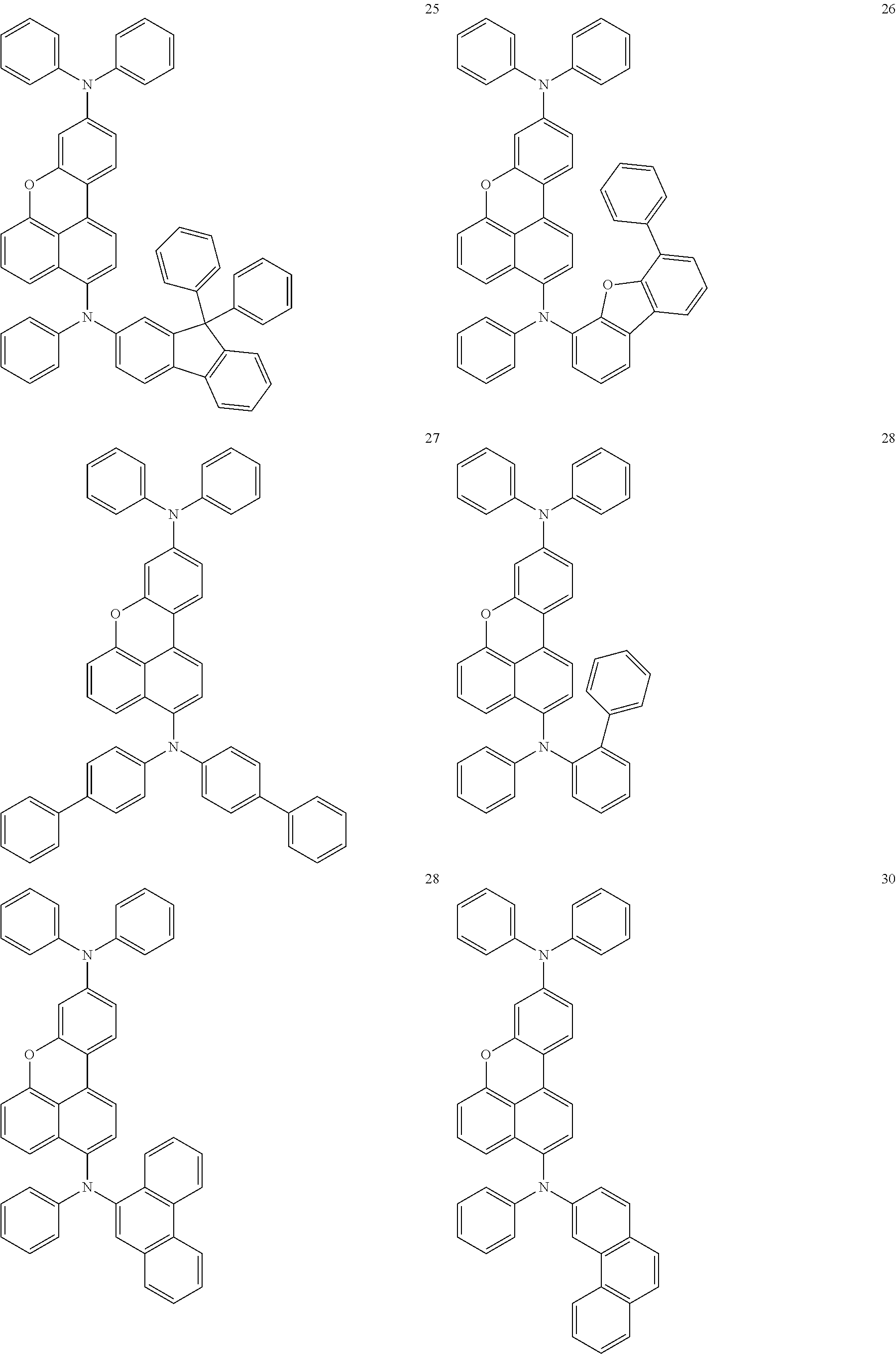

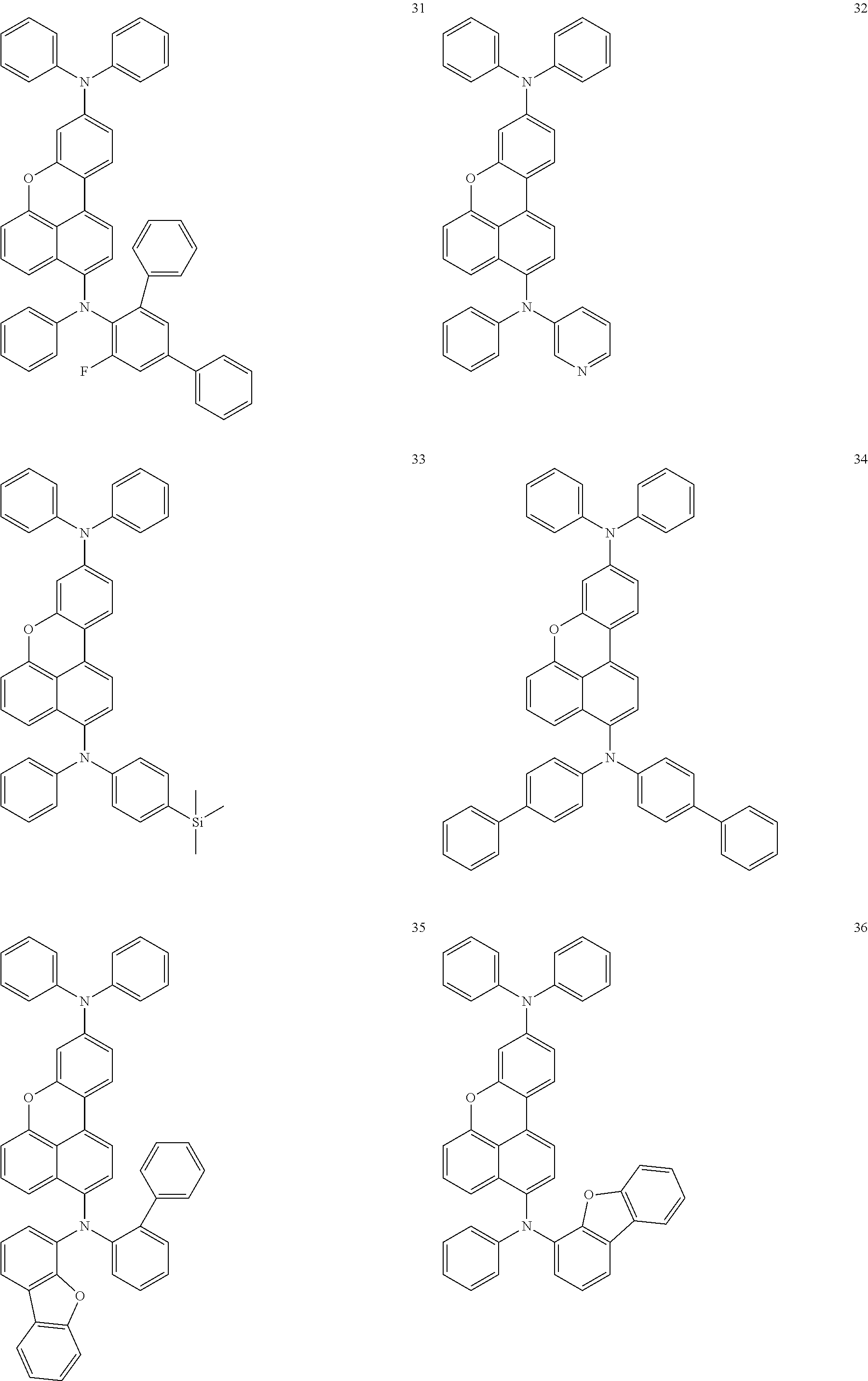

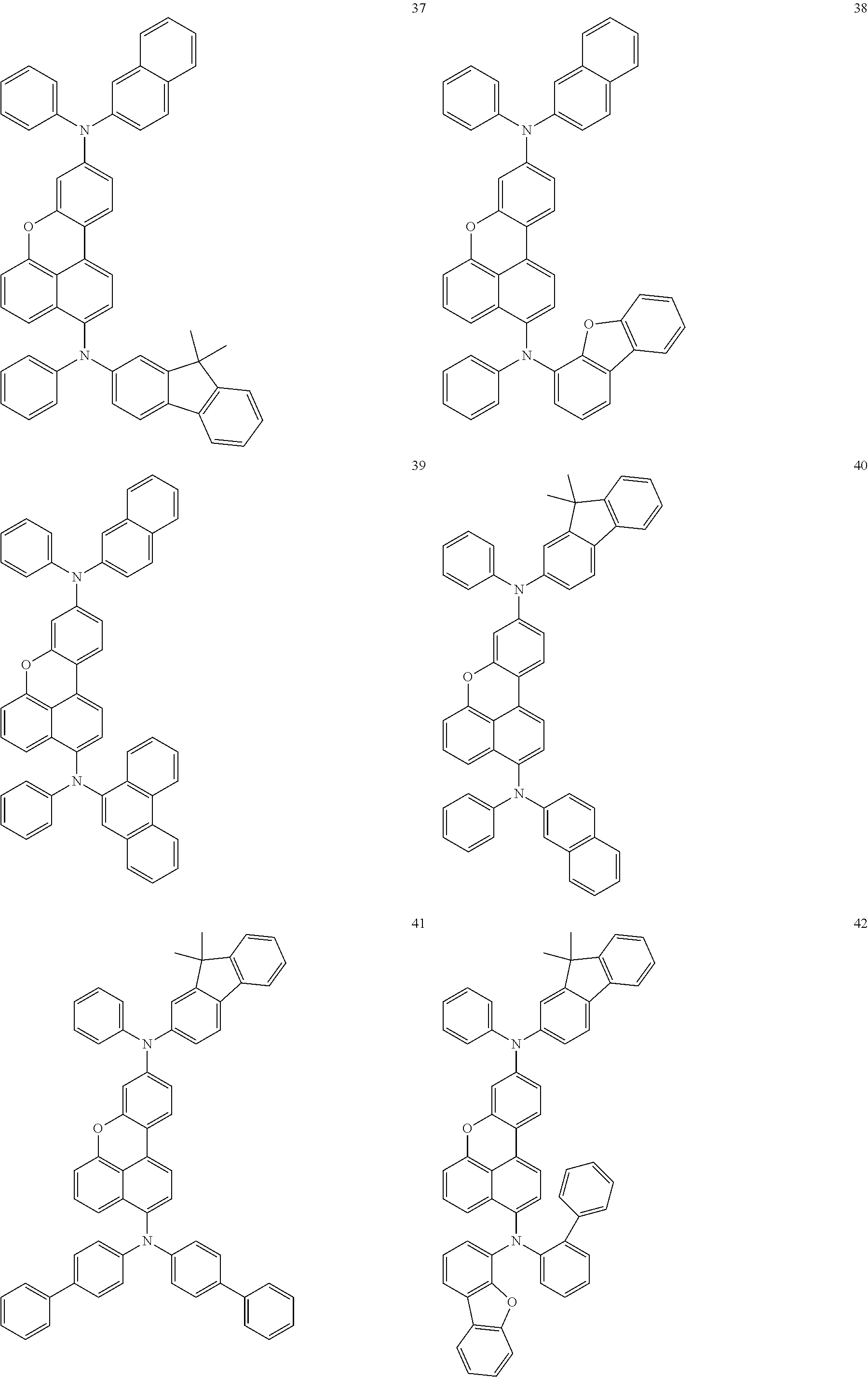

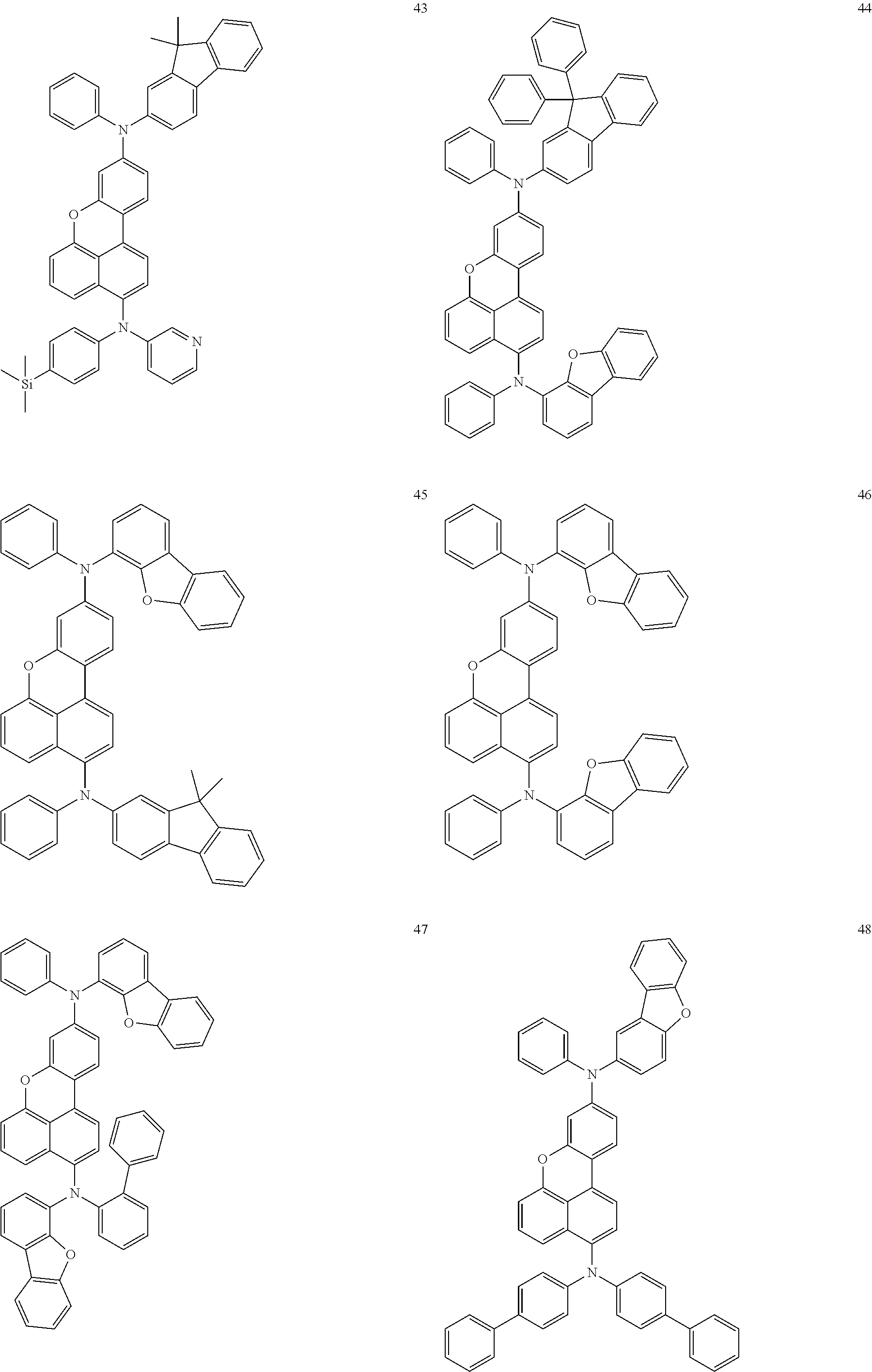

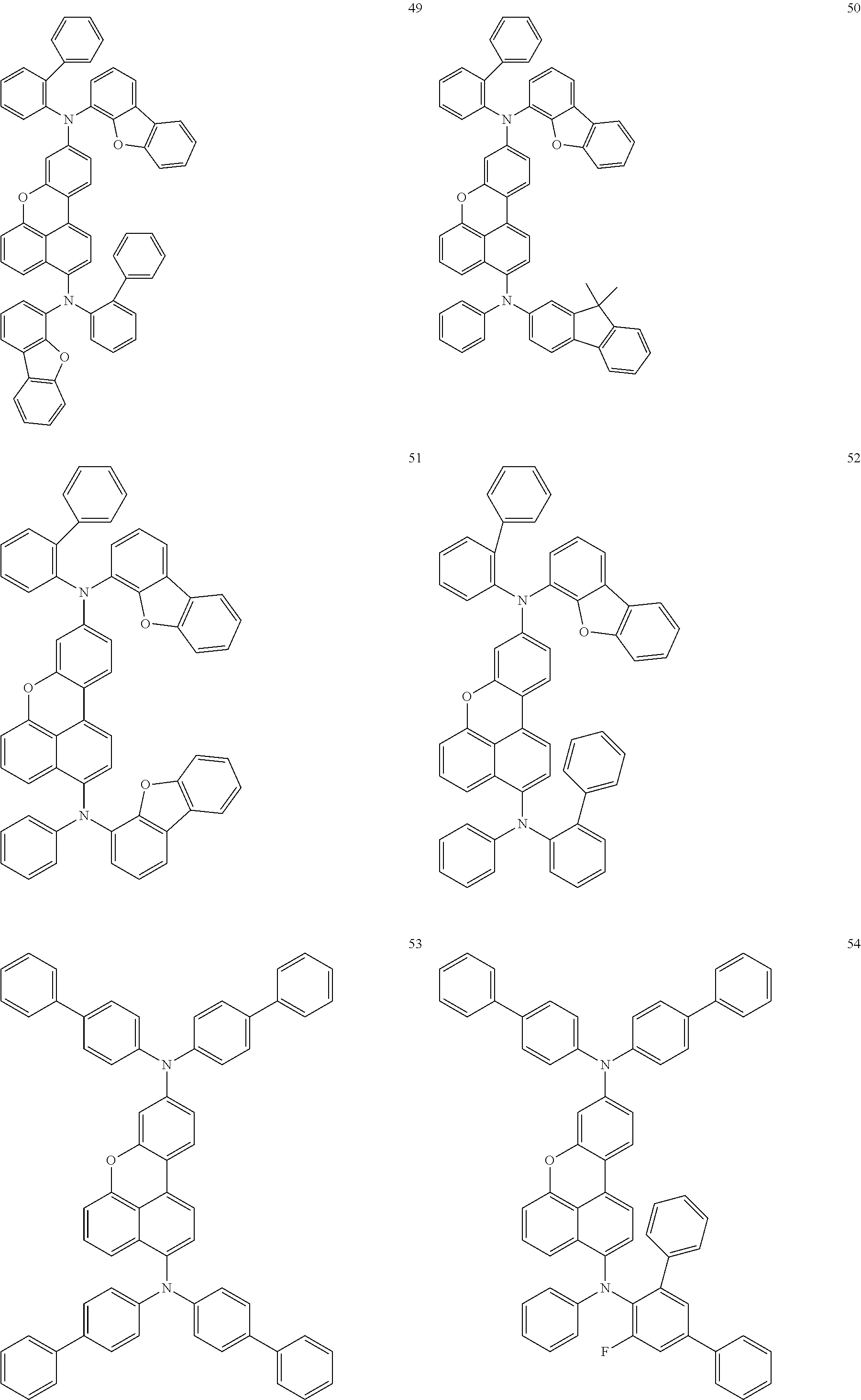

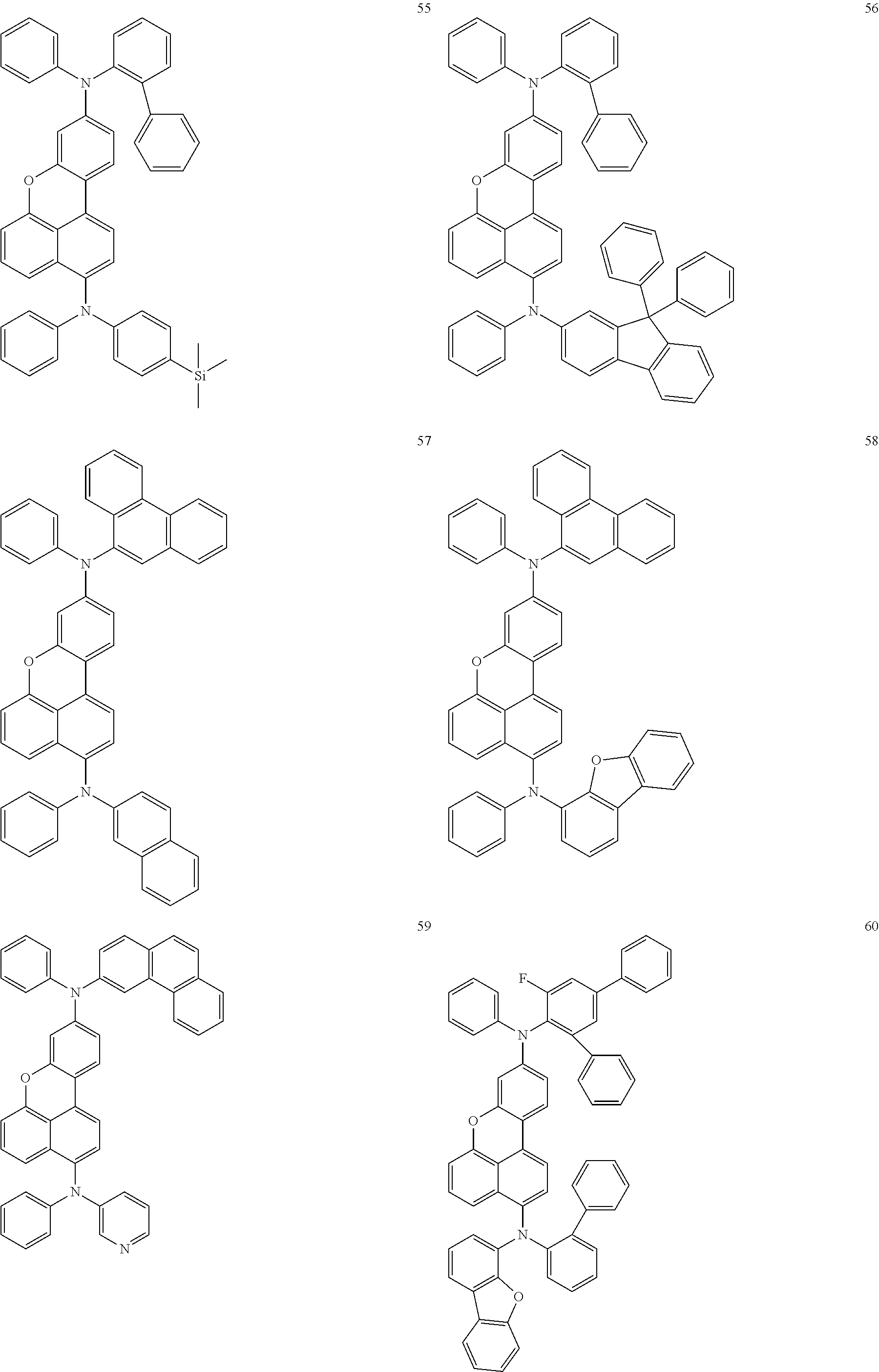

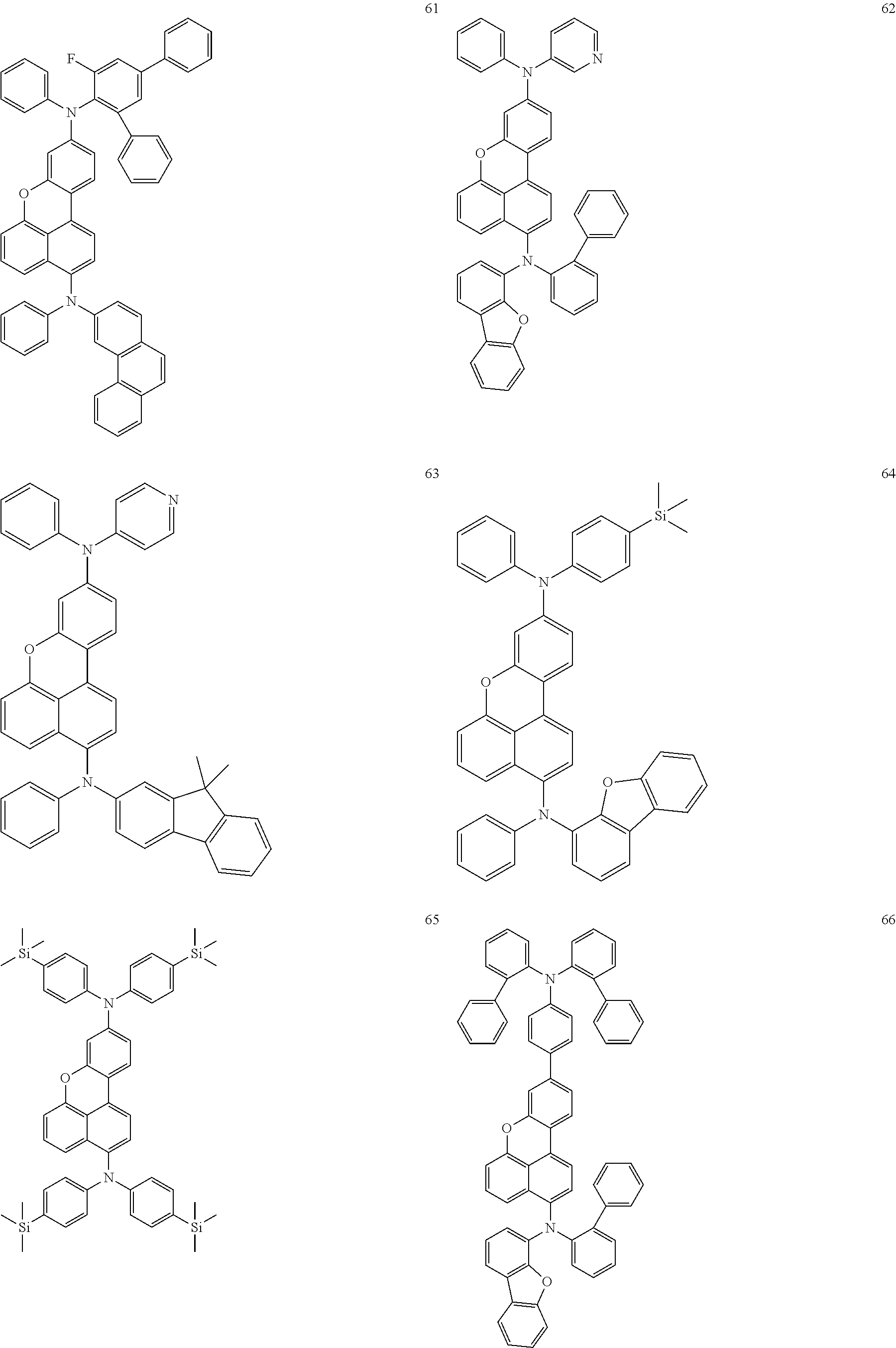

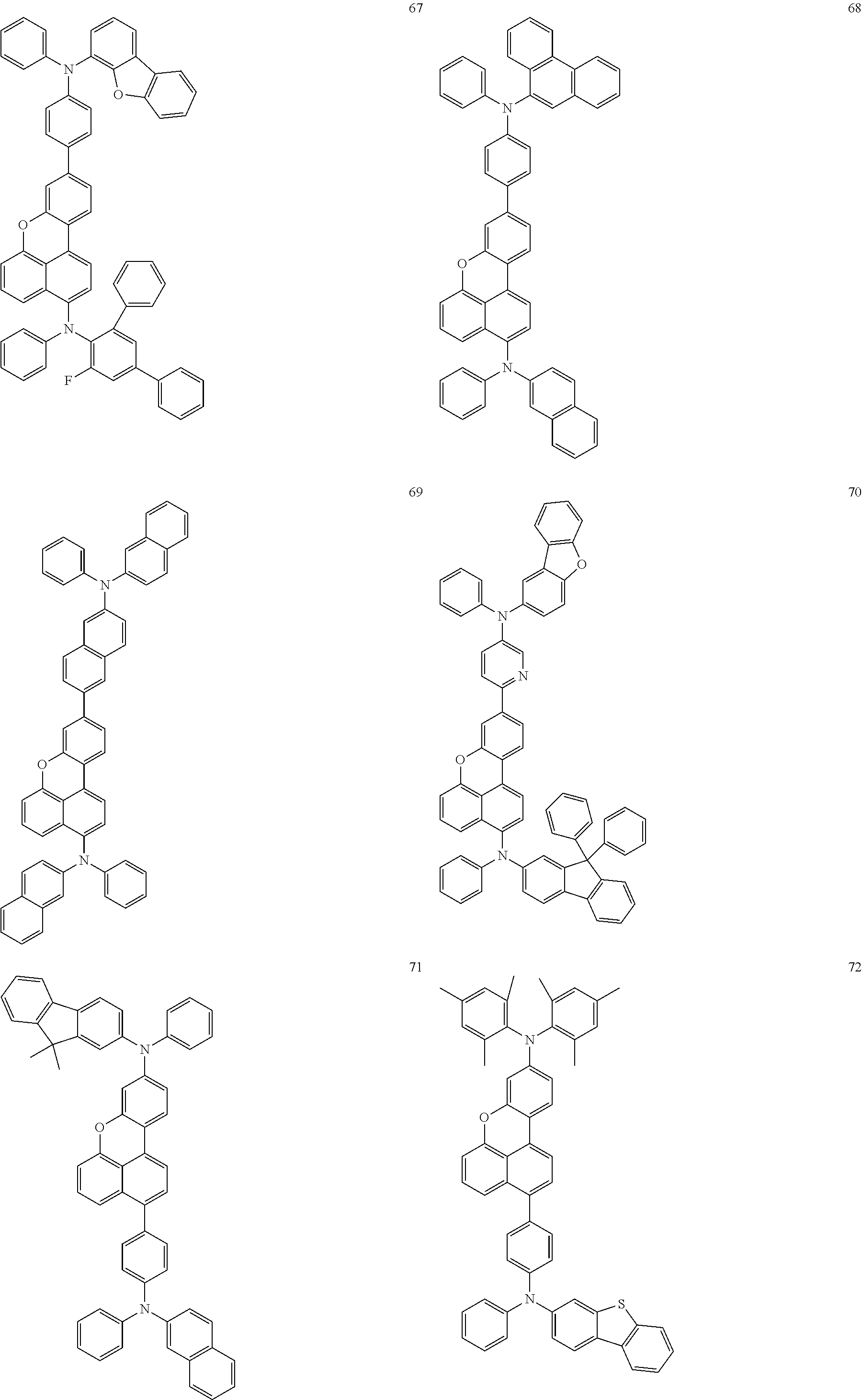

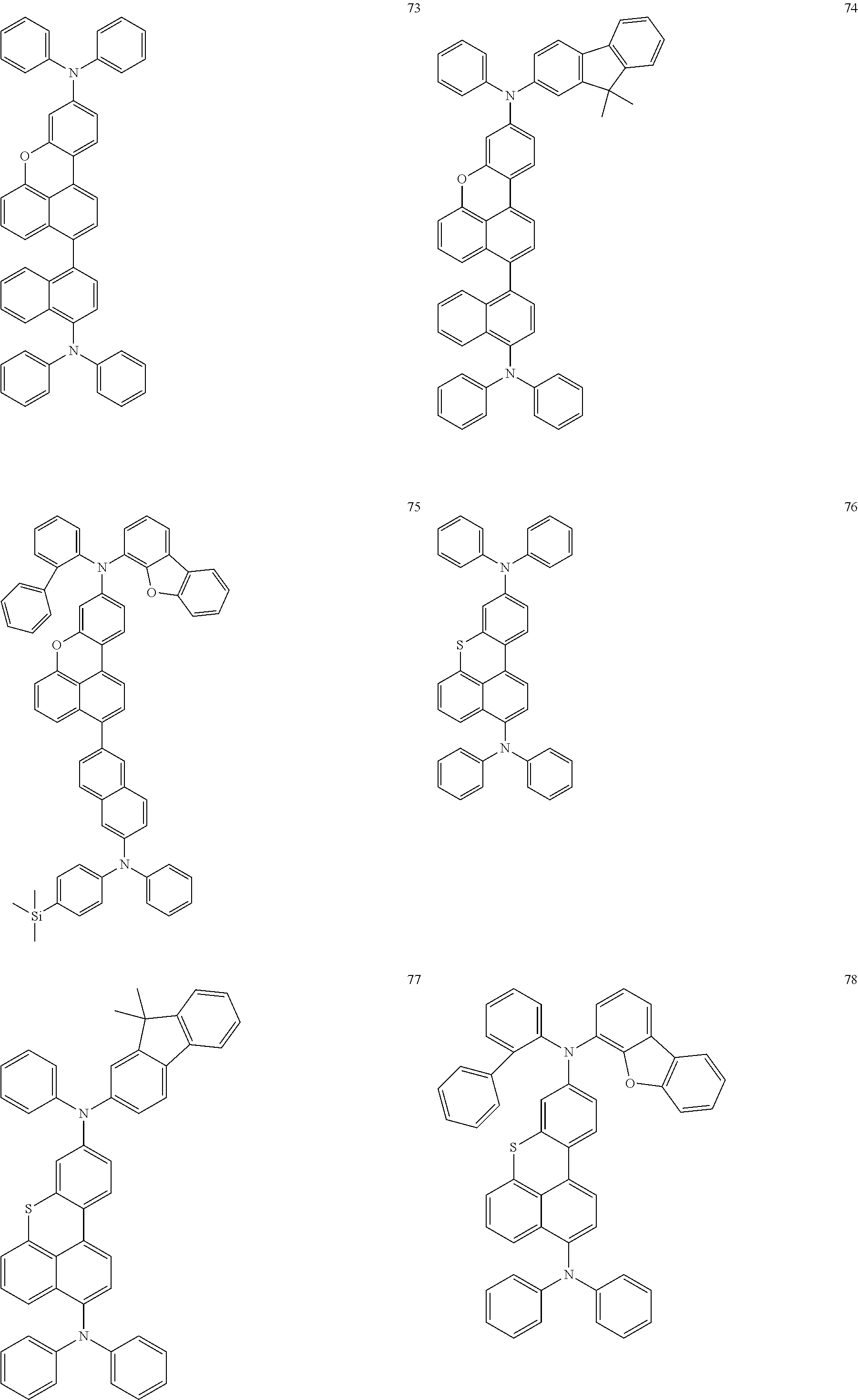

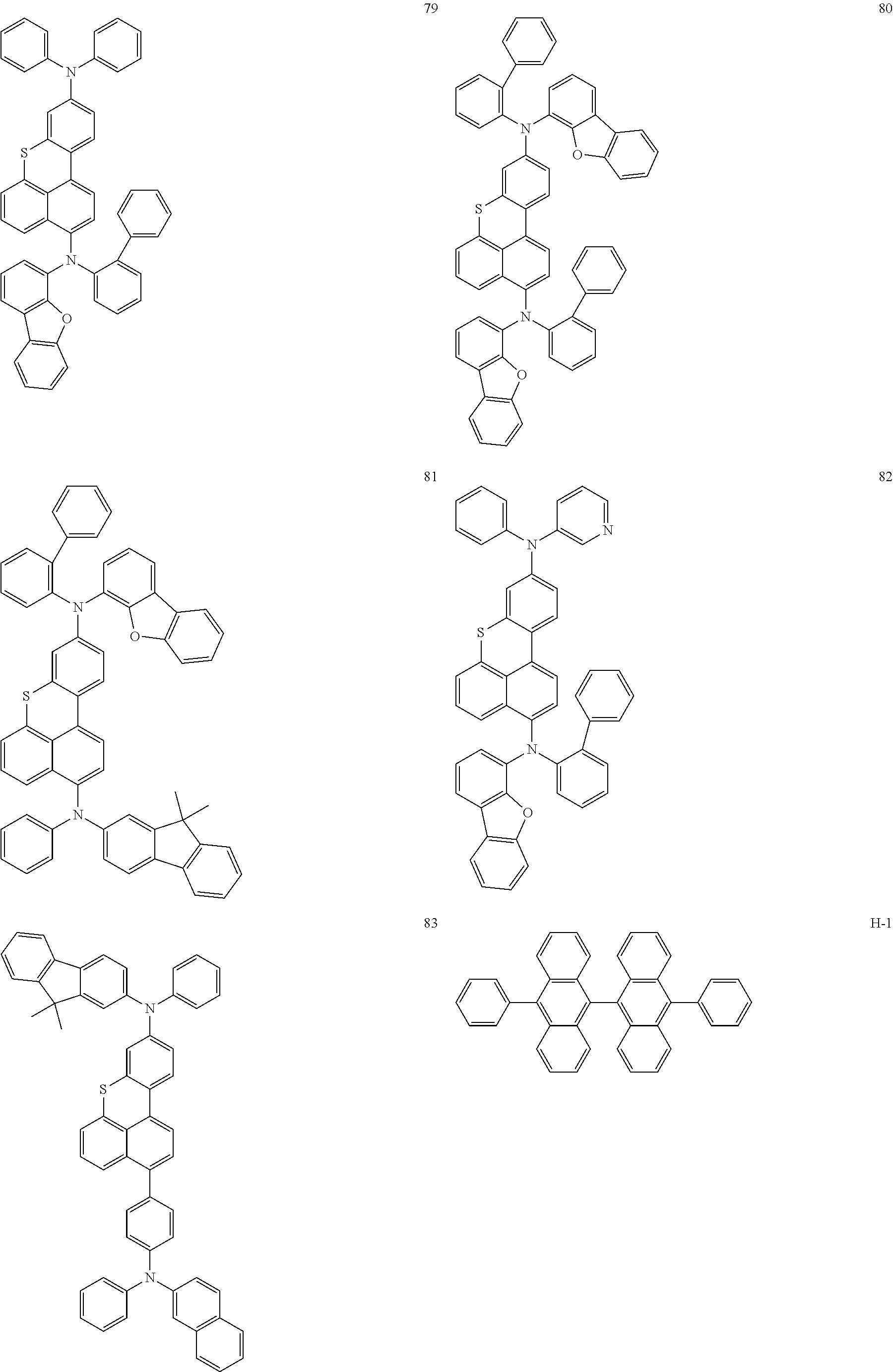

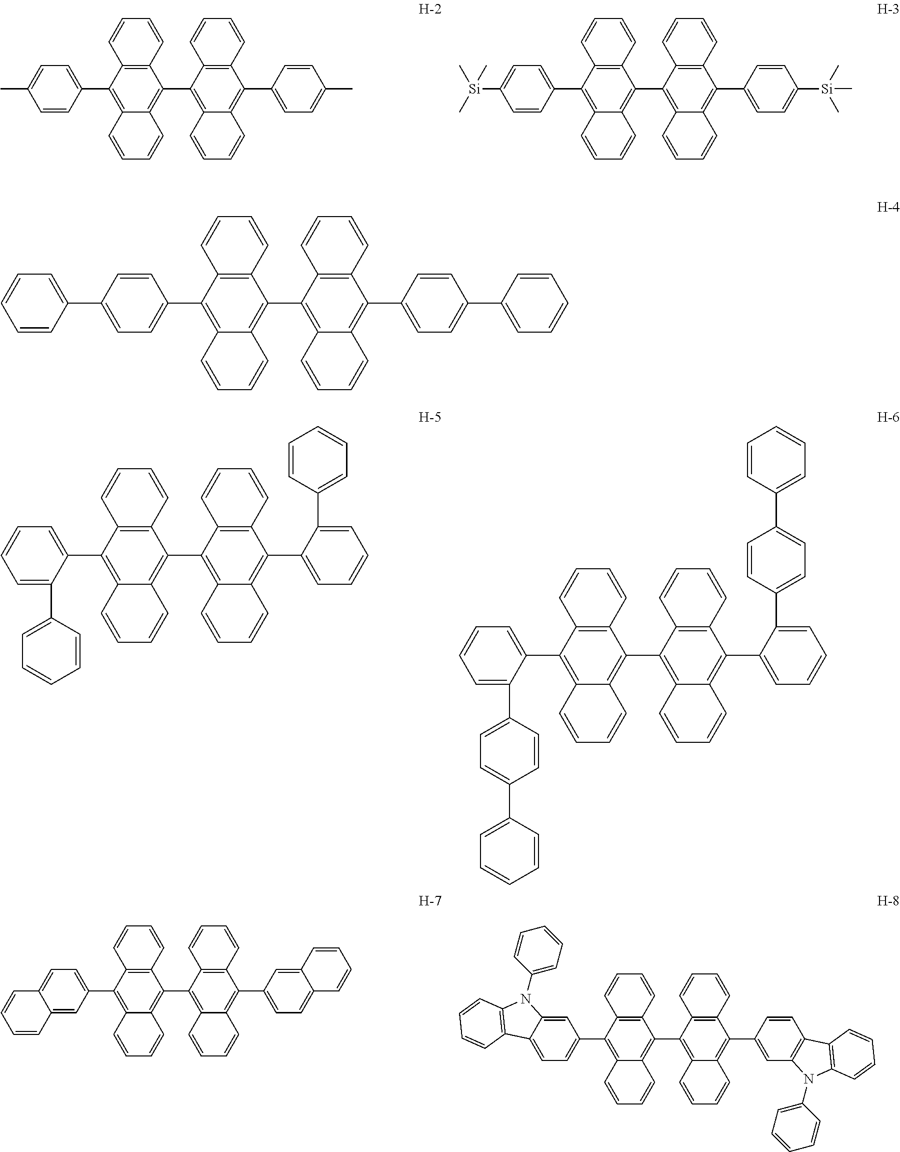

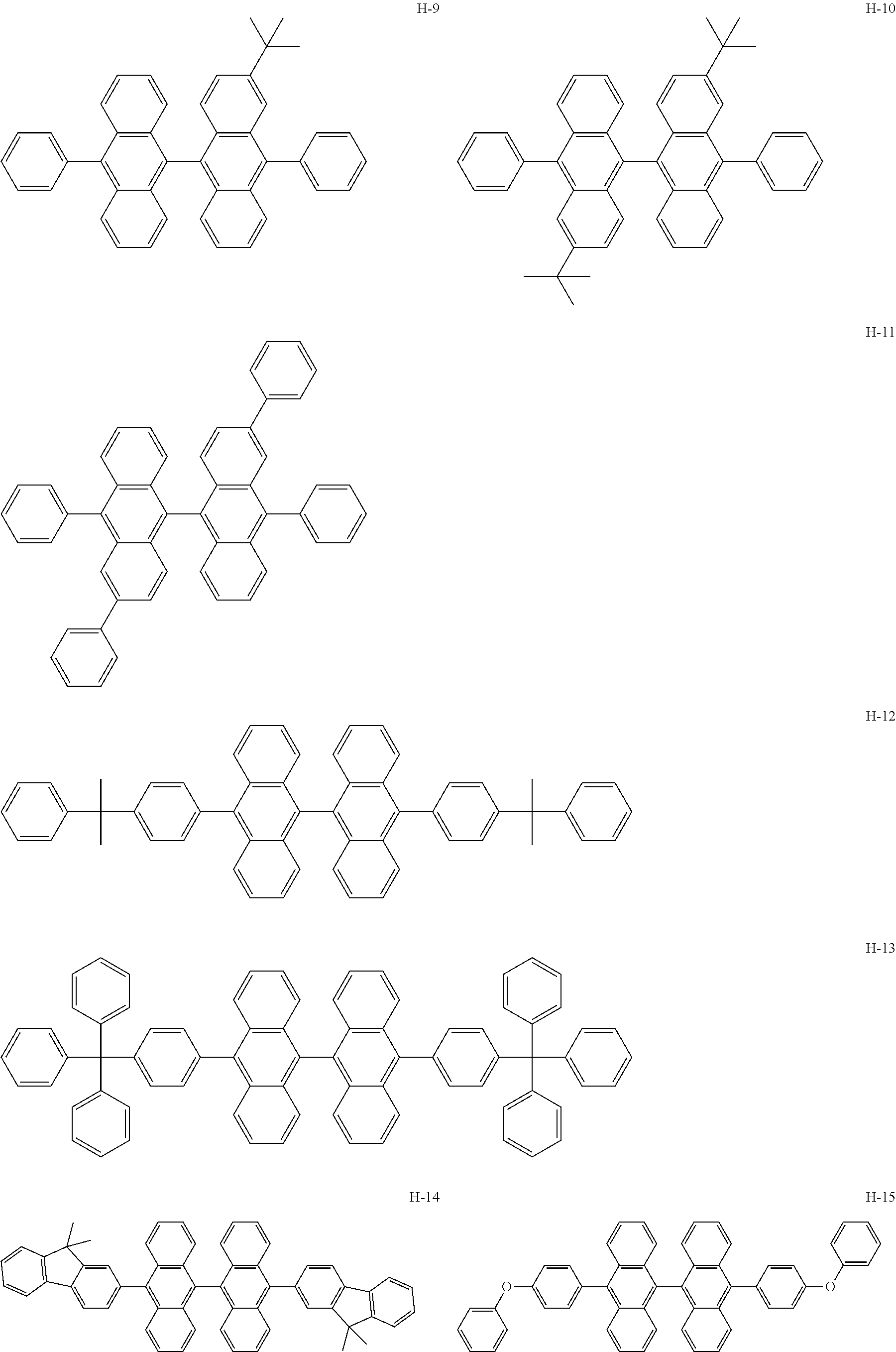

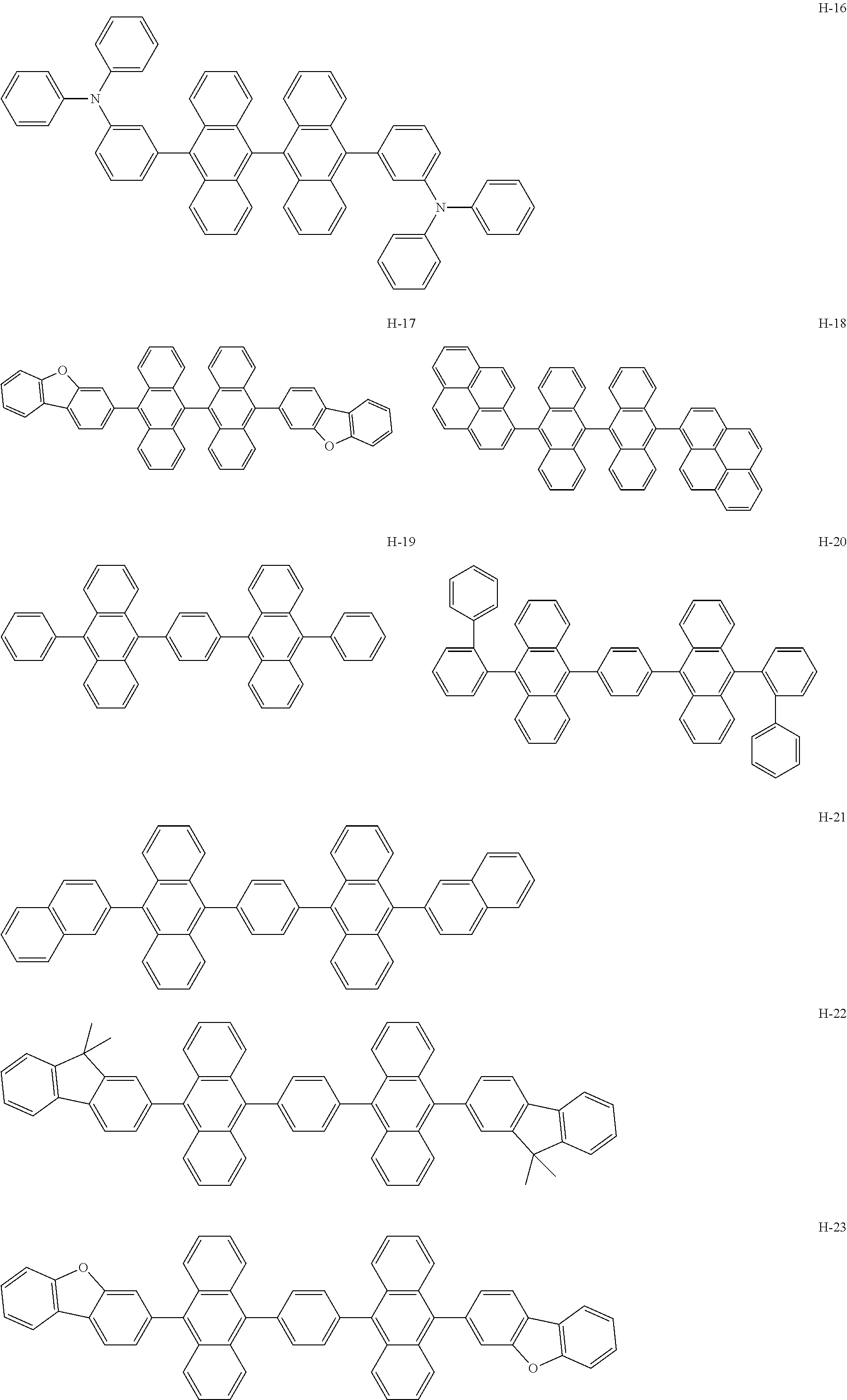

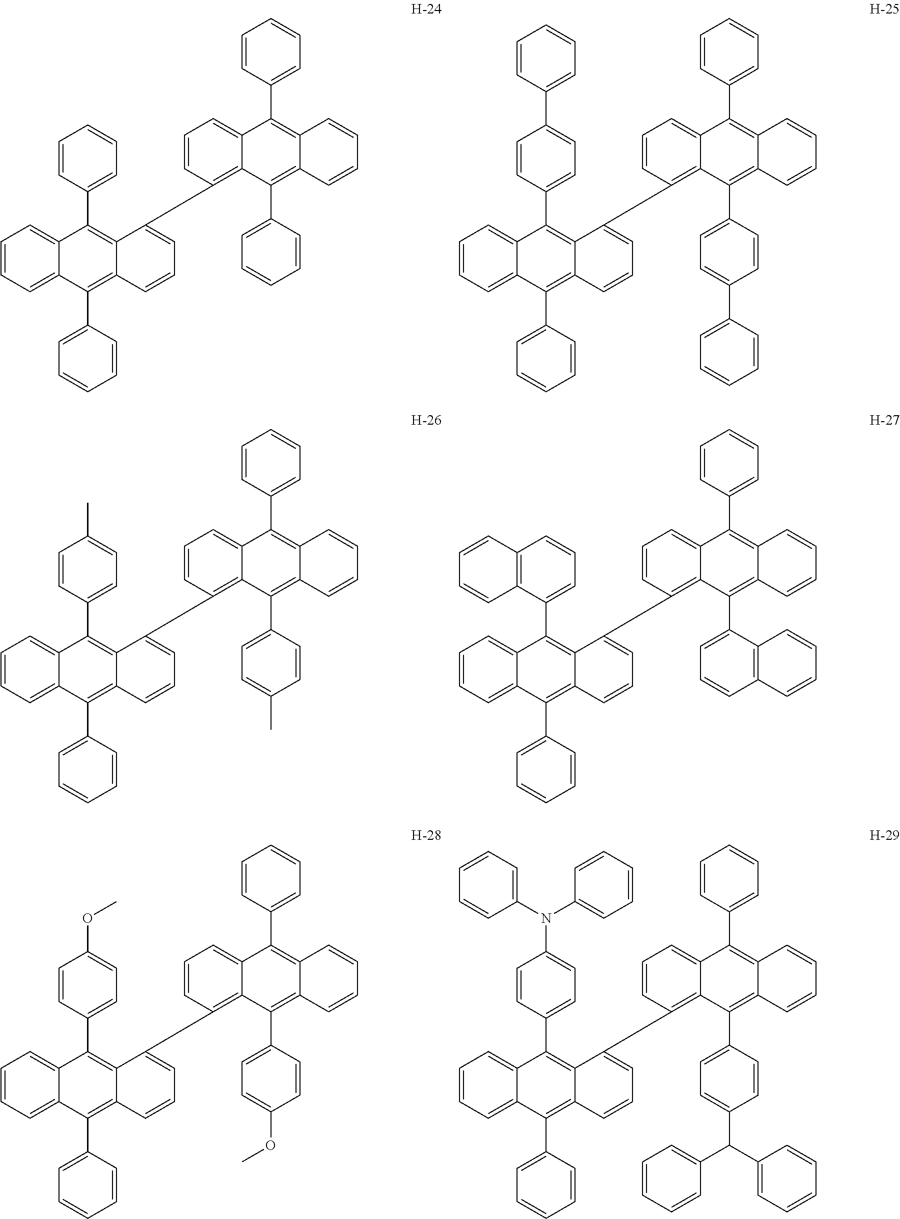

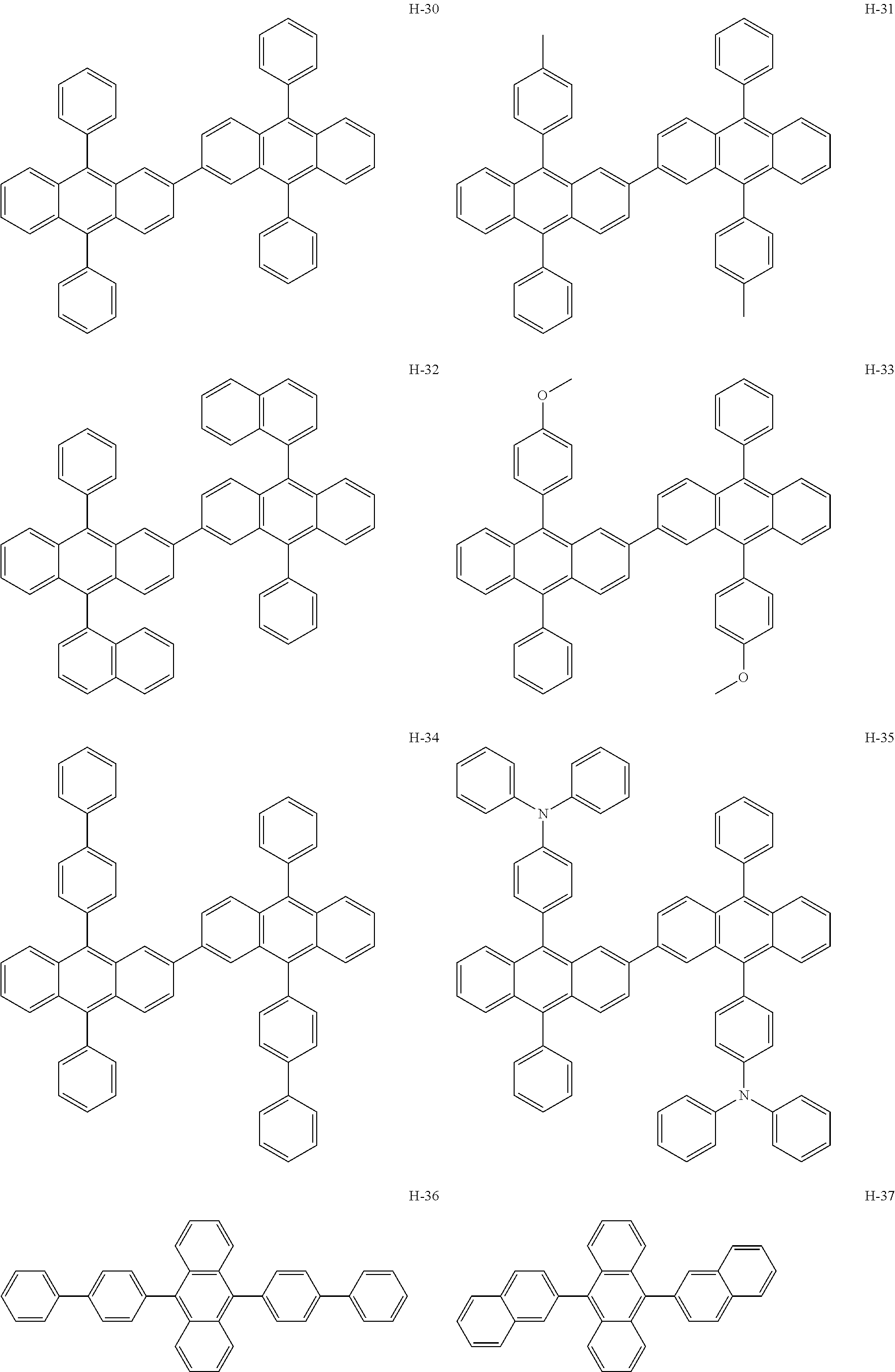

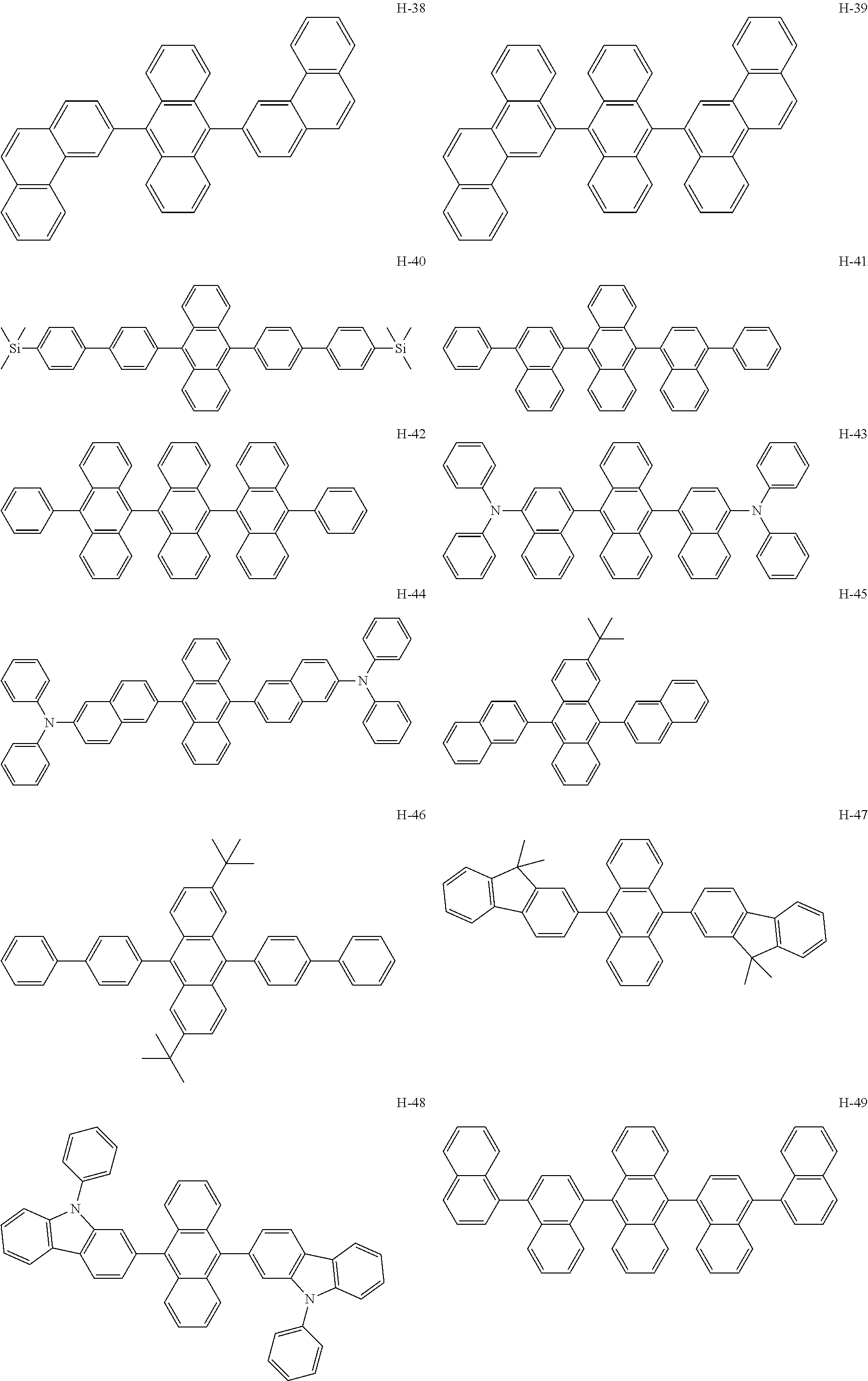

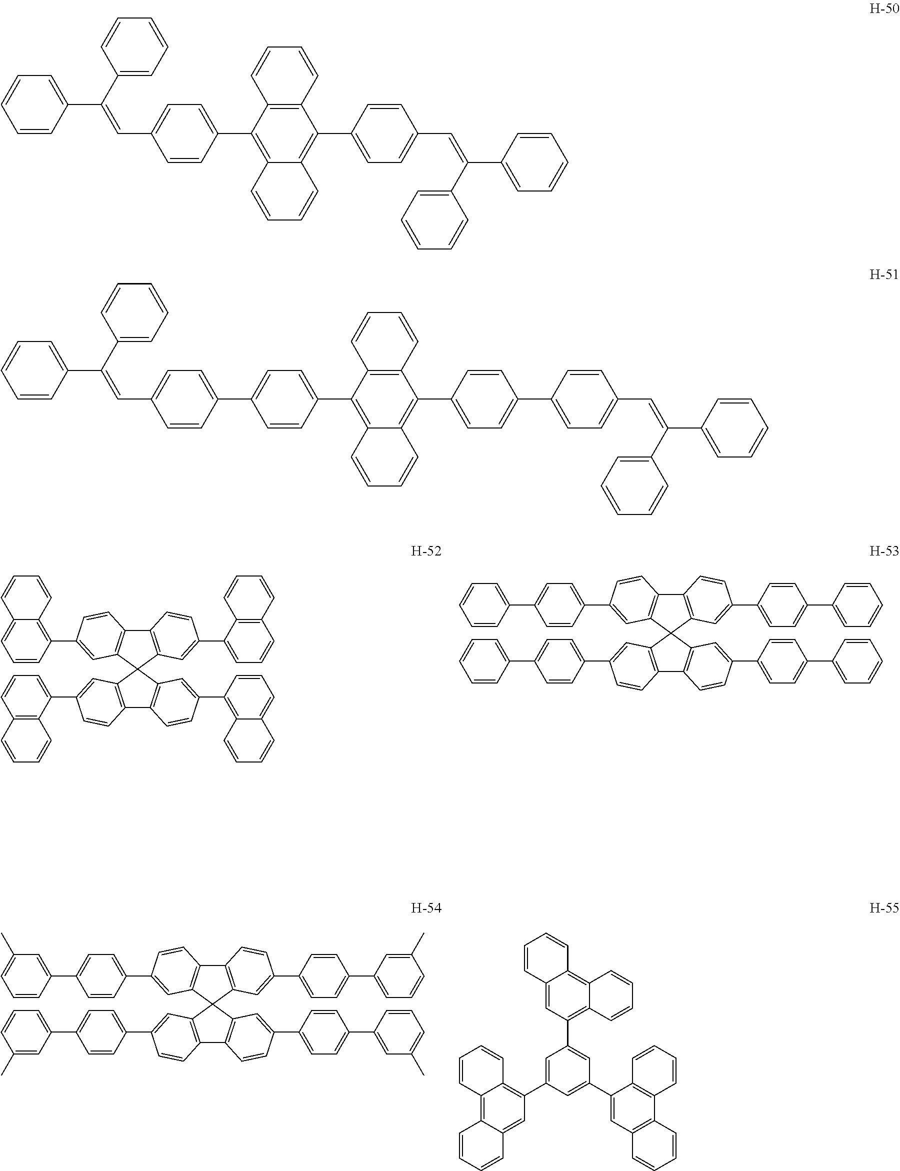

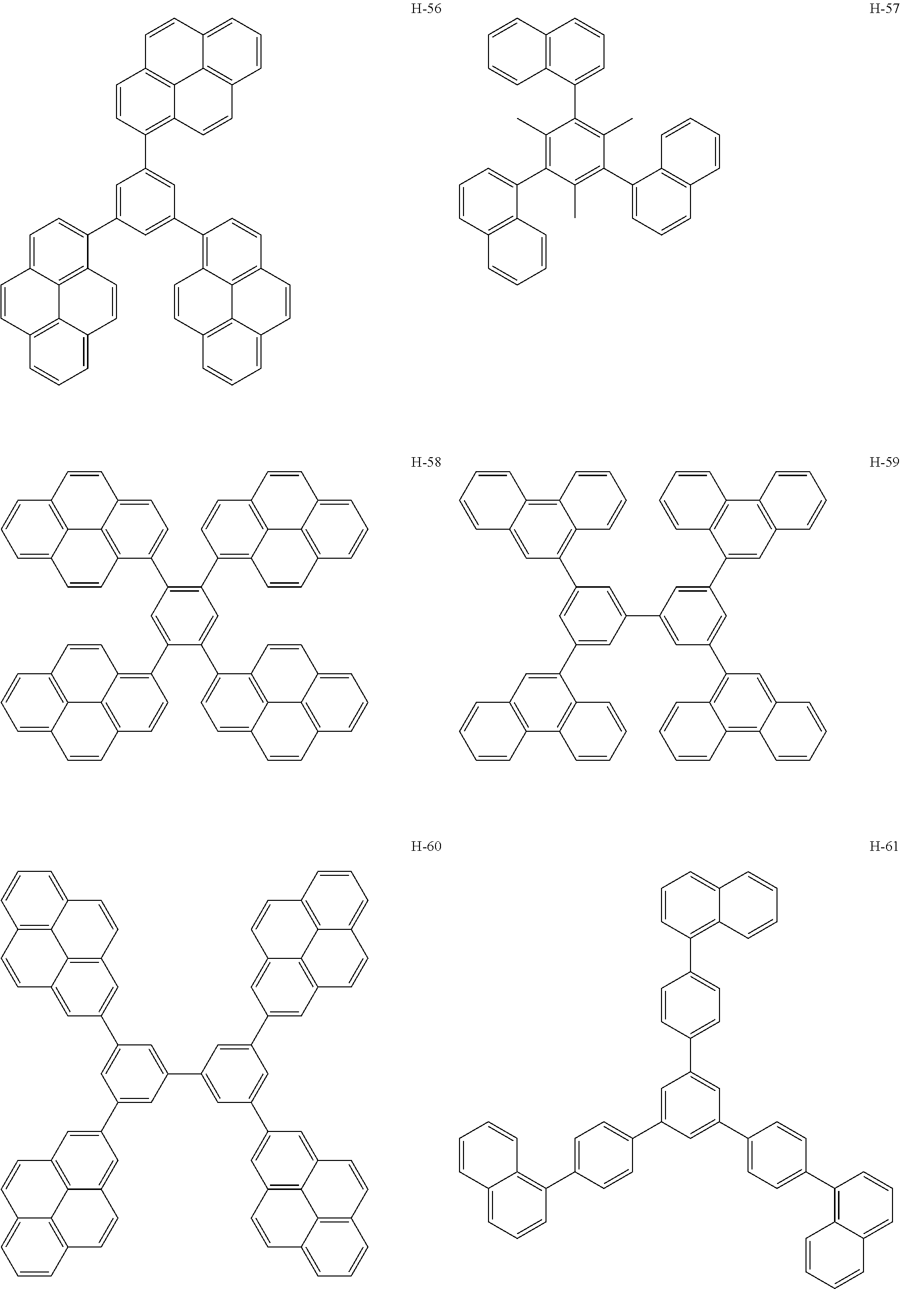

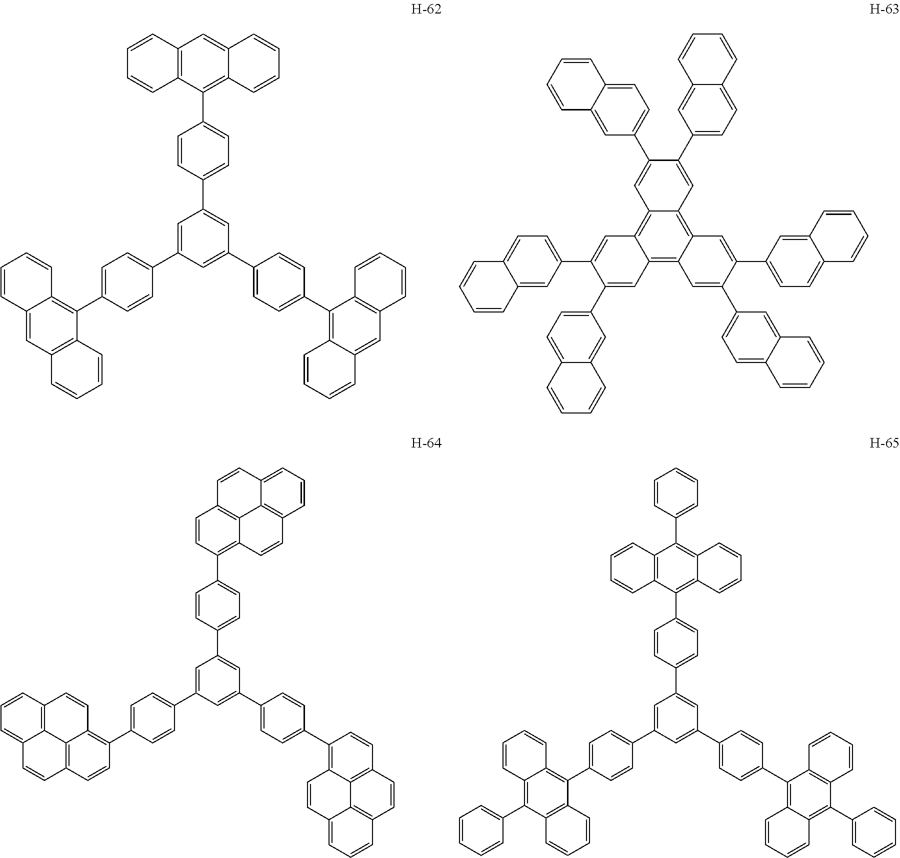

The first compound represented by Formula 1 may have a core represented by

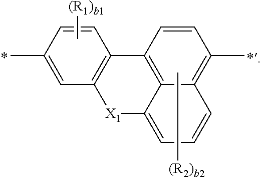

The core in Formula 1 may be constructed such that a benzene moiety and a naphthalene moiety are condensed to each other with X₁ therebetween, thereby having non-polarized 16 π-electrons. In the core in Formula 1, X₁ may be O or S, each having two non-covalent electron pairs, and the core in Formula 1 may partially receive excess electrons from the non-covalent electron pairs of X₁. Accordingly, the center of the first compound represented by Formula 1 may be enriched with π-electrons, leading to high possibility of π→π* transition and n→π* transition. Thus, luminescent efficiency of the first compound represented by Formula 1 may be increased.

Meanwhile, in the case of another compound (e.g. Compound A to be explained later) having the same structure as shown in Formula 1 except that X₁ is carbon, a benzene moiety may be linked to a naphthalene moiety with a carbon atom that does not have a non-covalent electron pair therebetween. Accordingly, an increase in luminescent efficiency due to the above-mentioned mechanism may not be achieved. In addition, due to two substituents linked to the carbon atom of the other compound, intramolecular vibration or a degree of freedom of rotational energy of the other compound may increase. As a result, the loss of transition energy of the other compound occurs, leading to a high possibility of a non-radiative transition instead of a radiative transition into a ground state. Accordingly, luminescent efficiency of the other compound may be decreased.

Also, energy transition from the second compound represented by one of Formulae 2-1 to 2-4 into the first compound represented by Formula 1 may smoothly occur. Accordingly, the first compound represented by Formula 1 may emit blue or yellow light having excellent color purity.

Thus, an electric device, e.g., an organic light-emitting device, including an organic layer (that includes the first compound and the second compound at the same time) may have high heat resistance, high efficiency, and a long lifespan.

The organic layer 150 may include both the first compound and the second compound. In some embodiments, the second compound may be included in an emission layer that is included in the organic layer 150, and the first compound may be included in a hole transport region between a first electrode and the emission layer. In some embodiments, the first compound and the second compound may all be included in an emission layer that is included in the organic layer 150, and additionally, the first compound may be further included in a hole transport region between a first electrode and the emission layer. In this regard, the first compound included in the emission layer and the first compound included in the hole transport region may be identical to or different from each other.

For example, the emission layer that is included in the organic layer 150 may include a host and a dopant. For example, the first compound included in the emission layer of the organic layer 150 may act as a dopant, and the second compound included in the emission layer of the organic layer 150 may act as a host. For example, the first compound included in the emission layer of the organic layer 150 may act as a fluorescent dopant, and the second compound included in the emission layer of the organic layer 150 may act as a fluorescent host.

A weight ratio of the first compound to the second compound may be in a range of 1:99 to 20:80. For example, a weight ratio of the first compound to the second compound may be in a range of 1:99 to 10:90. When the weight ratio of the first compound to the second compound satisfies these ranges, blue or yellow light having excellent color purity may be emitted.

A thickness of the emission layer may be in a range of about 100 Å to about 1,000 Å, e.g., about 200 Å to about 600 Å. When the thickness of the emission layer is within these ranges, excellent light-emission characteristics may be obtained without a substantial increase in driving voltage.

The hole transport region may include at least one selected from a hole injection layer (HIL), a hole transport layer (HTL), a buffer layer, and an electron blocking layer (EBL), and/or the electron transport region may include at least one selected from a hole blocking layer (HBL), an electron transport layer (ETL), and an electron injection layer (EIL).

The hole transport region may have a single-layered structure formed of a single material, a single-layered structure formed of a plurality of different materials, or a multi-layered structure having a plurality of layers formed of a plurality of different materials.

For example, the hole transport region may have a single-layered structure formed of a plurality of different materials, or a structure of hole injection layer/hole transport layer, a structure of hole injection layer/hole transport layer/buffer layer, a structure of hole injection layer/buffer layer, a structure of hole transport layer/buffer layer, a structure of hole injection layer/hole transport layer/electron blocking layer, or a structure of hole transport layer/electron blocking layer, wherein layers of each structure are sequentially stacked from the first electrode 110 in this stated order.

When the hole transport region includes a hole injection layer, the hole injection layer may be formed on the first electrode by using a suitable method, e.g., vacuum deposition, spin coating, casting, Langmuir-Blodgett (LB) method, ink-jet printing, laser-printing, or laser-induced thermal imaging (LITI).

When the hole injection layer is formed by vacuum-deposition, e.g., the vacuum-deposition may be performed at a temperature of a deposition temperature of about 100° C. to about 500° C., at a vacuum degree of about 10⁻⁸ Torr to about 10⁻³ Torr, and/or at a vacuum-deposition rate in a range of about 0.01 Å/sec to about 100 Å/sec in consideration of a compound for the hole injection layer to be deposited, and the structure of the hole injection layer to be formed.

When a hole injection layer is formed by spin coating, the spin coating may be performed at a coating rate of about 2,000 rpm to about 5,000 rpm, and/or at a temperature of about 80° C. to 200° C. in consideration of a compound for a hole injection layer to be deposited, and the structure of a hole injection layer to be formed.

When the hole transport region includes a hole transport layer, the hole transport layer may be formed on the first electrode or the hole injection layer by using a suitable method, e.g., vacuum deposition, spin coating, casting, LB method, ink-jet printing, laser-printing, or LITI. When the hole transport layer is formed by vacuum-deposition or spin coating, conditions for vacuum-deposition and coating may be similar to the above-described vacuum-deposition and coating conditions for forming the hole injection layer.

The hole transport region may include at least one selected from m-MTDATA, TDATA, 2-TNATA, NPB, β-NPB, TPD, a spiro-TPD, a spiro-NPB, α-NPB, TAPC, HMTPD, 4,4′,4″-tris(N-carbazolyl)triphenylamine (TCTA), polyaniline/dodecylbenzenesulfonic acid (Pani/DBSA), poly(3,4-ethylenedioxythiophene)/poly(4-styrenesulfonate) (PEDOT/PSS), polyaniline/camphor sulfonicacid (Pani/CSA), (polyaniline)/poly(4-styrenesulfonate) (PANI/PSS), a compound represented by Formula 201 below, and a compound represented by Formula 202 below:

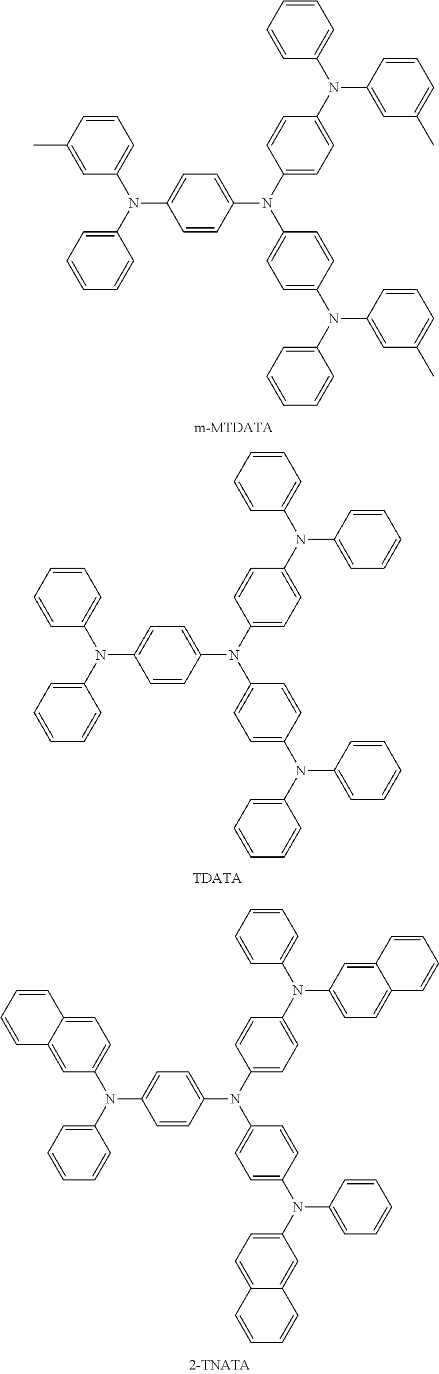

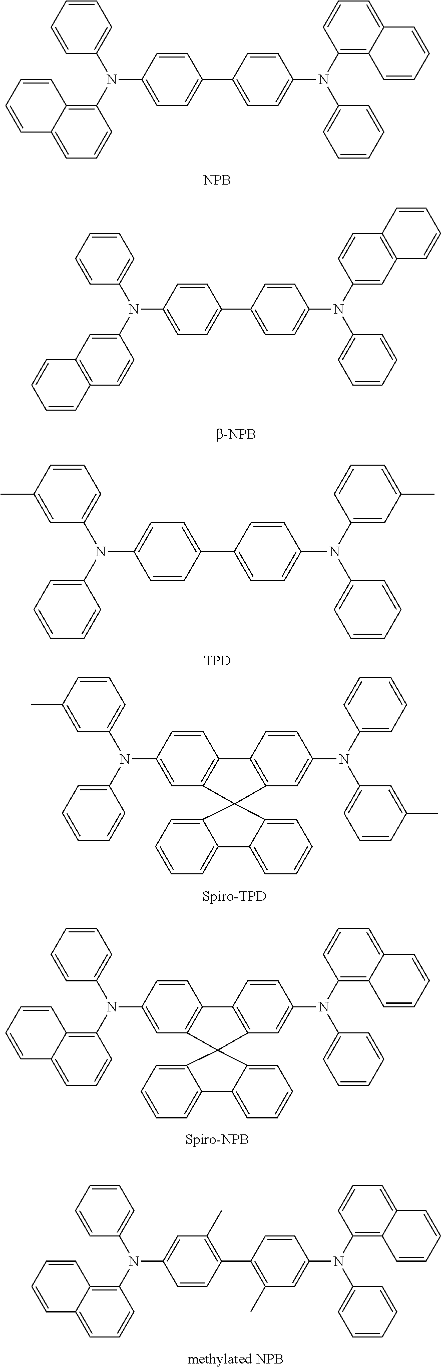

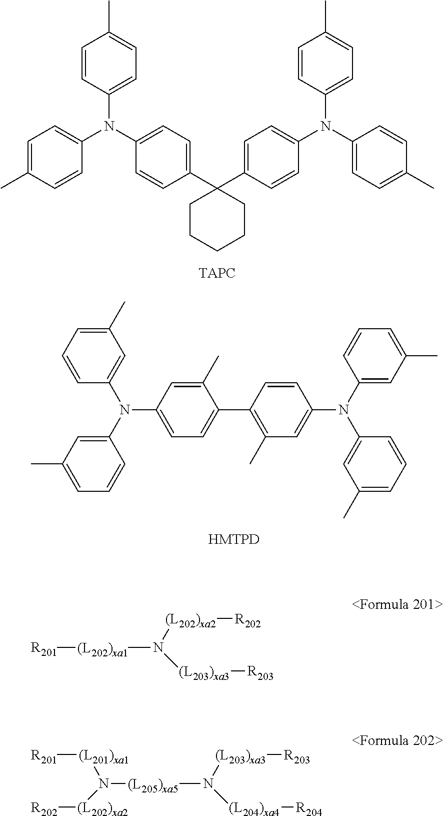

wherein in Formulae 201 and 202,

descriptions of L₂₀₁ to L₂₀₅ may be understood by referring to the descriptions provided in connection with L₁ to L₃;

xa1 to xa4 may each independently be selected from 0, 1, 2, and 3;

xa5 may be selected from 1, 2, 3, 4, and 5;

R₂₀₁ to R₂₀₄ may each independently be selected from a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group.

For example, L₂₀₁ to L₂₀₅ in Formulae 201 and 202 may each independently be selected from:

a phenylene group, a naphthylene group, a fluorenylene group, a spiro-fluorenylene group, a benzofluorene group, a dibenzofluorene group, a phenanthrenylene group, an anthracenylene group, a pyrenylene group, a chrysenylene group, a pyridinylene group, a pyrazinylene group, a pyrimidinylene group, a pyridazinylene group, a quinolinylene group, an isoquinolinylene group, a quinoxalinylene group, a quinazolinylene group, a carbazolylene group, and a triazinylene group; and

a phenylene group, a naphthylene group, a fluorenylene group, a spiro-fluorenylene group, a benzofluorenylene group, a dibenzofluorenylene group, a phenanthrenylene group, an anthracenylene group, a pyrenylene group, a chrysenylene group, a pyridinylene group, a pyrazinylene group, a pyrimidinylene group, a pyridazinylene group, a quinolinylene group, an isoquinolinylene group, a quinoxalinylene group, a quinazolinylene group, a carbazolylene group, and a triazinylene group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, an isoindolyl group, a quinolinyl group, an isoquinolinyl group, a quinoxalinyl group, a quinazolinyl group, a carbazolyl group, and a triazinyl group;

xa1 to xa4 may each independently be 0, 1, or 2;

xa5 may be 1, 2, or 3;

R₂₀₁ to R₂₀₄ may be each independently selected from:

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group; and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, an azulenyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group.

The compound represented by Formula 201 may be represented by Formula 201A below:

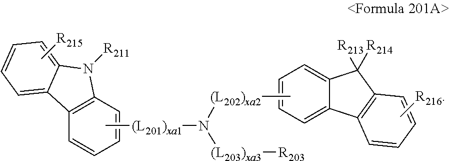

For example, the compound represented by Formula 201 may be represented by Formula 201A-1:

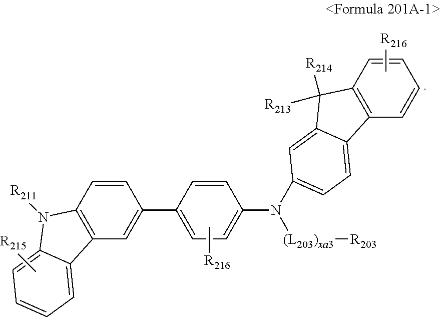

The compound represented by Formula 202 may be represented by Formula 202A:

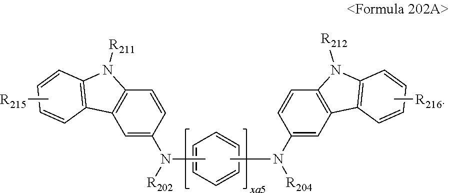

L₂₀₁ to L₂₀₃, xa1 to xa3, xa5 and R₂₀₂ to R₂₀₄ in Formulae 201A, 201A-1 and 202A are already described above, descriptions of R₂₁₁ and R₂₁₂ are the same as the descriptions provided in connection with R₂₀₃, and R₂₁₃ to R₂₁₆ may each independently be selected from a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group.

For example, in Formulae 201A, 201A-1, and 202A,

L₂₀₁ to L₂₀₃ may each independently be selected from

a phenylene group, a naphthylene group, a fluorenylene group, a spiro-fluorenylene group, a benzofluorenylene group, a dibenzofluorenylene group, a phenanthrenylene group, an anthracenylene group, a pyrenylene group, a chrysenylene group, a pyridinylene group, a pyrazinylene group, a pyrimidinylene group, a pyridazinylene group, a quinolinylene group, an isoquinolinylene group, a quinoxalinylene group, a quinazolinylene group, a carbazolylene group, and a triazinylene group; and

a phenylene group, a naphthylene group, a fluorenylene group, a spiro-fluorenylene group, a benzofluorenylene group, a dibenzofluorenylene group, a phenanthrenylene group, an anthracenylene group, a pyrenylene group, a chrysenylene group, a pyridinylene group, a pyrazinylene group, a pyrimidinylene group, a pyridazinylene group, a quinolinylene group, an isoquinolinylene group, a quinoxalinylene group, a quinazolinylene group, a carbazolylene group, and a triazinylene group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group;

xa1 to xa3 may each independently be 0 or 1;

R₂₀₃, R₂₀₄, R₂₁₁, and R₂₁₂ may each independently be selected from

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group; and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group, each substituted with at least one selected from a deuterium, —F, —Cl, —Br, —I, a hydroxyl group, a cyano group, a nitro group, an amino group, an amidino group, a hydrazine group, a hydrazone group, carboxylic acid a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group;

R₂₁₃ and R₂₁₄ may each independently be selected from

a C₁-C₂₀ alkyl group and a C₁-C₂₀ alkoxy group;

a C₁-C₂₀ alkyl group and a C₁-C₂₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group;

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group; and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group;

R₂₁₅ and R₂₁₆ may each independently be selected from

a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, and C₁-C₂₀ alkoxy group;

a C₁-C₂₀ alkyl group and a C₁-C₂₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group;

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, and a triazinyl group; and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group and a triazinyl group; and

xa5 may be 1 or 2.

R₂₁₃ and R₂₁₄ in Formulae 201A and 201A-1 may be linked to each other to form a saturated or unsaturated ring.

The compound represented by Formula 201 and/or the compound represented by Formula 202 may include one of the following Compounds HT1 to HT20.

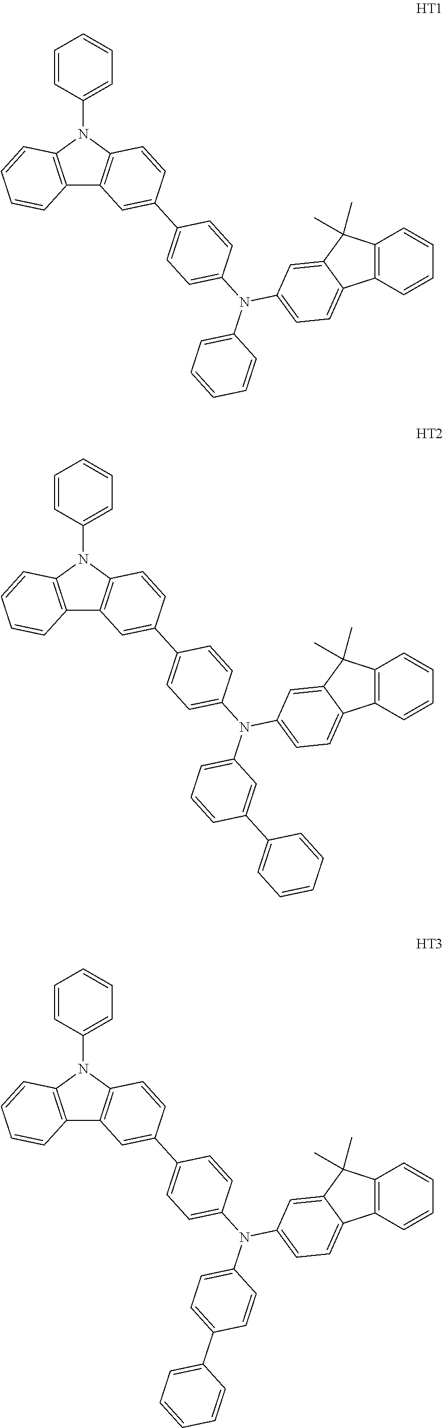 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

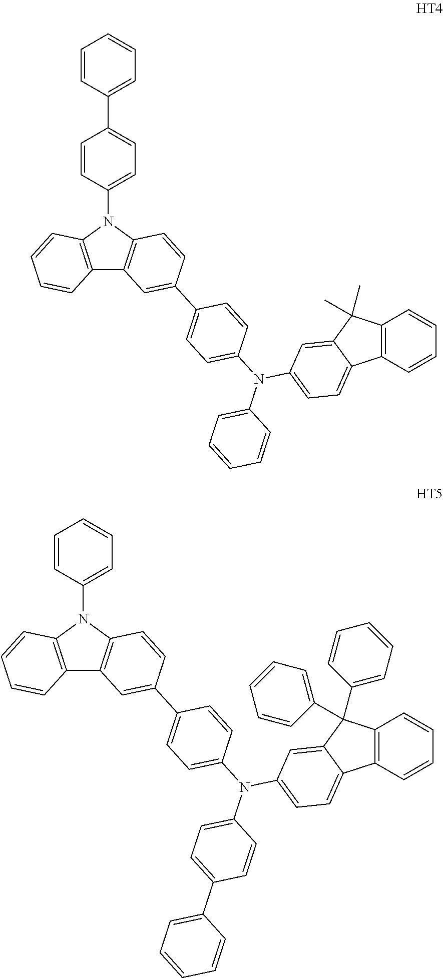 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

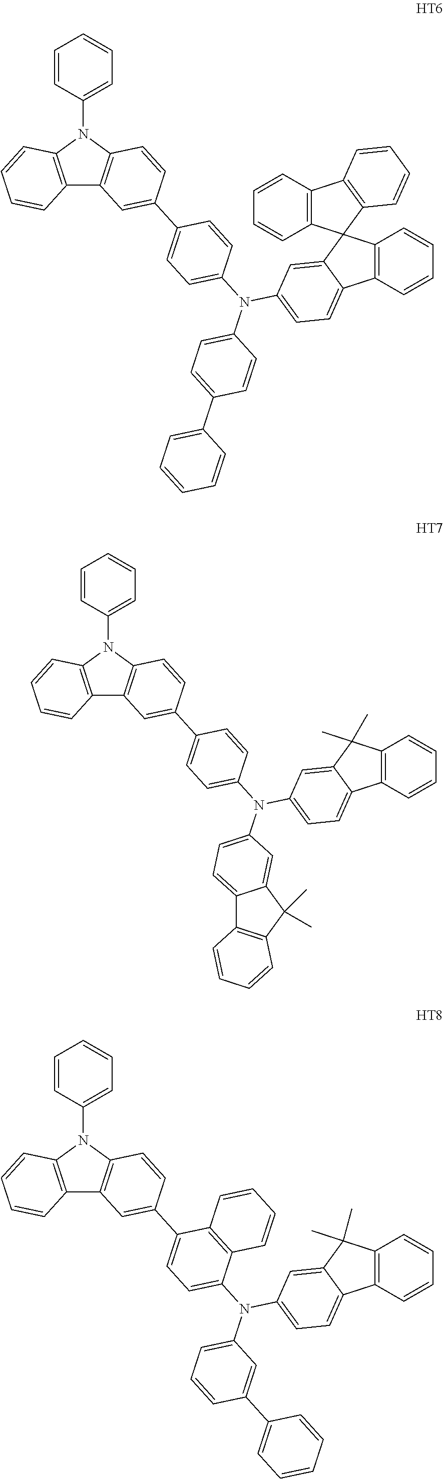 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3cccc(-c4ccccc4)c3)c3ccc(-c4ccc5c(c4)c4ccccc4n5-c4ccccc4)c4ccccc34)cc21]

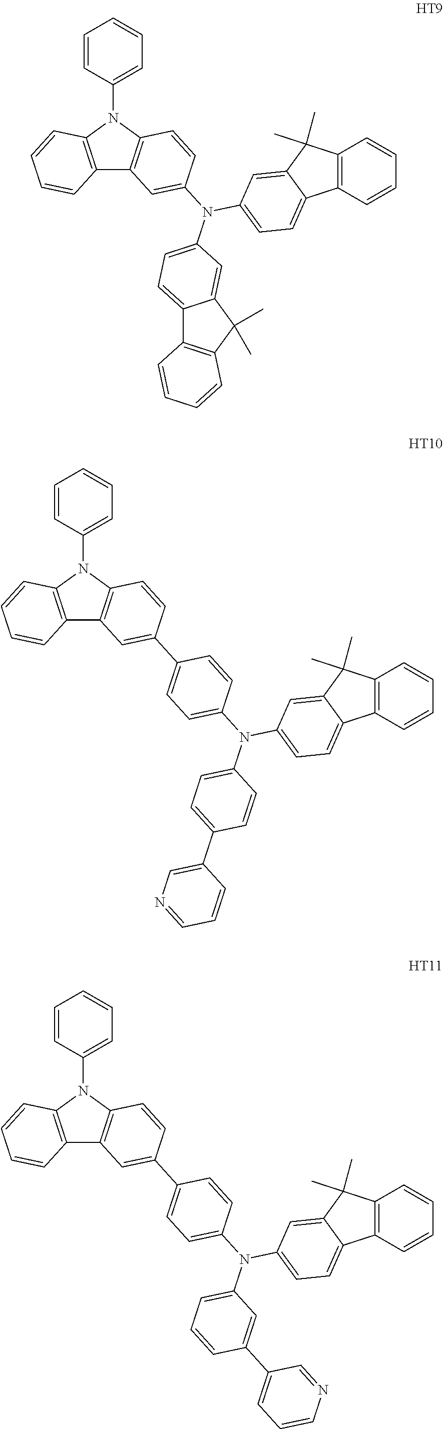 [SMILES: CC1(C)c2ccccc2-c2ccc(N(c3ccc4c(c3)C(C)(C)c3ccccc3-4)c3ccc4c(c3)c3ccccc3n4-c3ccccc3)cc21 ; CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21]

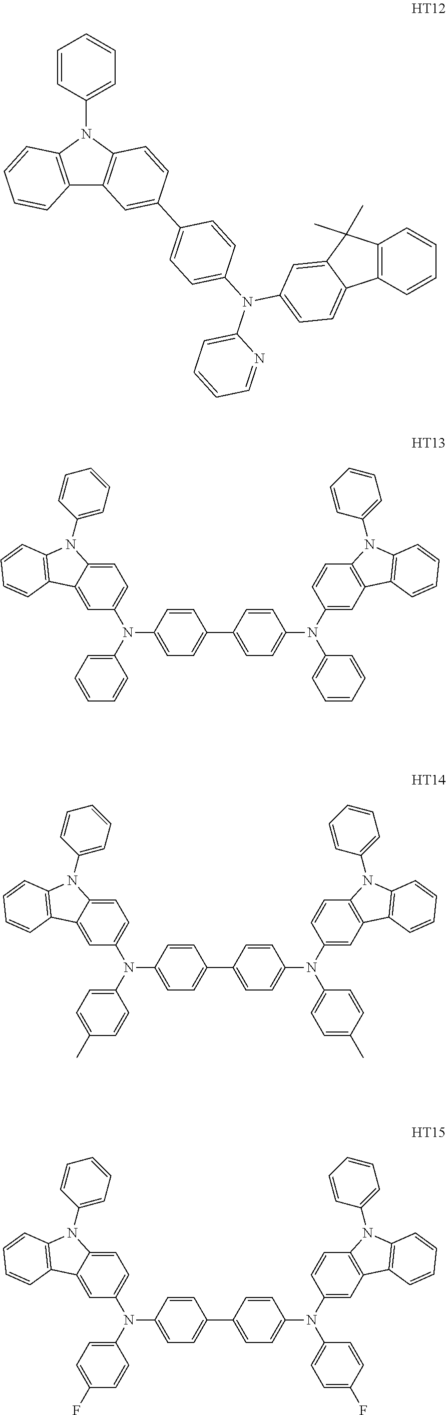 [SMILES: CC1(C)c2ccccc2-c2ccc(N(c3ccc(-c4ccc5c(c4)c4ccccc4n5-c4ccccc4)cc3)c3ccccn3)cc21 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1]

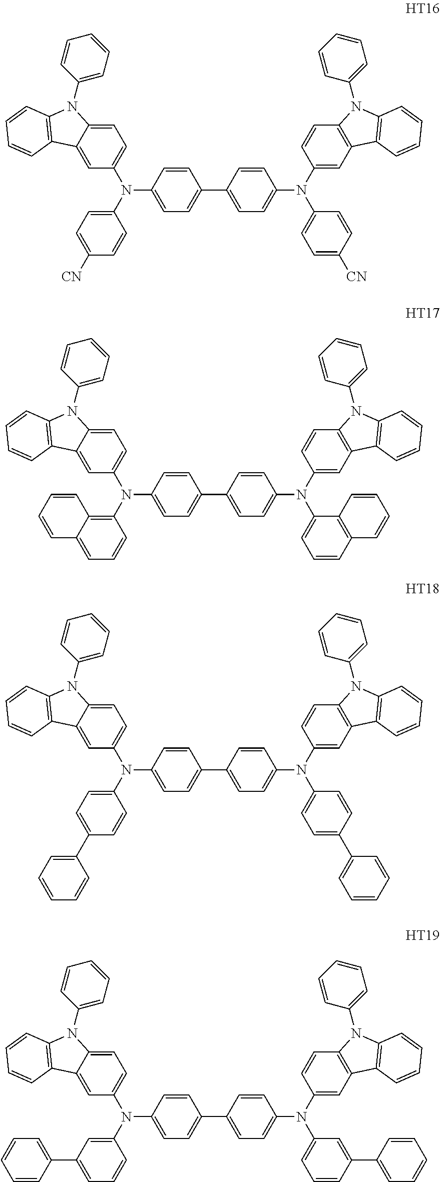

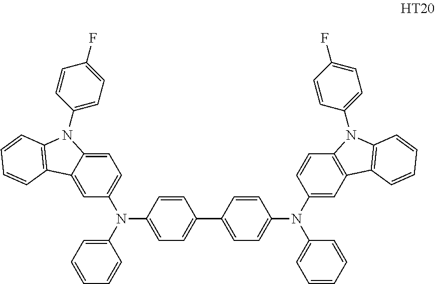 [SMILES: Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

A thickness of the hole transport region may be in a range of about 100 Å to about 10,000 Å, e.g., about 100 Å to about 1,000 Å. When the hole transport region includes a hole injection layer and a hole transport layer, the thickness of the hole injection layer may be in a range of about 100 Å to about 10,000 Å, e.g., about 100 Å to about 1000 Å, and the thickness of the hole transport layer may be in a range of about 50 Å to about 2,000 Å, e.g., about 100 Å to about 1,500 Å. When the thicknesses of the hole transport region, the hole injection layer, and the hole transport layer are within these ranges, excellent hole transport characteristics may be obtained without a substantial increase in driving voltage.

The hole transport region may further include, in addition to the mentioned materials above, a charge-generating material to improve conductive properties. The charge-generating material may be homogeneously or non-homogeneously dispersed throughout the hole transport region.

The charge-generating material may be, e.g., a p-dopant. The p-dopant may be one selected from a quinone derivative, a metal oxide, and a cyano group-containing compound. For example, non-limiting examples of the p-dopant are a quinone derivative, such as tetracyanoquinonedimethane (TCNQ) or 2,3,5,6-tetrafluoro-tetracyano-1,4-benzoquinonedimethane (F4-TCNQ); a metal oxide, such as a tungsten oxide or a molybdenum oxide, and Compound HT-D1 illustrated below.

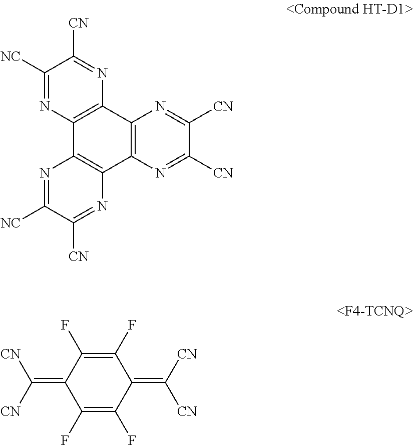

The hole transport region may further include, in addition to the hole injection layer and the hole transport layer, at least one selected from a buffer layer and an electron blocking layer. Since the buffer layer may compensate for an optical resonance distance according to a wavelength of light emitted from the emission layer, light-emission efficiency of a formed organic light-emitting device may be improved. As a material included in the buffer layer, materials that are included in the hole transport region may be used. The electron blocking layer prevents injection of electrons from the electron transport region.

For example, a material for the electron blocking layer may be, e.g., mCP.

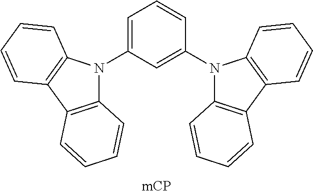 [SMILES: c1cc(-n2c3ccccc3c3ccccc32)cc(-n2c3ccccc3c3ccccc32)c1]

The electron transport region may include at least one selected from a hole blocking layer, an ETL, and an electron injection layer.

For example, the electron transport region may have a structure of electron transport layer/electron injection layer or a structure of hole blocking layer/electron transport layer/electron injection layer, wherein layers of each structure are sequentially stacked from the emission layer in the stated order.

The electron transport region may include a hole blocking layer. In the case that the emission layer includes a phosphorescent dopant, the hole blocking layer may be formed to prevent diffusion of excitons or holes into an electron transport layer.

When the electron transport region includes a hole blocking layer, the hole blocking layer may be formed on the emission layer by using a suitable method, e.g., vacuum-deposition, spin coating, casting, LB method, ink-jet printing, laser-printing, or LITI. When the hole blocking layer is formed by vacuum-deposition or spin coating, deposition and coating conditions for the hole blocking layer may be determined by referring to the deposition and coating conditions for the hole injection layer.

The hole blocking layer may include, e.g., at least one selected from BCP and Bphen:

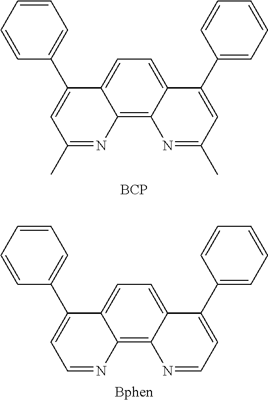

A thickness of the hole blocking layer may be in a range of about 20 Å to about 1,000 Å, e.g., about 30 Å to about 300 Å. When the thickness of the hole blocking layer is within this range, excellent hole blocking characteristics may be obtained without a substantial increase in driving voltage.

The electron transport region may include an electron transport layer. The electron transport layer may be formed on the emission layer or the hole blocking layer by using a suitable method, e.g., vacuum deposition, spin coating, casting, LB method, ink-jet printing, laser-printing, or LITI. When the electron transport layer is formed by using vacuum deposition or spin coating, vacuum deposition and coating conditions for the electron transport layer may be determined by referring to the vacuum deposition and coating conditions for the hole injection layer.

The electron transport layer may include at least one selected from BCP, Bphen, Alq₃, BAlq, TAZ, and NTAZ.

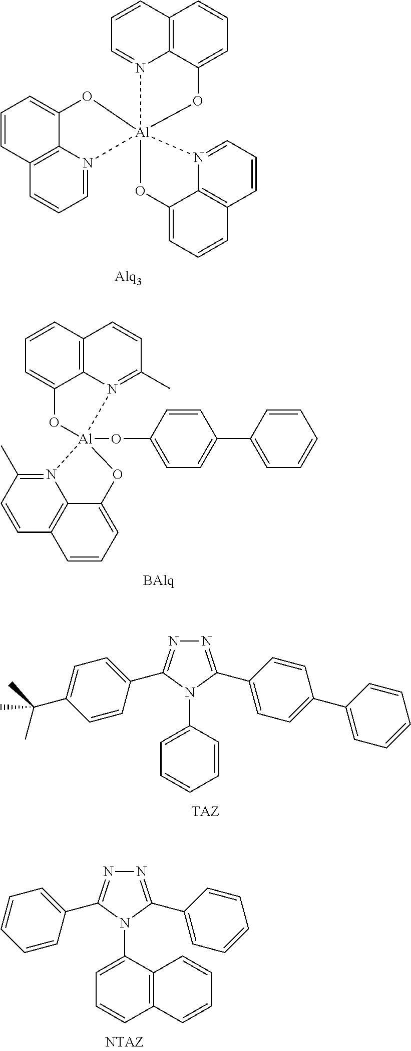

In some embodiments, the electron transport layer may include at least one compound selected from a compound represented by Formula 601 and a compound represented by Formula 602 illustrated below:

Ar₆₀₁-[(L₆₀₁)ₓₑ₁-E₆₀₁]ₓₑ₂ <Formula 601>

in Formula 601,

Ar₆₀₁ may be selected from

a naphthalene, a heptalene, a fluorene, a spiro-fluorene, a benzofluorene, a dibenzofluorene, a phenalene, a phenanthrene, an anthracene, a fluoranthene, a triphenylene, a pyrene, a chrysene, naphthacene, a picene, a perylene, a pentaphene, and an indenoanthracene;

a naphthalene, a heptalene, a fluorene, a spiro-fluorene, a benzofluorene, a dibenzofluorene, a phenalene, a phenanthrene, an anthracene, a fluoranthene, a triphenylene, a pyrene, a chrysene, naphthacene, a picene, a perylene, a pentaphene, and an indenoanthracene, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, and —Si(Q₃₀₁)(Q₃₀₂)(Q₃₀₃) (wherein Q₃₀₁ to Q₃₀₃ may be each independently selected from a hydrogen, C₁-C₆₀ alkyl group, a C₂-C₆₀ alkenyl group, a C₆-C₆₀ aryl group, and a C₁-C₆₀ heteroaryl group);

descriptions of L₆₀₁ may be understood by referring to the descriptions provided in connection with L₂₀₁;

E₆₀₁ may be selected from

a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazopyridinyl group, an imidazopyrimidinyl group; and

a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazopyridinyl group, and an imidazopyrimidinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazopyridinyl group, and an imidazopyrimidinyl group;

xe1 is selected from 0, 1, 2, and 3;

xe2 is selected from 1, 2, 3, and 4.

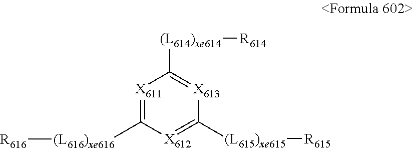

wherein in Formula 602,

X₆₁₁ may be N or C-(L₆₁₁)ₓₑ₆₁₁-R₆₁₁, X₆₁₂ may be N or C-(L₆₁₂)ₓₑ₆₁₂-R₆₁₂, X₆₁₃ may be N or C-(L₆₁₃)ₓₑ₆₁₃-R₆₁₃, at least one selected from X₆₁₁ to X₆₁₃ may be N;

descriptions L₆₁₁ to L₆₁₆ may be understood by referring to the descriptions provided in connection with L₂₀₁;

R₆₁₁ to R₆₁₆ may each independently be selected from

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group; and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group;

xe611 to xe616 may each independently be selected from 0, 1, 2, and 3.

The compound represented by Formula 601 and/or the compound represented by Formula 602 may each be selected from Compounds ET1 to ET15 illustrated below:

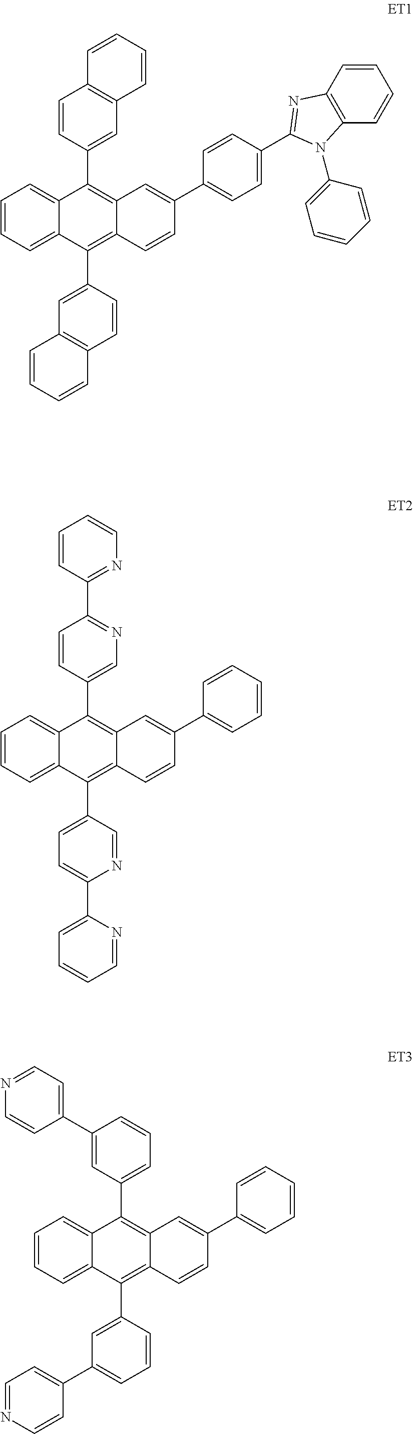 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

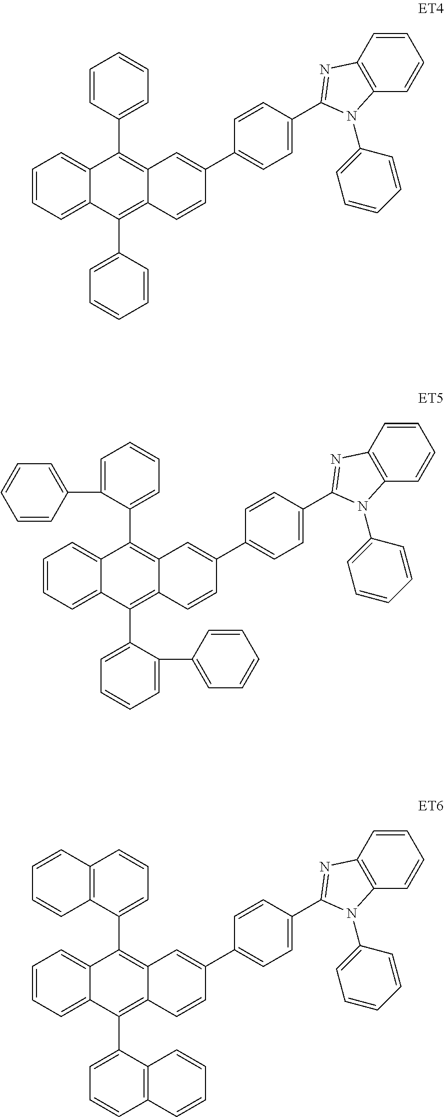 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

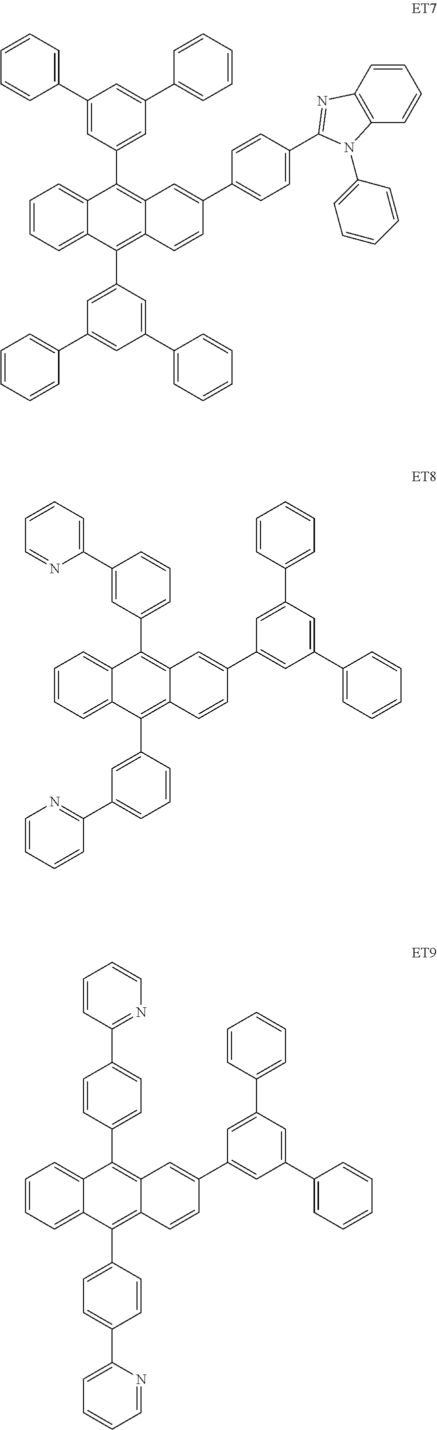 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

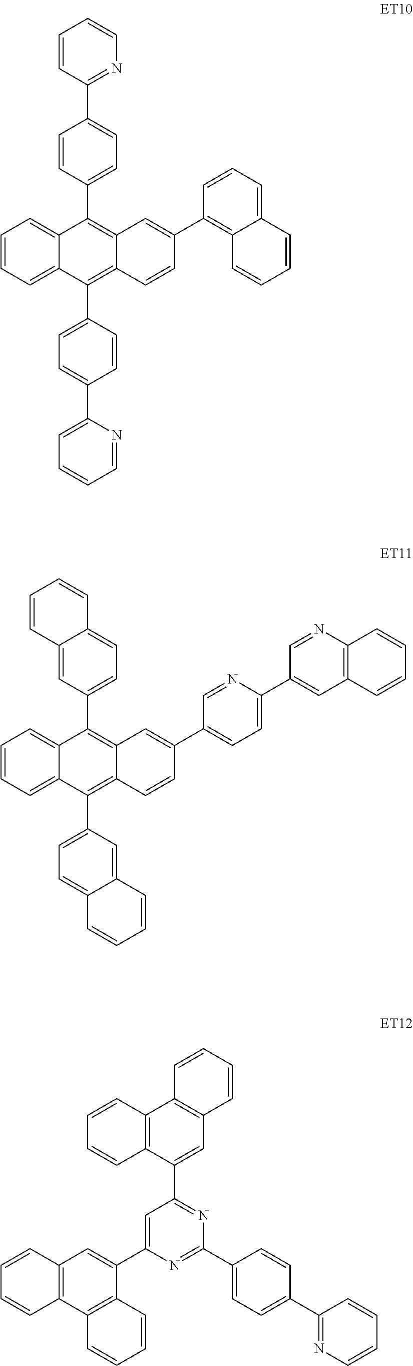 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-c2ccc(-c3nc(-c4cc5ccccc5c5ccccc45)cc(-c4cc5ccccc5c5ccccc45)n3)cc2)nc1]

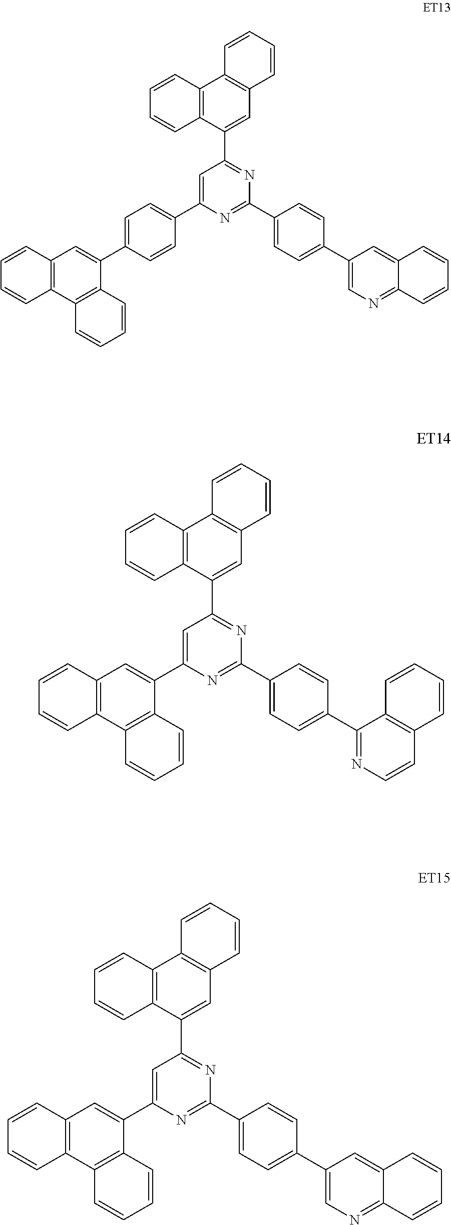 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)cc(-c5cc6ccccc6c6ccccc56)n4)cc3)cc2c1]

A thickness of the electron transport layer may be in a range of about 100 Å to about 1,000 Å, e.g., about 150 Å to about 500 Å. When the thickness of the electron transport layer is within this range, excellent electron transport characteristics may be obtained without a substantial increase in driving voltage.

The electron transport layer may further include a metal-containing material in addition to the materials described above.

The metal-containing material may be a Li complex. The Li complex may be, for example, Compound ET-D1 (lithium quinolate, LiQ) or ET-D2.

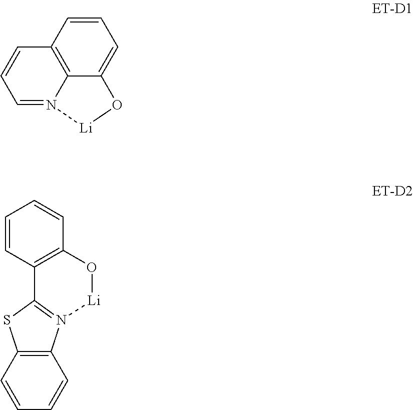

The electron transport region may include an electron injection layer that facilitates electron injection from the second electrode 190.

The electron injection layer may be formed on the electron transport layer by using a suitable method, e.g., vacuum-deposition, spin coating, casting, LB method, ink-jet printing, laser-printing, or LITI. When the electron injection layer is formed by vacuum-deposition or spin coating, vacuum-deposition and coating conditions for the electron injection layer may be determined by referring to the vacuum-deposition and coating conditions for the hole injection layer.

The electron injection layer may include at least one selected from, LiF, NaCl, CsF, Li₂O, BaO, and LiQ.

A thickness of the electron injection layer may be in a range of about 1 Å to about 100 Å, e.g., about 3 Å to about 90 Å. When the thickness of the electron injection layer is within this range, excellent electron injection characteristics may be obtained without a substantial increase in driving voltage.

The second electrode 190 may be disposed on the organic layer 150. The second electrode 190 may be a cathode that is an electron injection electrode, and in this regard, a material for forming the second electrode 190 may be a material having a low work function, and such a material may be metal, alloy, an electrically conductive compound, or a mixture thereof. Examples of the material for the second electrode 190 may include lithium (Li), magnesium (Mg), aluminum (Al), aluminum-lithium (Al—Li), calcium (Ca), magnesium-indium (Mg—In), and magnesium-silver (Mg—Ag). In some embodiments, the material for forming the second electrode 190 may be ITO or IZO. The second electrode 190 may be a reflective electrode, a semi-transmissive electrode, or a transmissive electrode.

Hereinbefore, the organic light-emitting device has been described with reference to FIG. 1.

A C₁-C₆₀ alkyl group as used herein refers to a linear or branched aliphatic hydrocarbon monovalent group having 1 to 60 carbon atoms, and detailed examples thereof are a methyl group, an ethyl group, a propyl group, an iso-butyl group, a sec-butyl group, a tert-butyl group, a pentyl group, an iso-amyl group, and a hexyl group. A C₁-C₆₀ alkylene group as used herein refers to a divalent group having the same structure as a C₁-C₆₀ alkyl group.

A C₁-C₆₀ alkoxy group as used herein refers to a monovalent group represented by —OA₁₀₁ (wherein Al₁₀₁ is the C₁-C₆₀ alkyl group), and detailed examples thereof are a methoxy group, an ethoxy group and an isopropyloxy group.

A C₂-C₆₀ alkenyl group as used herein refers to a hydrocarbon group formed by substituting at least one carbon double bond in the middle or at the terminal of the C₂-C₆₀ alkyl group, and detailed examples thereof are an ethenyl group, a propenyl group, and a butenyl group. A C₂-C₆₀ alkenylene group as used herein refers to a divalent group having the same structure as a C₂-C₆₀ alkenyl group.

A C₂-C₆₀ alkynyl group as used herein refers to a hydrocarbon group formed by substituting at least one carbon triple bond in the middle or at the terminal of the C₂-C₆₀ alkyl group, and detailed examples thereof are an ethynyl group and a propynyl group. A C₂-C₆₀ alkynylene group as used herein refers to a divalent group having the same structure as a C₂-C₆₀ alkynyl group.

A C₃-C₁₀ cycloalkyl group as used herein refers to a monovalent monocyclic saturated hydrocarbon group including 3 to 10 carbon atoms, and detailed examples thereof are a cyclopropyl group, a cyclobutyl group, a cyclopentyl group, a cyclohexyl group, and a cycloheptyl group. A C₃-C₁₀ cycloalkylene group as used herein refers to a divalent group having the same structure as a C₃-C₁₀ cycloalkyl group.

A C₁-C₁₀ heterocycloalkyl group as used herein refers to a monovalent monocyclic group including at least one hetero atom selected from N, O, P, and S as a ring-forming atom and 1 to 10 carbon atoms. Examples thereof are a tetrahydrofuranyl group and a tetrahydrothiophenyl group. A C₁-C₁₀ heterocycloalkylene group as used herein refers to a divalent group having the same structure as a C₁-C₁₀ heterocycloalkyl group.

A C₃-C₁₀ cycloalkenyl group as used herein refers to a monovalent monocyclic group that has 3 to 10 carbon atoms and at least one double bond in its ring, and which is not aromatic. Examples thereof are a cyclopentenyl group, a cyclohexenyl group, and a cycloheptenyl group. A C₃-C₁₀ cycloalkenylene group as used herein refers to a divalent group having the same structure as a C₃-C₁₀ cycloalkenyl group.

A C₁-C₁₀ heterocycloalkenyl group as used herein refers to a monovalent monocyclic group including at least one hetero atom selected from N, O, P, and S as a ring-forming atom, 1 to 10 carbon atoms, and at least one double bond in its ring. Examples of the C₁-C₁₀ heterocycloalkenyl group are 2,3-dihydrofuranyl group and 2,3-dihydrohiophenyl group. A C₁-C₁₀ heterocycloalkenylene group as used herein refers to a divalent group having the same structure as a C₁-C₁₀ heterocycloalkenyl group.

A C₆-C₆₀ aryl group as used herein refers to a monovalent group including a carbocyclic aromatic system having 6 to 60 carbon atoms, and a C₆-C₆₀ arylene group as used herein refers to a divalent group including a carbocyclic aromatic system having 6 to 60 carbon atoms. Examples of the C₆-C₆₀ aryl group are a phenyl group, a naphthyl group, an anthracenyl group, a phenanthrenyl group, a pyrenyl group, and a chrysenyl group. When the C₆-C₆₀ aryl group and the C₆-C₆₀ arylene group each include a plurality of rings, the rings may be fused to each other.

A C₁-C₆₀ heteroaryl group as used herein refers to a monovalent group having a carbocyclic aromatic system including at least one hetero atom selected from N, O, P, and S as a ring-forming atom and 1 to 60 carbon atoms. A C₁-C₆₀ heteroarylene group as used herein refers to a divalent group having a carbocyclic aromatic system including at least one hetero atom selected from N, O, P, and S as a ring-forming atom and 1 to 60 carbon atoms. Examples of the C₁-C₆₀ heteroaryl group are a pyridinyl group, a pyrimidinyl group, a pyrazinyl group, a pyridazinyl group, a triazinyl group, a quinolinyl group, and an isoquinolinyl group. When the C₁-C₆₀ heteroaryl group and the C₁-C₆₀ heteroarylene group each include a plurality of rings, the rings may be fused to each other.

A C₆-C₆₀ aryloxy group as used herein indicates —OA₁₀₂ (wherein A₁₀₂ is the C₆-C₆₀ aryl group), and a C₆-C₆₀ arylthio group as used herein indicates —SA₁₀₃ (wherein A₁₀₃ is the C₆-C₆₀ aryl group).

A monovalent non-aromatic condensed polycyclic group as used herein refers to a monovalent group that has two or more rings condensed to each other, only carbon atoms (for example, the number of carbon atoms may be in a range of 8 to 60) as ring forming atoms, wherein the molecular structure as a whole is non-aromatic in the entire molecular structure. A detailed example of the monovalent non-aromatic condensed polycyclic group is a fluorenyl group. A divalent non-aromatic condensed polycyclic group as used herein refers to a divalent group having the same structure as the monovalent non-aromatic condensed polycyclic group.

A monovalent non-aromatic condensed heteropolycyclic group as used herein refers to a monovalent group that has two or more rings condensed to each other, has a hetero atom selected from N, O P, and S, other than carbon atoms (for example, the number of carbon atoms may be in a range of 1 to 60), as ring-forming atoms, wherein the molecular structure as a whole is non-aromatic in the entire molecular structure. The monovalent non-aromatic condensed heteropolycyclic group includes a carbazolyl group. A divalent non-aromatic condensed hetero-polycyclic group as used herein refers to a divalent group having the same structure as the monovalent non-aromatic condensed hetero-polycyclic group.

At least one of substituents of the substituted C₃-C₁₀ cycloalkylene group, substituted C₁-C₁₀ heterocycloalkylene group, substituted C₃-C₁₀ cycloalkenylene group, substituted C₁-C₁₀ heterocycloalkenylene group, substituted C₆-C₆₀ arylene group, substituted C₁-C₆₀ heteroarylene group, substituted divalent non-aromatic condensed polycyclic group, substituted divalent non-aromatic condensed heteropolycyclic group, substituted C₁-C₆₀ alkyl group, substituted C₂-C₆₀ alkenyl group, substituted C₂-C₆₀ alkynyl group, substituted C₁-C₆₀ alkoxy group, substituted C₃-C₁₀ cycloalkyl group, substituted C₁-C₁₀ heterocycloalkyl group, substituted C₃-C₁₀ cycloalkenyl group, substituted C₁-C₁₀ heterocycloalkenyl group, substituted C₆-C₆₀ aryl group, substituted C₆-C₆₀ aryloxy group, substituted C₆-C₆₀ arylthio group, substituted C₁-C₆₀ heteroaryl group, substituted monovalent non-aromatic condensed polycyclic group, and substituted monovalent non-aromatic condensed heteropolycyclic group used herein may be selected from

a C₁-C₆₀ alkyl group, a C₂-C₆₀ alkenyl group, a C₂-C₆₀ alkynyl group, and a C₁-C₆₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group(aryloxy), C₆-C₆₀ arylthio group(arylthio), C₁-C₆₀ heteroaryl group, a monovalent non-aromatic condensed polycyclic group, a monovalent non-aromatic condensed heteropolycyclic group, —Si(Q₁₁)(Q₁₂)(Q₁₃), —B(Q₁₄)(Q₁₅), and —N(Q₁₆)(Q₁₇);

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group and a monovalent non-aromatic condensed heteropolycyclic group;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₂₁)(Q₂₂)(Q₂₃), —B(Q₂₄)(Q₂₅), and —N(Q₂₆)(Q₂₇); and

—Si(Q₃₁)(Q₃₂)(Q₃₃), —B(Q₃₄)(Q₃₅) and —N(Q₃₆)(Q₃₇),

wherein Q₁₁ to Q₁₇, Q₂₁ to Q₂₇ and Q₃₁ to Q₃₇ may be each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group.

For example, at least one of substituents of the substituted C₃-C₁₀ cycloalkylene group, substituted C₁-C₁₀ heterocycloalkylene group, substituted C₃-C₁₀ cycloalkenylene group, substituted C₁-C₁₀ heterocycloalkenylene group, substituted C₆-C₆₀ arylene group, substituted C₁-C₆₀ heteroarylene group, substituted divalent non-aromatic condensed polycyclic group, substituted divalent non-aromatic condensed heteropolycyclic group, substituted C₁-C₆₀ alkyl group, substituted C₂-C₆₀ alkenyl group, substituted C₂-C₆₀ alkynyl group, substituted C₁-C₆₀ alkoxy group, substituted C₃-C₁₀ cycloalkyl group, substituted C₁-C₁₀ heterocycloalkyl group, substituted C₃-C₁₀ cycloalkenyl group, substituted C₁-C₁₀ heterocycloalkenyl group, substituted C₆-C₆₀ aryl group, substituted C₆-C₆₀ aryloxy group, substituted C₆-C₆₀ arylthio group, substituted C₁-C₆₀ heteroaryl group, substituted monovalent non-aromatic condensed polycyclic group and substituted monovalent non-aromatic condensed heteropolycyclic group may be selected from

a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₂-C₆₀ alkenyl group, a C₂-C₆₀ alkynyl group, and C₁-C₆₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a cyclopentyl group, a cyclohexyl group, a cycloheptyl group, a cyclopentenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazopyridinyl group, an imidazopyrimidinyl group, —N(Q₁₁)(Q₁₂), —B(Q₁₃)(Q₁₄), and —Si(Q₁₅)(Q₁₆)(Q₁₇);

a cyclopentyl group, a cyclohexyl group, a cycloheptyl group, a cyclopentenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazopyridinyl group, and an imidazopyrimidinyl group;

a cyclopentyl group, a cyclohexyl group, a cycloheptyl group, a cyclopentenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazopyridinyl group, and an imidazopyrimidinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a cyclopentyl group, a cyclohexyl group, a cycloheptyl group, a cyclopentenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazopyridinyl group, an imidazopyrimidinyl group, —N(Q₂₁)(Q₂₂), —B(Q₂₃)(Q₂₄), and —Si(Q₂₅)(Q₂₆)(Q₂₇); and

—N(Q₃₁)(Q₃₂), —B(Q₃₃)(Q₃₄) and —Si(Q₃₅)(Q₃₆)(Q₃₇),

wherein Q₁₁ to Q₁₇, Q₂₁ to Q₂₇ and Q₃₁ to Q₃₇ may be each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a cyclopentyl group, a cyclohexyl group, a cycloheptyl group, a cyclopentenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazopyridinyl group, an imidazopyrimidinyl group.

In the present specification, “Ph” indicates a phenyl group, “Me” indicates a methyl group, “Et” indicates an ethyl group, and “ter-Bu” or “Bu^{t}” indicates a tert-butyl group.

Hereinafter, an organic light-emitting device according to one or more embodiments will be described in detail with reference to Synthesis Examples and Examples. However, these examples are for illustrative purposes only and are not intended to limit the scope of the embodiments. The wording “B was used instead of A” used in Synthesis Examples indicate that a molar equivalent of A equals a molar equivalent of B.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### EXAMPLE

### Synthesis Example 1

### Synthesis of Compound 1

Compound 1 was synthesized according to Reaction Scheme 1:

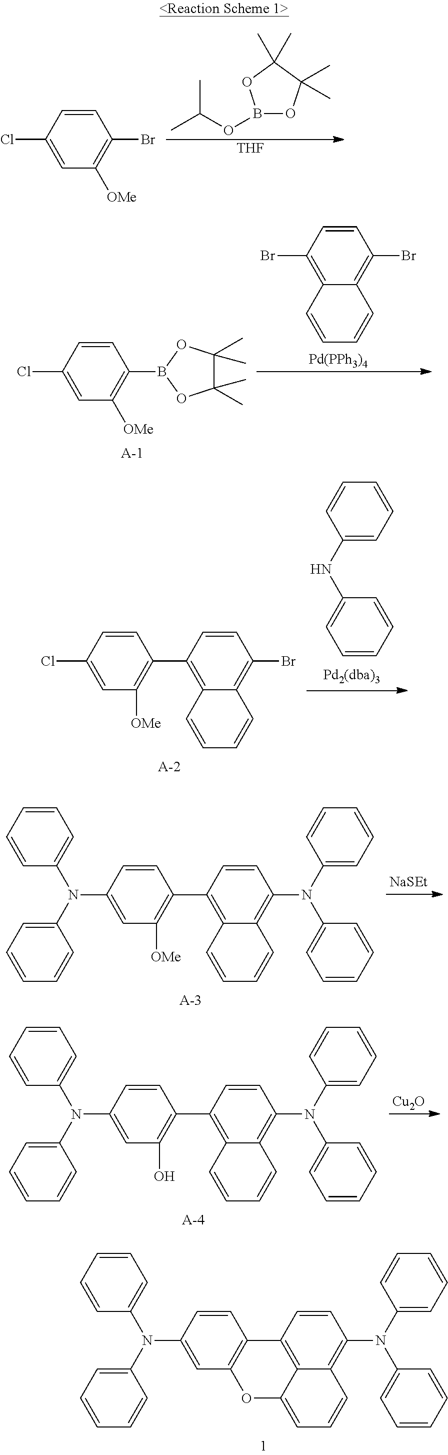

Synthesis of Intermediate A-1

6.4 g (30 mmol) of 2-bromo-5-chloroanisole was dissolved in 150 ml of THF, and then, at a temperature of −78° C., 12 mL (30.0 mmol, 2.5 M in hexane) of n-BuLi was slowly added dropwise thereto. At the same temperature, the result was stirred for 1 hour, and then, 6.7 mL (36.0 mmol) of 2-isoproxy-4,4,5,5,-tetramethyl-1,3,2-dioxaborolane was slowly added dropwise thereto, and the reaction solution was stirred at a temperature of −78° C. for 1 hour, and additionally stirred for 24 hours at ambient temperature. Once the reaction was completed, 50 mL of 10% HCl aqueous solution and 50 mL of H₂O was added thereto, and then, subjected to an extraction process three times by using 80 mL of diethyl ether. An organic layer separated therefrom was dried by using magnesium sulfate, and the residual obtained by evaporating a solvent therefrom was separation-purified by silica gel column chromatography to obtain 7.25 g (yield of 90%) of Intermediate A-1. The synthesized compound was confirmed by LC-MS.

C₁₃H₁₈BClO₃: M⁺ 268.1

Synthesis of Intermediate A-2

7.25 g (27.0 mmol) of Intermediate A-1, 11.6 g (40.5 mmol) of 1,4-dibromo naphthalene, 1.27 g (1.1 mmol) of Pd(PPh₃)₄(tetrakis(triphenylphosphine)palladium), and 6.82 g (50 mmol) of K₂CO₃ were dissolved in 200 ml of THF/H₂O (a volumetric ratio of 9/1) mixed solution, and then, stirred at a temperature of 70° C. for 5 hours. The reaction solution was cooled at ambient temperature, and then, 60 ml of water was added thereto, and the result was subjected to an extraction process three times using 60 ml of ethyl ether. An organic layer separated therefrom was dried by using magnesium sulfate, and the residual obtained by evaporating a solvent therefrom was separation-purified by silica gel column chromatography to obtain 7.65 g (yield of 81.5%) of Intermediate A-2. The synthesized compound was confirmed by LC-MS.

C₁₇H₁₂ BrClO: M⁺ 345.9

Synthesis of Intermediate A-3

1.74 g (5 mmol) of Intermediate A-2, 2.1 g (15 mmol) of diphenylamine, 0.45 g (0.5 mmol) of Pd₂(dba)₃, 0.1 g (0.5 mmol) of PtBu₃, and 2.25 g (20.0 mmol) of KOtBu were dissolved in 50 ml of toluene, and the mixture was stirred at a temperature of 85° C. for 4 hours. The reaction solution was cooled at ambient temperature, and then, subjected to an extraction process three times by using 50 mL of water and 50 mL of diethyl ether. An organic layer separated therefrom was dried by using magnesium sulfate, and the residual obtained by evaporating a solvent therefrom was separation-purified by silica gel column chromatography to obtain 2.47 g (yield of 87%) of Intermediate A-3. The synthesized compound was confirmed by LC-MS.

C₄₁H₃₂N₂O: M⁺ 568.2

Synthesis of Intermediate A-4

2.47 g (4.35 mmol) of Intermediate A-3 was dissolved in 50 ml of DMF, and then, stirred together with 0.73 g (8.7 mmol) of sodium ethanethiolate for 24 hours at a temperature of 160° C. Once the reaction was completed, and then, subjected to an extraction process three times by using 10 mL of H₂O and 20 mL of diethyl ether. An organic layer separated therefrom was dried by using magnesium sulfate, and the residual obtained by evaporating a solvent therefrom was separation-purified by silica gel column chromatography to obtain 2.27 g (yield of 94%) of Intermediate A-4. The synthesized compound was confirmed by LC-MS.

C₄₀H₃₀N₂O: M⁺ 554.2

Synthesis of Compound 1

2.27 g (4.1 mmol) of Intermediate A-4 was dissolved in 30 ml of DMF, and then, at ambient temperature, 1.76 g (12.3 mmol) of Cu₂O was added dropwise thereto. The reaction solution was stirred at a temperature of 190° C. for 48 hours. Once the reaction as completed, the reaction product was filtered by using Celite, and an organic layer obtained therefrom was subjected to an extraction process three times by using 10 mL of H₂O and 30 mL of ethyl acetate. An organic layer separated therefrom was dried by using magnesium sulfate, and the residual obtained by evaporating a solvent therefrom was separation-purified by silica gel column chromatography to obtain 1.63 g (yield of 72%) of Compound 1. The synthesized compound was confirmed by LC-MS and NMR.

C₄₀H₂₈N₂O: M⁺ 552.2

### Synthesis Example 2

### Synthesis of Compound 15

Compound 15 was synthesized according to Reaction Scheme 2:

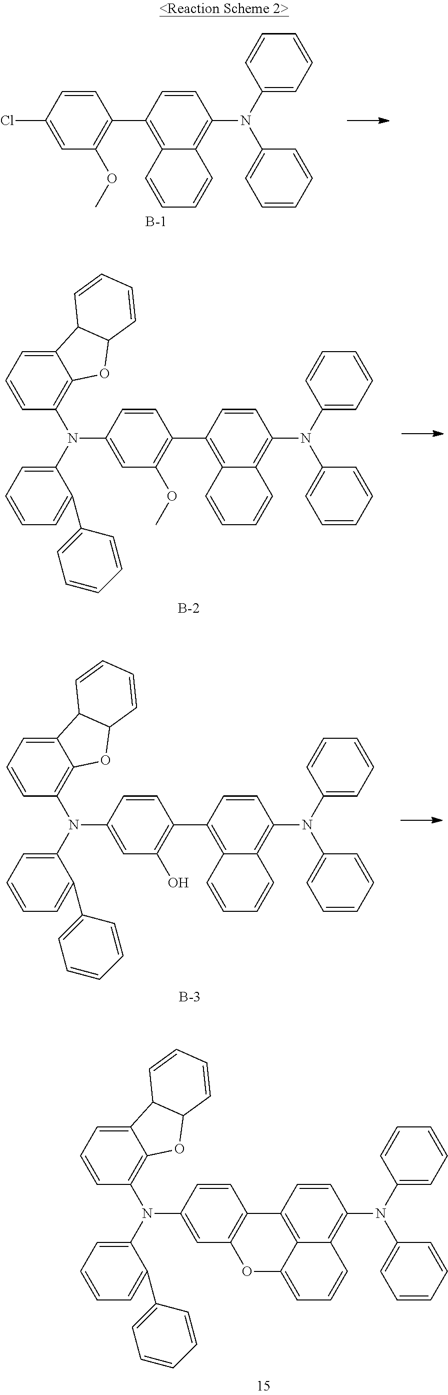

Synthesis of Intermediate B-1

1.74 g (5 mmol) of Intermediate A-2, 0.85 g (5 mmol) of diphenylamine, 0.23 g (0.25 mmol) of Pd₂(dba)₃, 0.05 g (0.25 mmol) of PtBu₃, and 1.12 g (10.0 mmol) of KOtBu were dissolved in 30 ml of toluene, and then, the mixture was stirred at a temperature of 85° C. for 4 hours. A reaction solution was cooled at ambient temperature, and then, subjected to an extraction process three times by using 30 mL of water and 30 mL of diethyl ether. An organic layer separated therefrom was dried by using magnesium sulfate, and the residual obtained by evaporating a solvent therefrom was separation-purified by silica gel column chromatography to obtain 2.00 g (yield of 92%) of Intermediate B-1. The synthesized compound was confirmed by LC-MS.

C₂₉H₂₂ClNO: M⁺ 435.1

Synthesis of Intermediate B-2

2.00 g (4.6 mmol) of Intermediate B-1, 2.01 g (6 mmol) of N-([1,1′-biphenyl]-2-yl)dibenzo[b,d]furan-4-amine, 0.23 g (0.25 mmol) of Pd₂(dba)₃, 0.05 g (0.25 mmol) of PtBu₃, and 1.12 g (10.0 mmol) of KOtBu were dissolved in 30 ml of toluene, and then, the mixture was stirred at a temperature of 85° C. for 4 hours. A reaction solution was cooled at ambient temperature, and then, subjected to an extraction process by using 30 mL of water and 30 mL of diethyl ether. An organic layer separated therefrom was dried by using magnesium sulfate, and the residual obtained by evaporating a solvent therefrom was separation-purified by silica gel column chromatography to obtain 3.16 g (yield of 93.5%) of Intermediate B-2. The synthesized compound was confirmed by LC-MS.

C₅₃H₃₈N₂O₂: M⁺ 734.3

Synthesis of Intermediate B-3

2.73 g (yield of 88.4%) Intermediate B-3 was synthesized in the same manner as used to synthesize Intermediate A-4 in Synthesis Example 1, except that Intermediate B-2 was used instead of Intermediate A-3. The synthesized compound was confirmed by LC-MS.

C₅₂H₃₆N₂O₂: M⁺ 720.3

Synthesis of Compound 15

1.87 g (yield of 68.4%) of Compound 15 was synthesized in the same manner as used to synthesize Compound 1 in Synthesis Example 1, except that Intermediate B-3 was used instead of Intermediate A-4. The synthesized compound was confirmed by LC-MS and NMR.

C₅₂H₃₄N₂O₂: M⁺ 718.3

### Synthesis Example 3

### Synthesis of Compound 40

Synthesis of Compound 40

1.94 g (yield of 71.1%) of Compound 40 was synthesized in the same manner as used to synthesize Compound 15 in Synthesis Example 2, except that N-phenylnaphthalen-2-amine was used instead of diphenylamine, and 9,9-dimethyl-N-phenyl-9H-fluoren-2-amine was used instead of N-([1,1′-biphenyl]-2-yl)dibenzo[b,d]furan-4-amine. The synthesized compound was confirmed by LC-MS and NMR.

C₅₃H₃₈N₂O: M⁺ 718.3

### Synthesis Example 4

### Synthesis of Compound 46

Synthesis of Compound 46

2.28 g (yield of 76%) of Compound 46 was synthesized in the same manner as used to synthesize Compound 1 in Synthesis Example 1, except that N-phenyldibenzo[b,d]furan-4-amine was used instead of diphenylamine. The synthesized compound was confirmed by LC-MS and NMR.

C₅₂H₃₂N₂O₃: M⁺ 732.2

### Synthesis Example 5

### Synthesis of Compound 69

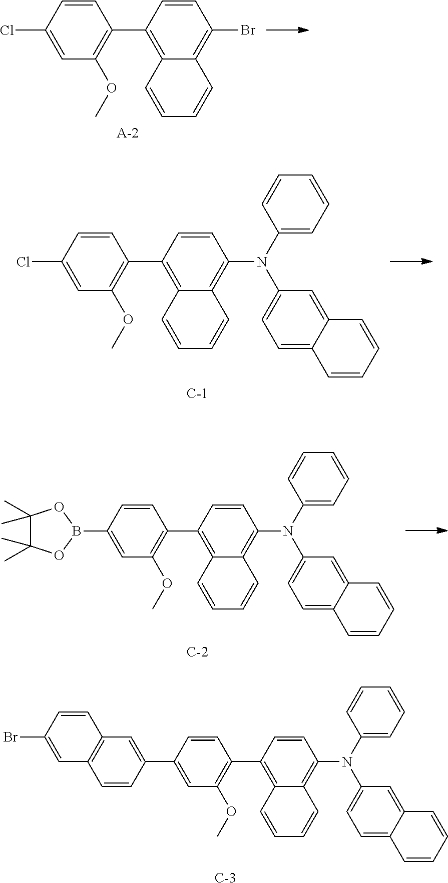

Synthesis of Intermediate C-1

2.19 g (yield of 90%) of Intermediate C-1 was synthesized in the same manner as used to synthesize Intermediate B-1 in Synthesis Example 1, except that N-phenylnaphthalen-2-amine was used instead of diphenylamine. The synthesized compound was confirmed by LC-MS.

C₃₃H₂₄ClNO: M⁺ 485.2

Synthesis of Intermediate C-2

2.19 g (4.5 mmol) of Intermediate C-1 was dissolved in 30 ml of THF, and then, at a temperature of −78° C., 2 mL (5.0 mmol, 2.5 M in hexane) of n-BuLi was slowly added dropwise thereto. At the same temperature, the result was stirred for 1 hour, and then, 1.1 mL (6.0 mmol) of 2-isoproxy-4,4,5,5,-tetramethyl-1,3,2-dioxaborolane was slowly added dropwise thereto. The reaction solution was stirred at a temperature of −78° C. for 1 hour, and then, additionally stirred at ambient temperature for 24 hours. Once the reaction was completed, 10 mL of 10% HCl aqueous solution and 10 mL of H₂O were added thereto, and then the resultant mixture was subjected to an extraction process three times by using 30 mL of diethyl ether. An organic layer obtained therefrom was dried by using magnesium sulfate, and the residual obtained by removing a solvent therefrom by evaporation was separation-purified by silica gel column chromatography to obtain 1.67 g (yield of 64%) of Intermediate C-2. The synthesized compound was confirmed by LC-MS.

C₃₉H₃₆BNO₃: M⁺ 577.3

Synthesis of Intermediate C-3

1.67 g (2.9 mmol) of Intermediate C-2, 1.43 g (5 mmol) of 2,6-dibromonaphthalene, 0.35 g (0.3 mmol) of Pd(PPh₃)₄ (tetrakis(triphenylphosphine)palladium), and 0.83 g (6 mmol) of K₂CO₃ were dissolved in 50 ml of a THF/H₂O (a volumetric ratio of 9/1) mixed solution, and then, the mixture was stirred at a temperature of 70° C. for 5 hours. The reaction solution was cooled at ambient temperature, and then, 30 ml of water was added thereto, and the result was subjected to an extraction process three times by using 30 ml of ethyl ether. An organic layer obtained therefrom was dried by using magnesium sulfate, and the residual obtained by removing a solvent therefrom by evaporation was separation-purified by silica gel column chromatography to obtain 1.45 g (yield of 76%) of Intermediate A-2. The synthesized compound was confirmed by LC-MS.

C₄₃H₃₀ BrNO: M⁺ 655.2

Synthesis of Compound 69

0.95 g (yield of 81%) of Compound 69 was synthesized in the same manner as used to synthesize Compound 15 in Synthesis Example 2, except that Intermediate C-3 was used instead of Intermediate B-1 and N-phenylnaphthalen-2-amine was used instead of N-([1,1′-biphenyl]-2-yl)dibenzo[b,d]furan-4-amine. The synthesized compound was confirmed by LC-MS and NMR.

C₅₈H₃₈N₂O: M⁺ 778.3

### Synthesis Example 6

### Synthesis of Compound 74

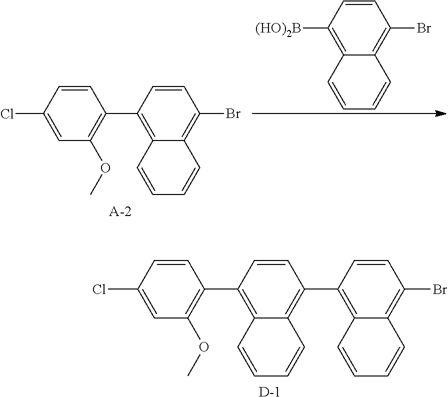

Synthesis of Intermediate D-1

1.83 g (yield of 64%) of Intermediate D-1 was synthesized in the same manner as used to synthesize Intermediate A-2 in Synthesis Example 1, except that Intermediate A-2 was used instead of Intermediate A-1 and (4-bromonaphthalen-1-yl)boronic acid was used instead of 1,4-dibromonaphthalene. The synthesized compound was confirmed by LC-MS.

C₂₇H₁₈ BrClO: M⁺ 472.0

Synthesis of Compound 74

1.39 g (yield of 83%) of Compound 74 was synthesized in the same manner as used to synthesize Compound 15 in Synthesis Example 2, except that Intermediate D-1 was used instead of Intermediate A-2 and 9,9-dimethyl-N-phenyl-9H-fluoren-2-amine was used instead of N-([1,1′-biphenyl]-2-yl)dibenzo[b,d]furan-4-amine. The synthesized compound was confirmed by LC-MS and NMR.

C₅₉H₄₂N₂O: M⁺ 794.3

### Synthesis Example 7

### Synthesis of Compound 76

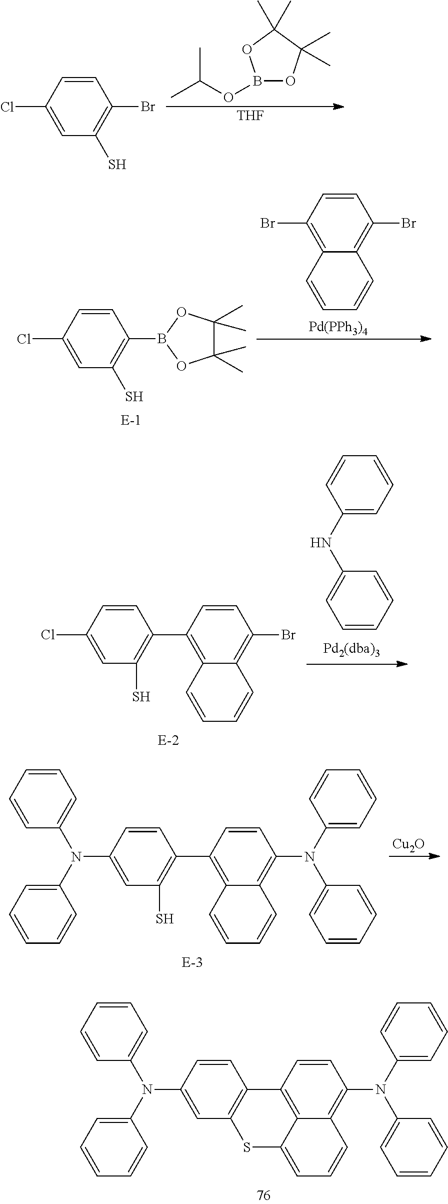

Synthesis of Intermediate E-1

4.0 g (yield of 73.9%) of Intermediate E-1 was synthesized in the same manner as used to synthesize Intermediate A-1 in Synthesis Example 1, except that 2-bromo-5-chlorobenzenethiol was used instead of 2-bromo-5-chloroanisole. The synthesized compound was confirmed by LC-MS.

C₁₂H₁₆BClO₂S: M⁺ 270.1

Synthesis of Intermediate E-2

4.0 g (yield of 79.8%) of Intermediate E-2 was synthesized in the same manner as used to synthesize Intermediate A-2 in Synthesis Example 1, except that Intermediate E-1 was used instead of Intermediate A-1. The synthesized compound was confirmed by LC-MS.

C₁₆H₁₀BrClS: M⁺ 347.9

Synthesis of Intermediate E-3

2.0 g (yield of 78.4%) of Intermediate E-3 was synthesized in the same manner as used to synthesize Intermediate A-3 in Synthesis Example 1, except that Intermediate E-2 was used instead of Intermediate A-2. The synthesized compound was confirmed by LC-MS.

C₄₀H₃₀N₂S: M⁺ 570.2

Synthesis of Compound 76

1.18 g (yield of 59.1%) of Compound 76 was synthesized in the same manner as used to synthesize Compound 1 in Synthesis Example 1, except that Intermediate E-3 was used instead of Intermediate A-4. The synthesized compound was confirmed by LC-MS and NMR.

C₄₀H₂₈N₂S: M⁺ 568.2

### Synthesis Example 8

### Synthesis of Compound 80

Synthesis of Compound 80

1.32 g (yield of 55.8%) of Compound 80 was synthesized in the same manner as used to synthesize Compound 76 in Synthesis Example 7, except that N-([1,1′-biphenyl]-2-yl)dibenzo[b,d]furan-4-amine was used instead of diphenyl amine. The synthesized compound was confirmed by LC-MS and NMR.

C₆₄H₄₀N₂O₂S: M⁺ 900.3

### Synthesis Example 9

### Synthesis of Compound H-4

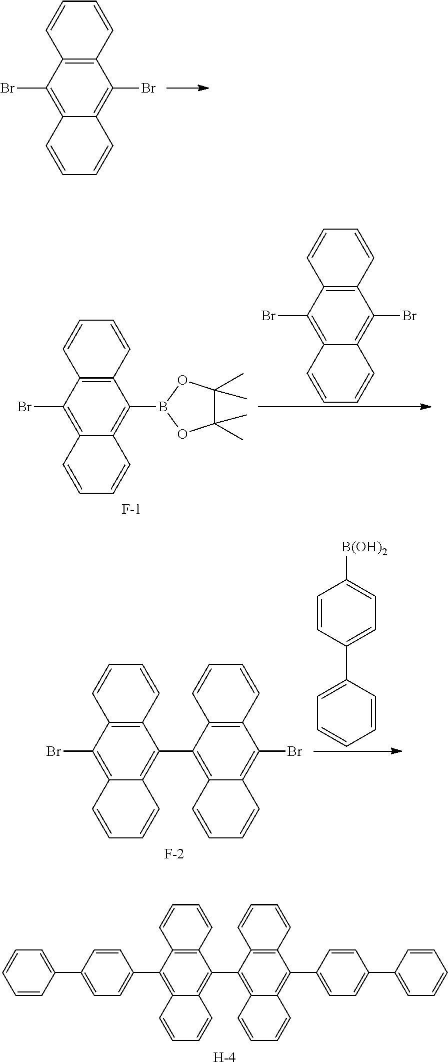

Synthesis of Intermediate F-1

11.0 g (yield of 72.1%) of Compound F-1 was synthesized in the same manner as used to synthesize Compound A-1 in Synthesis Example 1, except that 9,10-dibromoanthracene was used instead of 2-bromo-5-chloroanisole. The synthesized compound was confirmed by LC-MS.

C₂₀H₂₀BBrO₂: M⁺ 382.1

Synthesis of Intermediate F-2

9.31 g (yield of 62.7%) of Compound F-2 was synthesized in the same manner as used to synthesize Compound A-2 in Synthesis Example 1, except that Intermediate F-1 was used instead of Intermediate A-1 and 9,10-dibromoanthracene was used instead of 1,4-dibromonaphthalene. The synthesized compound was confirmed by LC-MS.

C₂₈H₁₆Br₂: M⁺ 510.0

Synthesis of Compound H-4

3.07 g (5 mmol) of Intermediate F-2, 2.57 g (13 mmol) of [1,1′-biphenyl]-4-ylboronic acid, 1.15 g (1 mmol) of Pd(PPh₃)₄(tetrakis(triphenylphosphine)palladium), and 2.76 g (20 mmol) of K₂CO₃ were dissolved in 50 ml of THF/H₂O (a volumetric ratio of 9/1) mixed solution, and then, at a temperature of 70° C., the mixture was stirred for 5 hours. The reaction solution was cooled at ambient temperature, and then, 30 ml of water was added thereto, and then, the result was subjected to an extraction process three times by using 30 ml of ethyl ether. An organic layer obtained therefrom was dried by using magnesium sulfate, and the residual obtained by removing a solvent therefrom by evaporation was separation-purified by silica gel column chromatography to obtain 2.16 g (yield of 65.7%) of Compound H-4. The synthesized compound was confirmed by LC-MS and NMR.

C₅₂H₃₄: M⁺ 658.3

### Synthesis Example 10

### Synthesis of Compound H-6

Synthesis of Compound H-6

2.56 g (yield of 63.1%) of Compound H-6 was synthesized in the same manner as used to synthesize Compound H-4 in Synthesis Example 7, except that [1,1′: 4′,1″-terphenyl]-2-ylboronic acid was used instead of [1,1′-biphenyl]-4-ylboronic acid. The synthesized compound was confirmed by LC-MS and NMR.

C₆₄H₄₂: M⁺ 810.3

### Synthesis Example 11

### Synthesis of Compound H-19

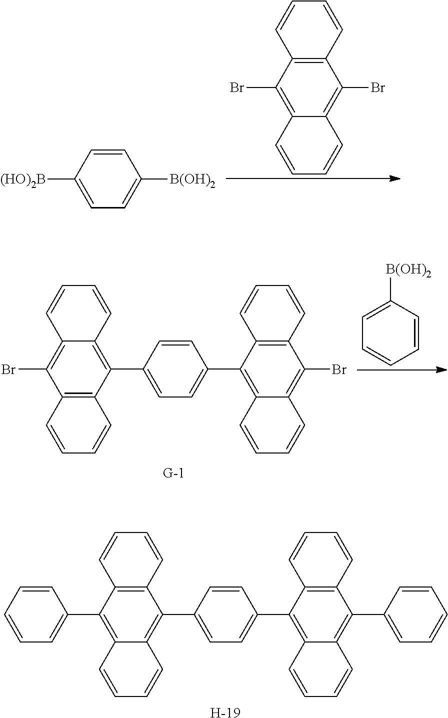

Synthesis of Intermediate G-1

4.89 g (yield of 71.5%) of Intermediate G-1 was synthesized in the same manner as used to synthesize Compound H-4 in Synthesis Example 7, except that 1,4-phenylenediboronic acid was used instead of Intermediate F-2, and 9,10-dibromoanthracene was used instead of [1,1′-biphenyl]-4-ylboronic acid. The synthesized compound was confirmed by LC-MS.

C₃₄H₂₀Br₂: M⁺ 586.0

Synthesis of Compound H-19

3.55 g (yield of 73.4%) of Intermediate H-19 was synthesized in the same manner as used to synthesize Compound H-4 in Synthesis Example 7, except that Intermediate G-1 was used instead of Intermediate F-2, and phenylboronic acid was used instead of [1,1′-biphenyl]-4-ylboronic acid. The synthesized compound was confirmed by LC-MS and NMR.

C₄₆H₃₀: M⁺ 582.3

### Synthesis Example 12

### Synthesis of Compound H-37

Synthesis of Compound H-37

3.37 g (yield of 78.2%) of Intermediate H-37 was synthesized in the same manner as used to synthesize Compound H-4 in Synthesis Example 7, except that 9,10-dibromoanthracene was used instead of Intermediate F-2, and naphthalen-2-ylboronic acid was used instead of [1,1′-biphenyl]-4-ylboronic acid. The synthesized compound was confirmed by LC-MS and NMR.

C₃₄H₂₂: M⁺ 430.2

### Synthesis Example 13

### Synthesis of Compound H-38

Synthesis of Compound H-38

4.28 g (yield of 80.7%) of Intermediate H-38 was synthesized in the same manner as used to synthesize Compound H-4 in Synthesis Example 7, except that 9,10-dibromoanthracene was used instead of Intermediate F-2, and phenanthren-3-ylboronic acid was used instead of [1,1′-biphenyl]-4-ylboronic acid. The synthesized compound was confirmed by LC-MS and NMR.

C₄₂H₂₆: M⁺ 530.2

### Synthesis Example 14

### Synthesis of Compound H-41

Synthesis of Compound H-41

4.45 g (yield of 76.3%) of Intermediate H-41 was synthesized in the same manner as used to synthesize Compound H-4 in Synthesis Example 7, except that 9,10-dibromoanthracene was used instead of Intermediate F-2, and (4-phenylnaphthalen-1-yl)boronic acid was used instead of [1,1′-biphenyl]-4-ylboronic acid. The synthesized compound was confirmed by LC-MS and NMR.

C₄₆H₃₀: M⁺ 582.2

### Synthesis Example 15

### Synthesis of Compound H-61

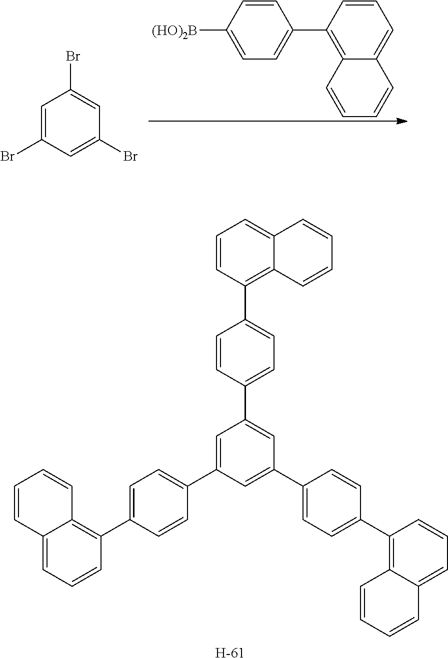

Synthesis of Compound H-61

3.15 g (10 mmol) of 1,3,5-tribromobenzene, 11.16 g (45 mmol) of (4-(naphthalen-1-yl)phenyl)boronic acid, 3.46 g (3 mmol) of Pd(PPh₃)₄ (tetrakis(triphenylphosphine)palladium), and 8.28 g (60 mmol) of K₂CO₃ were dissolved in 200 ml of a THF/H₂O (a volumetric ratio of 9/1) mixed solution, and then, the mixture was stirred at a temperature of 70° C. for 5 hours. The reaction solution was cooled at ambient temperature, and then, 70 ml of water was added thereto, and the result was subjected to an extraction process three times by using 70 ml of ethyl ether. An organic layer obtained therefrom was dried by using magnesium sulfate, and the residual obtained by removing a solvent therefrom by evaporation was separation-purified by silica gel column chromatography to obtain 3.76 g (yield of 54.9%) of Compound H-4. The synthesized compound was confirmed by LC-MS and NMR.

C₅₄H₃₆: M⁺ 684.3

TABLE 1

| | | MS/FAB | |
|---|---|---|---|
| Compound | ¹H NMR (CDCl₃, 400 MHz) | found | calc. |
| 1 | 7.82 (d, 1H), 7.72 (dd, 1H), 7.49 (dd, 1H), 7.41-7.37 (m, 2H), | 552.2 | 552.68 |
| | 7.15-7.08 (m, 8H), 6.86 (s, 1H), 6.83 (dd, 1H), 6.78-6.72 (m, 4H), 6.61 (dd, | | |
| | 1H), 6.43 (dd, 4H), 6.29 (dd, 4H) | | |
| 15 | 7.81-7.77 (m, 2H), 7.69 (dd, 1H), 7.67-7.62 (m, 2H), 7.58-7.62 (m, | 718.3 | 718.86 |
| | 10H), 7.18-7.13 (m, 2H), 7.09-6.95 (m, 8H), 6.8 (d, 1H), 6.7 (dd, 2H), | | |
| | 6.58 (d, 1H), 6.46 (dd, 1H), 6.26-6.23 (m, 4H) | | |
| 40 | 7.85 (dd, 1H), 7.83 (dd, 1H), 7.76-7.73 (m, 2H), 7.62-7.54 (m, 3H), | 718.3 | 718.90 |
| | 7.49-7.33 (m, 7H), 7.19-7.08 (m, 7H), 6.94 (dd, 1H), 6.79-6.71 (m, 4H), | | |
| | 6.63-6.59 (m, 2H), 6.46-6.42 (m, 2H), 6.32-6.29 (m, 2H), 1.84 (s, 6H) | | |
| 46 | 7.76 (dd, 3H), 7.69 (dd, 1H), 7.65-7.59 (m, 4H), 7.54 (dd, 1H), 7.44 (t, | 732.2 | 732.84 |
| | 2H), 7.4 (dd, 2H), 7.38-7.31 (m, 2H), 7.10-6.91 (m, 8H), 6.87 (d, 1H), | | |
| | 6.78 (d, 1H), 6.72-6.67 (m, 2H), 6.59 (dd, 1H), 6.45 (dd, 2H), 6.35 (dd, | | |
| | 2H) | | |
| 69 | 8.04 (d, 1H), 7.90 (dd, 3H), 7.86 (d, 1H), 7.80 (d, 1H), 7.68-7.52 (m, | 778.3 | 778.95 |
| | 13H), 7.48-7.41 (m, 4H), 7.29-7.16 (m, 8H), 6.89 (d, 1H), 6.87-6.83 (m, | | |
| | 2H), 6.5 (dd, 2H), 6.46 (dd, 2H) | | |
| 74 | 8.39 (d, 1H), 7.84 (d, 1H), 7.78 (dd, 1H), 7.68 (dd, 1H), 7.66-7.51 (m, | 794.3 | 795.00 |
| | 6H), 7.48 (d, 1H), 7.42-7.29 (m, 3H), 7.20-7.10 (m, 9H), 6.96 (dd, 1H), | | |
| | 6.81-6.72 (m, 4H), 6.63 (dd, 2H), 6.47 (dd, 2H), 6.23 (dd, 4H), 1.76 (s, | | |
| | 6H) | | |
| 76 | 7.55 (d, 1H), 7.37 (d, 1H), 7.34-7.30 (m, 2H), 7.20 (t, 1H), 6.93-6.86 (m, | 568.2 | 568.74 |
| | 8H), 6.79 (d, 1H), 6.71 (d, 1H), 6.57-6.52 (m, 4H), 6.44 (dd, 1H), | | |
| | 6.26 (dd, 4H), 6.1 (dd, 4H) | | |
| 80 | 7.64 (dd, 2H), 7.61 (d, 1H), 7.54-7.48 (m, 4H), 7.46-7.38 (m, 11H), | 900.3 | 901.10 |
| | 7.35-7.25 (m, 7H), 7.07-6.99 (m, 4H), 6.94-6.85 (m, 9H), 6.80 (t, 1H), | | |
| | 6.34 (dd, 1H) | | |
| H-4 | 7.84 (dd, 4H), 7.71 (t, 2H), 7.69 (t, 2H), 7.64-7.59 (m, 8H), | 658.3 | 658.84 |
| | 7.50-7.46 (m, 4H), 7.43-7.38 (m, 4H), 7.35-7.29 (m, 6H), 7.25 (t, 4H) | | |
| H-6 | 7.85-7.82 (m, 4H) 7.67 (dd, 4H), 7.65-7.61 (m, 6H), 7.50 (dd, 4H), | 810.3 | 811.04 |
| | 7.47-7.38 (m, 10H), 7.36 (dd, 2H), 7.33-7.17 (m, 12H) | | |
| H-19 | 7.88 (s, 4H), 7.70 (dd, 2H), 7.67 (dd, 2H), 7.61-7.56 (m, 8H), | 582.3 | 582.75 |
| | 7.41-7.37 (m, 4H), 7.32-7.28 (m, 2H), 7.25-7.21 (m, 8H) | | |
| H-37 | 8.02 (t, 2H), 7.84-7.79 (m, 8H), 7.59 (dd, 4H), 7.53-7.48 (m, 4H), | 430.2 | 430.55 |
| | 7.31 (dd, 4H) | | |
| H-38 | 8.46 (t, 2H), 8.39 (d, 2H), 8.04 (d, 2H), 7.92 (d, 2H), 7.82 (t, 2H), | 530.2 | 530.67 |
| | 7.73 (d, 2H), 7.67 (dd, 4H), 7.6 (d, 2H), 7.56 (dd, 4H), 7.31 (dd, 4H) | | |
| H-41 | 7.97 (dd, 4H), 7.84 (d, 2H), 7.79 (dd, 4H), 7.66 (d, 2H), 7.62 (dd, 2H), | 582.2 | 582.75 |
| | 7.56 (dd, 2H), 7.46 (t, 4H), 7.39-7.33 (m, 6H), 7.11-7.04 (m, 4H) | | |
| H-61 | 7.92 (dd, 3H), 7.88-7.83 (m, 12H), 7.80 (dd, 3H), 7.76-7.72 (m, 6H), | 684.3 | 684.88 |
| | 7.66 (dd, 6H), 7.45 (dd, 3H), 7.25 (dd, 3H) | | |

### Example 1

An ITO glass substrate (a product of Corning Inc.) having a sheet resistance of 15 Ω/cm² and a thickness of 1,200 Å was cut to a size of 50 mm×50 mm×0.5 mm, and then, sonicated with isopropyl alcohol and deionized water, each for 5 minutes, and then, exposed to ultraviolet rays for 30 minutes and ozone for washing. The resultant ITO glass substrate was mounted on a vacuum deposition apparatus.

2T-NATA was deposited on the ITO anode to form a hole injection layer having a thickness of 600 Å, and then, NPB was deposited on the hole injection layer to form a hole transport layer having a thickness of 300 Å. Then, H-4 (host) and Compound 1 (dopant) were deposited on the hole transport layer at a weight ratio of 98:2 to form an emission layer having a thickness of 300 Å.

Alq₃ was deposited on the emission layer to form an electron transport layer having a thickness of 300 Å, and LiF was deposited on the electron transport layer to form an electron injection layer having a thickness of 10 Å. Then, Al was deposited on the electron injection layer to form a cathode having a thickness of 3,000 Å, thereby completing the manufacture of an organic light-emitting device.

### Example 2

An organic light-emitting device was manufactured in the same manner as in Example 1, except that in forming the emission layer, as a dopant, Compound 15 was used instead of Compound 1.

### Example 3

An organic light-emitting device was manufactured in the same manner as in Example 2, except that in forming the emission layer, as a host, Compound H-16 was used instead of Compound H-4.

### Example 4

An organic light-emitting device was manufactured in the same manner as in Example 3, except that in forming the emission layer, as a dopant, Compound 40 was used instead of Compound 15.

### Example 5

An organic light-emitting device was manufactured in the same manner as in Example 1, except that in forming the emission layer, as a host, Compound H-19 was used instead of Compound H-4.

### Example 6

An organic light-emitting device was manufactured in the same manner as in Example 5, except that in forming the emission layer, as a dopant, Compound 46 was used instead of Compound 1.

### Example 7

An organic light-emitting device was manufactured in the same manner as in Example 2, except that in forming the emission layer, as a host, Compound H-38 was used instead of Compound H-4.

### Example 8

An organic light-emitting device was manufactured in the same manner as in Example 7, except that in forming the emission layer, as a dopant, Compound 40 was used instead of Compound 15.

### Example 9

An organic light-emitting device was manufactured in the same manner as in Example 7, except that in forming the emission layer, as a dopant, Compound 46 was used instead of Compound 15.

### Example 10

An organic light-emitting device was manufactured in the same manner as in Example 2, except that in forming the emission layer, as a host, Compound H-41 was used instead of Compound H-4.

### Example 11

An organic light-emitting device was manufactured in the same manner as in Example 10, except that in forming the emission layer, as a dopant, Compound 46 was used instead of Compound 15.

### Example 12

An organic light-emitting device was manufactured in the same manner as in Example 10, except that in forming the emission layer, as a dopant, Compound 69 was used instead of Compound 15.

### Example 13

An organic light-emitting device was manufactured in the same manner as in Example 10, except that in forming the emission layer, as a dopant, Compound 74 was used instead of Compound 15.

### Example 14

An organic light-emitting device was manufactured in the same manner as in Example 2, except that in forming the emission layer, as a host, Compound H-61 was used instead of Compound H-4.

### Example 15

An organic light-emitting device was manufactured in the same manner as in Example 14, except that in forming the emission layer, as a dopant, Compound 40 was used instead of Compound 15.

### Example 16

An organic light-emitting device was manufactured in the same manner as in Example 1, except that in forming the emission layer, as a dopant, Compound 76 was used instead of Compound 1.

### Example 17

An organic light-emitting device was manufactured in the same manner as in Example 1, except that in forming the emission layer, as a dopant, Compound 80 was used instead of Compound 1.

### Example 18

An organic light-emitting device was manufactured in the same manner as in Example 3, except that in forming the emission layer, as a dopant, Compound 80 was used instead of Compound 15.

### Comparative Example 1

An organic light-emitting device was manufactured in the same manner as in Example 9, except that in forming the emission layer, as a dopant, N,N,N′,N′-tetraphenyl-pyrene-1,6-diamine (FD1) was used instead of Compound 1.

<FD1>

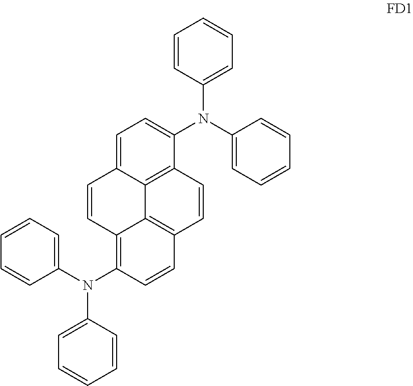 [SMILES: c1ccc(N(c2ccccc2)c2ccc3ccc4c(N(c5ccccc5)c5ccccc5)ccc5ccc2c3c54)cc1]

### Comparative Example 2

An organic light-emitting device was manufactured in the same manner as in Example 1, except that in forming the emission layer, as a dopant, Compound A was used instead of Compound 1.

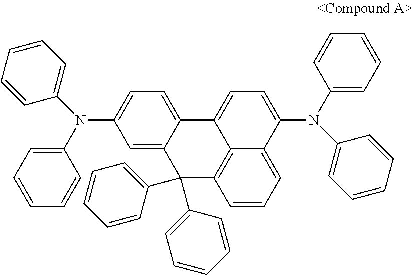 [SMILES: c1ccc(N(c2ccccc2)c2ccc3c(c2)C(c2ccccc2)(c2ccccc2)c2cccc4c(N(c5ccccc5)c5ccccc5)ccc-3c24)cc1]

### Evaluation Example 1

The driving voltage, luminance, efficiency, and half lifespan (T₅₀) data of the organic light-emitting devices manufactured according to Examples 1 to 15, Comparative Examples 1 and 2 were measured by using a Kethley SMU 236 and a luminance-based PR650. Results thereof are shown in Table 2, below. Lifespan (T₅₀) indicates a period of time that lapsed when a luminance of an organic light-emitting device was 50% of the initial luminance (100%) thereof.

TABLE 2

| | | | | | | | | Half |
|---|---|---|---|---|---|---|---|---|
| | | | | | | | | lifespan |
| | Host in | Dopant in | Driving | Current | | | | (T₅₀) |
| | emission | emission | voltage | density | Luminance | Efficiency | Emission | (hr) |
| | layer | layer | (V) | (mA/cm²) | (cd/m²) | (cd/A) | color | (@100 cd/m²) |
| Example 1 | Compound | Compound 1 | 4.93 | 50 | 3,260 | 6.52 | blue | 438 |
| | H-4 | | | | | | | |
| Example 2 | Compound | Compound | 4.81 | 50 | 3,570 | 7.14 | blue | 427 |
| | H-4 | 15 | | | | | | |
| Example 3 | Compound | Compound | 5.26 | 50 | 3,420 | 6.84 | blue | 441 |
| | H-16 | 15 | | | | | | |
| Example 4 | Compound | Compound | 5.18 | 50 | 3,455 | 6.91 | blue | 452 |
| | H-16 | 40 | | | | | | |
| Example 5 | Compound | Compound 1 | 6.08 | 50 | 3,195 | 6.39 | blue | 389 |
| | H-19 | | | | | | | |
| Example 6 | Compound | Compound | 5.53 | 50 | 3,475 | 6.95 | blue | 429 |
| | H-19 | 46 | | | | | | |
| Example 7 | Compound | Compound | 5.13 | 50 | 3,660 | 7.32 | blue | 460 |
| | H-38 | 15 | | | | | | |
| Example 8 | Compound | Compound | 4.92 | 50 | 3,730 | 7.46 | blue | 453 |
| | H-38 | 40 | | | | | | |
| Example 9 | Compound | Compound | 5.22 | 50 | 3,805 | 7.61 | blue | 472 |
| | H-37 | 46 | | | | | | |
| Example 10 | Compound | Compound | 4.77 | 50 | 3,685 | 7.37 | blue | 413 |
| | H-41 | 15 | | | | | | |
| Example 11 | Compound | Compound | 5.18 | 50 | 3,870 | 7.74 | blue | 447 |
| | H-41 | 46 | | | | | | |
| Example 12 | Compound | Compound | 5.59 | 50 | 3,190 | 6.38 | blue | 326 |
| | H-41 | 69 | | | | | | |
| Example 13 | Compound | Compound | 5.76 | 50 | 3,355 | 6.71 | blue | 394 |
| | H-41 | 74 | | | | | | |
| Example 14 | Compound | Compound | 5.84 | 50 | 3,390 | 6.78 | blue | 376 |
| | H-61 | 15 | | | | | | |
| Example 15 | Compound | Compound | 5.63 | 50 | 3,465 | 6.93 | blue | 383 |
| | H-61 | 40 | | | | | | |
| Example 16 | Compound | Compound | 5.47 | 50 | 3,305 | 6.61 | blue | 311 |
| | H-4 | 76 | | | | | | |
| Example 17 | Compound | Compound | 5.59 | 50 | 3,370 | 6.74 | blue | 298 |
| | H-4 | 80 | | | | | | |
| Example 18 | Compound | Compound | 5.81 | 50 | 3,410 | 6.82 | blue | 304 |
| | H-16 | 80 | | | | | | |
| Comparative | Compound | FD1 | 7.02 | 50 | 2,690 | 5.38 | blue | 242 |
| Example 1 | H-37 | | | | | | | |
| Comparative | Compound | Compound A | 6.34 | 50 | 2,145 | 6.29 | blue | 276 |
| Example 2 | H-4 | | | | | | | |

Referring to Table 2, it may be seen that the organic light-emitting devices manufactured according to Examples 1 to 18 have a lower driving voltage, higher luminance, higher efficiency, and a longer half lifespan (T₅₀) than the organic light-emitting devices manufactured according to Comparative Examples 1 and 2.

An organic light-emitting device according to embodiments may have high efficiency and a long lifespan.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An organic light-emitting device, comprising:
a first electrode;
a second electrode facing the first electrode; and
an organic layer between the first electrode and the second electrode, the organic layer including an emission layer,
wherein:
the organic layer includes a first compound and a second compound,
the first compound includes a compound represented by the following Formula 1, and
the second compound includes a compound represented by one of the following Formulae 2-1 to 2-4: 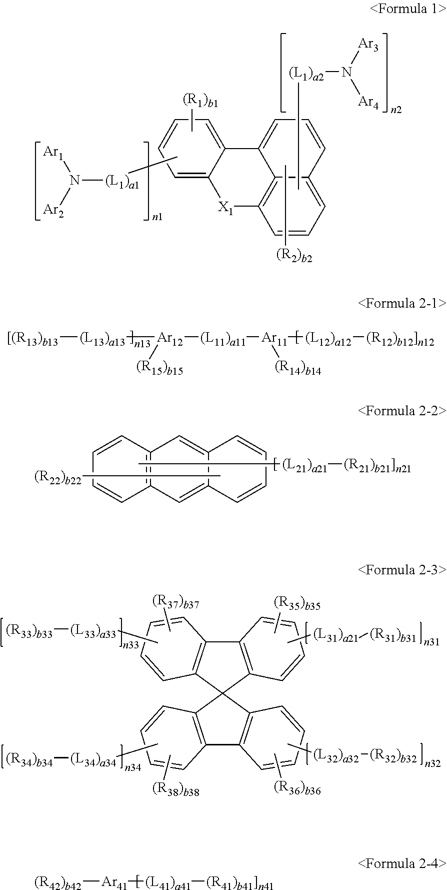
wherein, in Formulae 1 and 2-1 to 2-4,
X₁ is O or S;
Ar₁₁ and Ar₁₂ are each independently selected from a naphthalene group, an anthracene group, a triphenylene group, a pyrene group, a chrysene group, and a perylene group;
Ar₄₁ is a C₆-C₄₀ arylene;
L₁, L₂, L₁₁ to L₁₃, L₂₁, L₃₁ to L₃₄, and L₄₁ are each independently selected from a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed heteropolycyclic group;
a1, a2, a11 to a13, a21, a31 to a34, and a41 are each independently selected from 0, 1, 2, and 3, when a1 is 2 or more, a plurality of L₁ are identical or different, when a2 is 2 or more, a plurality of L₂ are identical or different, when a11 is 2 or more, a plurality of L₁₁ are identical or different, when a12 is 2 or more, a plurality of L₁₂ are identical or different, when a13 is 2 or more, a plurality of L₁₃ are identical or different, when a21 is 2 or more, a plurality of L₂₁ are identical or different, when a31 is 2 or more, a plurality of L₃₁ are identical or different, when a32 is 2 or more, a plurality of L₃₂ are identical or different, when a33 is 2 or more, a plurality of L₃₃ are identical or different, when a34 is 2 or more, a plurality of L₃₄ are identical or different, and when a41 is 2 or more, a plurality of L₄₁ are identical or different;
Ar₁ to Ar₄ are each independently selected from a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group;
R₁, R₂, R₁₂ to R₁₅, R₂₁, R₂₂, R₃₁ to R₃₈, R₄₁, and R₄₂ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, and —Si(Q₁)(Q₂)(Q₃);
b1, b12, b13, b21, b31 to b38, b41, and b42 are each independently selected from 0, 1, 2, and 3, when b1 is 2 or more, a plurality of R₁ are identical or different, when b12 is 2 or more, a plurality of R₁₂ are identical or different, when b13 is 2 or more, a plurality of R₁₃ are identical or different, when b31 is 2 or more, a plurality of R₃₁ are identical or different, when b32 is 2 or more, a plurality of R₃₂ are identical or different, when b33 is 2 or more, a plurality of R₃₃ are identical or different, when b34 is 2 or more, a plurality of R₃₄ are identical or different, when b35 is 2 or more, a plurality of R₃₅ are identical or different, when b36 is 2 or more, a plurality of R₃₆ are identical or different, when b37 is 2 or more, a plurality of R₃₇ are identical or different, when b38 is 2 or more, a plurality of R₃₈ are identical or different, and when b41 is 2 or more, a plurality of R₄₁ are identical or different, and when b42 is 2 or more, a plurality of R₄₂ are identical or different;
b2 is selected from 0, 1, 2, 3, 4, and 5, and when b2 is 2 or more, a plurality of R₂ are identical or different;
b14 and b15 are each independently 0, 1, 2, 3, 4, 5, and 6, and when b14 is 2 or more, a plurality of R₁₄ are identical or different, and b15 is 2 or more, a plurality of R₁₅ are identical or different;
b22 is selected from 0, 1, 2, 3, 4, 5, 6, 7, 8, and 9, and when b22 is 2 or more, a plurality of R₂₂ are identical or different;
n1, n2, n12, n13, n21, and n31 to n34 are each independently selected from 0, 1, 2, and 3,
n41 is selected from 0, 1, 2, 3, 4, 5, 6, 7, 8, and 9; and
at least one substituent of the substituted benzene ring, substituted naphthalene ring, substituted C₃-C₁₀ cycloalkylene group, substituted C₁-C₁₀ heterocycloalkylene group, substituted C₃-C₁₀ cycloalkenylene group, substituted C₁-C₁₀ heterocycloalkenylene group, substituted C₆-C₆₀ arylene group, substituted C₁-C₆₀ heteroarylene group, substituted divalent non-aromatic condensed polycyclic group, substituted divalent non-aromatic condensed heteropolycyclic group, substituted C₁-C₆₀ alkyl group, substituted C₂-C₆₀ alkenyl group, substituted C₂-C₆₀ alkynyl group, substituted C₁-C₆₀ alkoxy group, substituted C₃-C₁₀ cycloalkyl group, substituted C₁-C₁₀ heterocycloalkyl group, substituted C₃-C₁₀ cycloalkenyl group, substituted C₁-C₁₀ heterocycloalkenyl group, substituted C₆-C₆₀ aryl group, substituted C₆-C₆₀ aryloxy group, substituted C₆-C₆₀ arylthio group, substituted C₁-C₆₀ heteroaryl group, substituted monovalent non-aromatic condensed polycyclic group, and substituted monovalent non-aromatic condensed heteropolycyclic group is selected from:
a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, and a C₁-C₆₀ alkoxy group;
a C₁-C₆₀ alkyl group, a C₂-C₆₀ alkenyl group, a C₂-C₆₀ alkynyl group, and a C₁-C₆₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group(aryloxy), C₆-C₆₀ arylthio group(arylthio), C₁-C₆₀ heteroaryl group, a monovalent non-aromatic condensed polycyclic group, a monovalent non-aromatic condensed heteropolycyclic group, —Si(Q₁₁)(Q₁₂)(Q₁₃), —B(Q₁₄)(Q₁₅), and —N(Q₁₆)(Q₁₇);
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₂₁)(Q₂₂)(Q₂₃), —B(Q₂₄)(Q₂₅), and —N(Q₂₆)(Q₂₇); and
—Si(Q₃₁)(Q₃₂)(Q₃₃), —B(Q₃₄)(Q₃₅), and —N(Q₃₆)(Q₃₇),
wherein Q₁ to Q₃, Q₁₁ to Q₁₇, Q₂₁ to Q₂₇, and Q₃₁ to Q₃₇ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group.

2. The organic light-emitting device as claimed in claim 1, wherein:
Ar₁₁ and Ar₁₂ are each an anthracene group, and
Ar₄₁ is selected from a benzene group and a triphenylene group.

3. The organic light-emitting device as claimed in claim 1, wherein L₁, L₂, L₁₁ to L₁₃, L₂₁, L₃₁ to L₃₄, and L₄₁ are each independently selected from:
a phenylene group, a pentalenylene group, an indenylene group, a naphthylene group, an azulenylene group, a heptalenylene group, an indacenylene group, an acenaphthylene group, a fluorenylene group, a spiro-fluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, a pentacenylene group, a rubicenylene group, a coronenylene group, an ovalenylene group, a pyrrolylene group, a thiophenylene group, a furanylene group, an imidazolylene group, a pyrazolylene group, a thiazolylene group, an isothiazolylene group, an oxazolylene group, an isoxazolylene group, a pyridinylene group, a pyrazinylene group, a pyrimidinylene group, a pyridazinylene group, an isoindolylene group, an indolylene group, an indazolylene group, a purinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a carbazolylene group, a phenanthridinylene group, an acridinylene group, a phenanthrolinylene group, a phenazinylene group, a benzoimidazolylene group, a benzofuranylene group, a benzothiophenylene group, an isobenzothiazolylene group, a benzoxazolylene group, an isobenzoxazolylene group, a triazolylene group, a tetrazolylene group, an oxadiazolylene group, a triazinylene group, a dibenzofuranylene group, a dibenzothiophenylene group, a benzocarbazolylene group, a dibenzocarbazolylene group, a thiadiazolylene group, an imidazopyridinylene group, and an imidazopyrimidinylene group; and
a phenylene group, a pentalenylene group, an indenylene group, a naphthylene group, an azulenylene group, a heptalenylene group, an indacenylene group, an acenaphthylene group, a fluorenylene group, a spiro-fluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, a pentacenylene group, a rubicenylene group, a coronenylene group, an ovalenylene group, a pyrrolylene group, a thiophenylene group, a furanylene group, an imidazolylene group, a pyrazolylene group, a thiazolylene group, an isothiazolylene group, an oxazolylene group, an isoxazolylene group, a pyridinylene group, a pyrazinylene group, a pyrimidinylene group, a pyridazinylene group, an isoindolylene group, an indolylene group, an indazolylene group, a purinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a carbazolylene group, a phenanthridinylene group, an acridinylene group, a phenanthrolinylene group, a phenazinylene group, a benzoimidazolylene group, a benzofuranylene group, a benzothiophenylene group, an isobenzothiazolylene group, a benzoxazolylene group, an isobenzoxazolylene group, a triazolylene group, a tetrazolylene group, an oxadiazolylene group, a triazinylene group, a dibenzofuranylene group, a dibenzothiophenylene group, a benzocarbazolylene group, a dibenzocarbazolylene group, a thiadiazolylene group, an imidazopyridinylene group, and an imidazopyrimidinylene group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazopyridinyl group, and an imidazopyrimidinyl group.

4. The organic light-emitting device as claimed in claim 1, wherein L₁, L₂, L₁₁ to L₁₃, L₂₁, L₃₁ to L₃₄, and L₄₁ are each independently a group represented by one of the following Formulae 3-1 to 3-22: 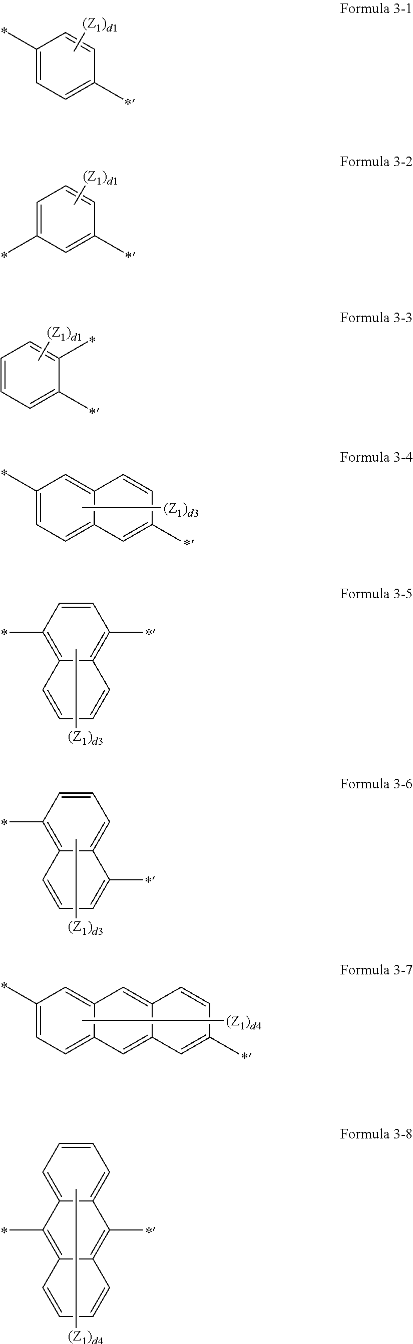 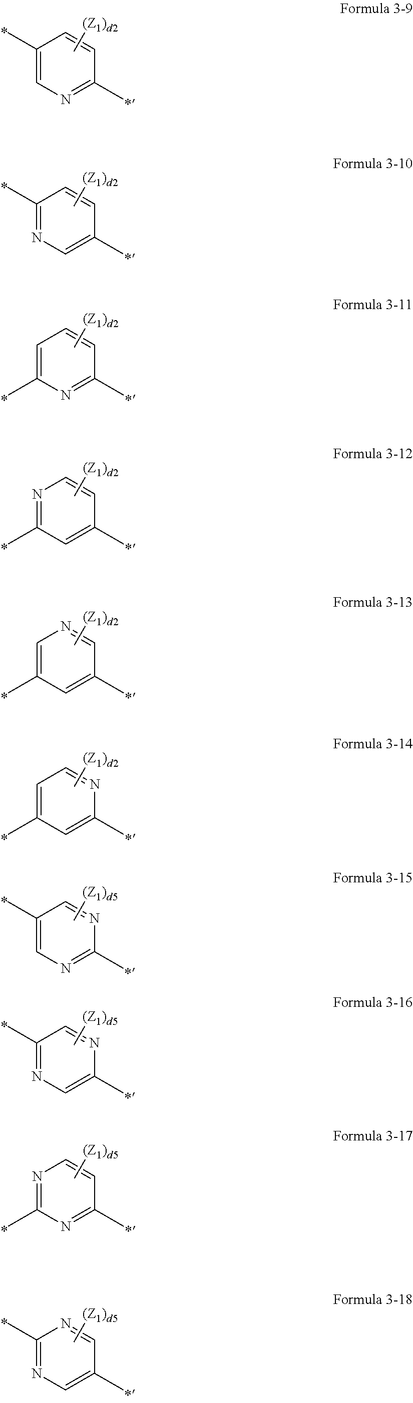 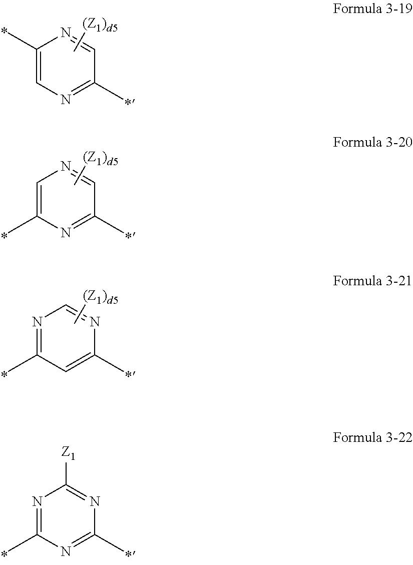
wherein, in Formulae 3-1 to 3-22,
Z₁ is selected from a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group,
d1 is an integer selected from 1 to 4, d2 is an integer selected from 1 to 3, d3 is an integer selected from 1 to 6, d4 is an integer selected from 1 to 8, d5 is an integer selected from 1 and 2, and each of * and *′ indicates a binding site to a neighboring atom.

5. The organic light-emitting device as claimed in claim 1, wherein L₁, L₂, L₁₁ to L₁₃, L₁₁ to L₁₃, L₂₁, L₃₁ to L₃₄, and L₄₁ are each independently a group represented by one of the following Formulae 4-1 to 4-6: 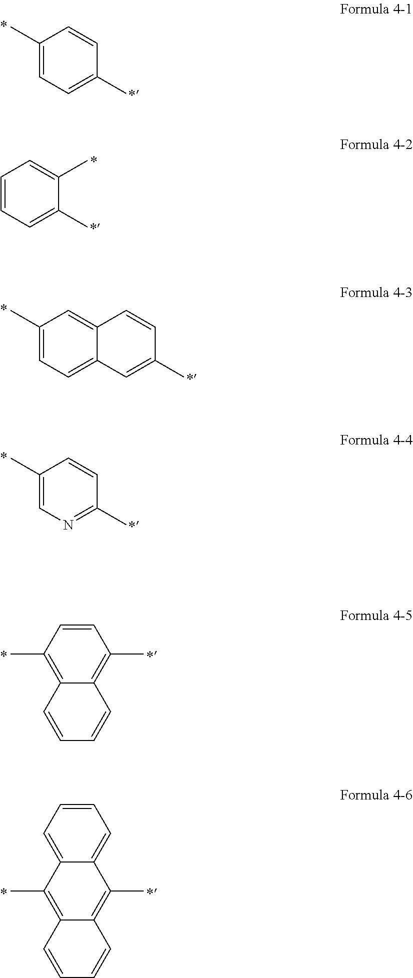
wherein, in Formulae 4-1 to 4-6, each of * and *′ indicates a binding site to a neighboring atom.

6. The organic light-emitting device as claimed in claim 1, wherein Ar₁ to Ar₄ are each independently selected from:
a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a benzocarbazolyl group, a dibenzocarbazolyl group, a thiadiazolyl group, an imidazopyridinyl group, and an imidazopyrimidinyl group; and
a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a benzocarbazolyl group, a dibenzocarbazolyl group, a thiadiazolyl group, an imidazopyridinyl group, and an imidazopyrimidinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a benzocarbazolyl group, a dibenzocarbazolyl group, a thiadiazolyl group, an imidazopyridinyl group, an imidazopyrimidinyl group, and —Si(Q₃₁)(Q₃₂)(Q₃₃),
wherein Q₃₁ to Q₃₃ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group.

7. The organic light-emitting device as claimed in claim 1, wherein Ar₁ to Ar₄ are each independently a group represented by one of the following Formulae 5-1 to 5-20: 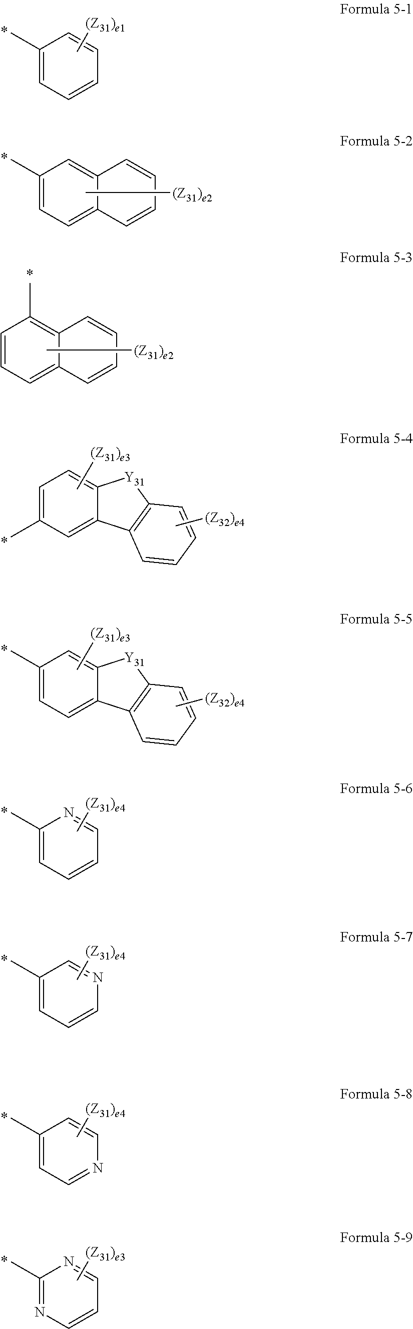 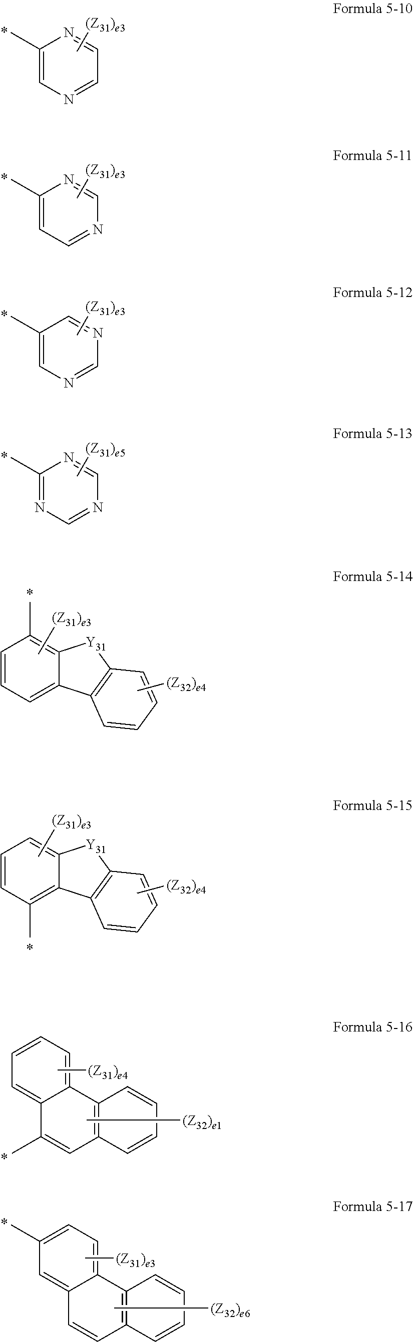 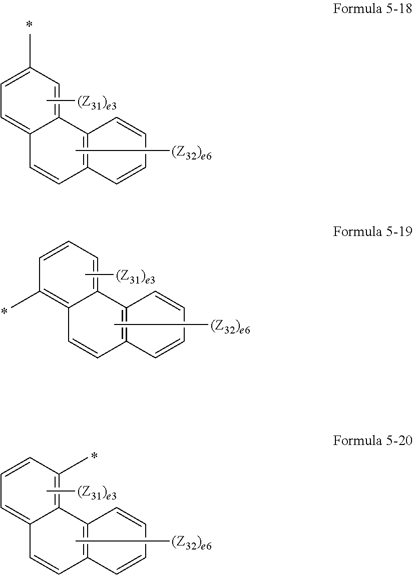
wherein, in Formulae 5-1 to 5-20,
Y₃₁ is O, S, C(Z₃₃)(Z₃₄), or N(Z₃₅);
Z₃₁ to Z₃₅ are each independently selected from:
a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, and a C₁-C₂₀ alkoxy group;
a C₁-C₂₀ alkyl group and C₁-C₂₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, and a phosphoric acid group or a salt thereof;
a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a carbazolyl group, a benzocarbazolyl group, and a dibenzocarbazolyl group;
a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a carbazolyl group, a benzocarbazolyl group, and a dibenzocarbazolyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, and a naphthyl group; and
—Si(Q₃₁)(Q₃₂)(Q₃₃), in which Q₃₁ to Q₃₃ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, and a carbazolyl group; and
e1 is an integer selected from 1 to 5, e2 is an integer selected from 1 to 7, e3 is an integer selected from 1 to 3, e4 is an integer selected from 1 to 4, e5 is an integer selected from 1 and 2, e6 is an integer selected from 1 to 6, and * indicates a binding site to a neighboring atom.

8. The organic light-emitting device as claimed in claim 1, wherein Ar₁ to Ar₄ are each independently a group represented by one of the following Formulae 6-1 to 6-21: 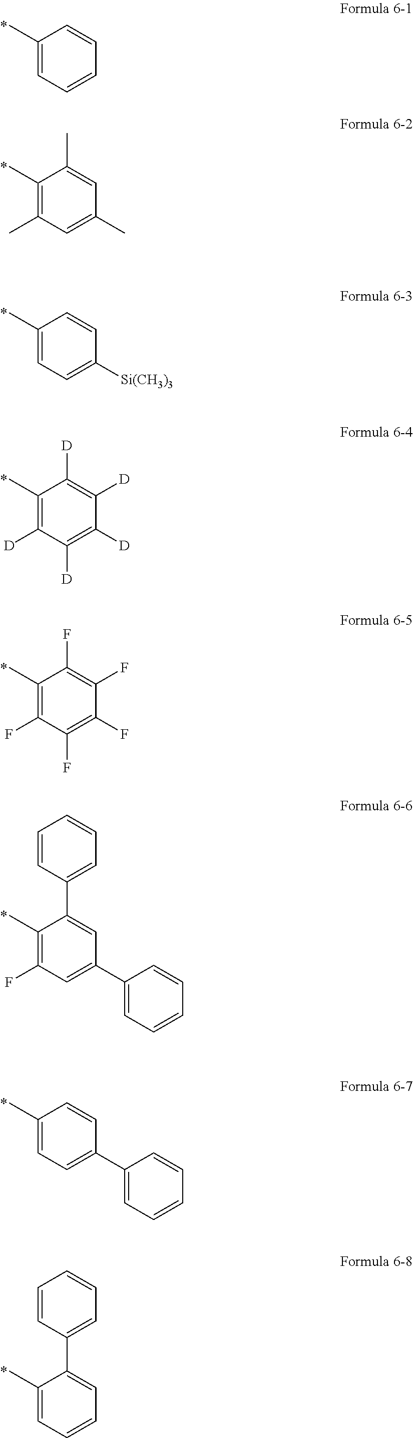 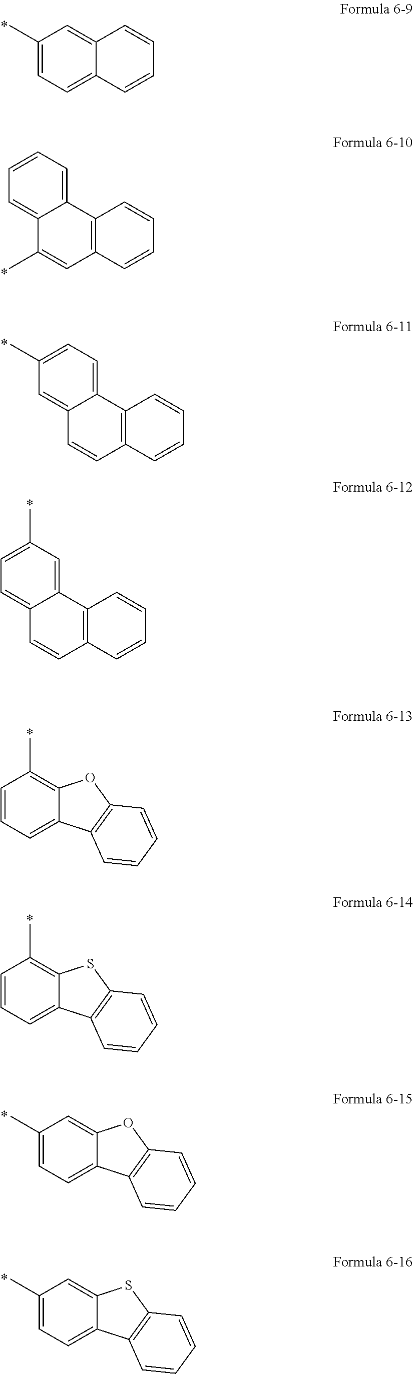 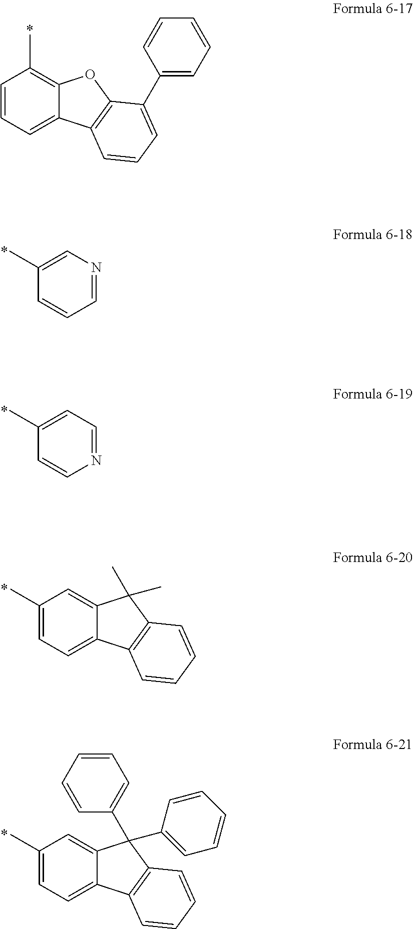
wherein, in Formulae 6-1 to 6-21, * indicates a binding site to a neighboring atom.

9. The organic light-emitting device as claimed in claim 1, wherein R₁ and R₂ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a phenyl group, a naphthyl group, and an anthracenyl group.

10. The organic light-emitting device of claim 1, wherein R₁₂ to R₁₅, R₂₁, R₂₂, R₃₅ to R₃₈, and R₄₂ are each independently selected from:
a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₆₀ alkenyl group and a C₁-C₂₀ alkoxy group;
a C₁-C₂₀ alkyl group, a C₂-C₆₀ alkenyl group and C₁-C₂₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a phenyl group, a naphthyl group, a pyridinyl group, and a pyrimidinyl group;
a phenoxy group, a phenylthio group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, and an imidazopyrimidinyl group;
a phenoxy group, a phenylthio group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, and an imidazopyrimidinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —Si(Q₃₁)(Q₃₂)(Q₃₃), —B(Q₃₄)(Q₃₅), and N(Q₃₆)(Q₃₇); and
—Si(Q₁)(Q₂)(Q₃), —B(Q₄)(Q₅), and N(Q₆)(Q₇),
wherein Q₁ to Q₇ and Q₃₁ to Q₃₇ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, and a carbazolyl group.

11. The organic light-emitting device as claimed in claim 1, wherein R₁₂ to R₁₅, R₂₁, R₂₂, R₃₅ to R₃₈, and R₄₂ are each independently selected from a hydrogen, a deuterium, —F, —Cl, —Br, —I, a methyl group, an ethyl group, a propyl group, an iso-propyl group, a butyl group, an iso-butyl group, a sec-butyl group, a tert-butyl group, a methoxy group, an ethoxy group, an iso-a propoxy group, a butoxy group, an iso-butoxy group, a sec-butoxy group, a tert-butoxy group, —Si(CH₃)₃, —Si(Ph)₃, —N(Ph₂)₂, —B(Ph)₂, and a group represented by one of the following Formulae 7-1 to 7-21: 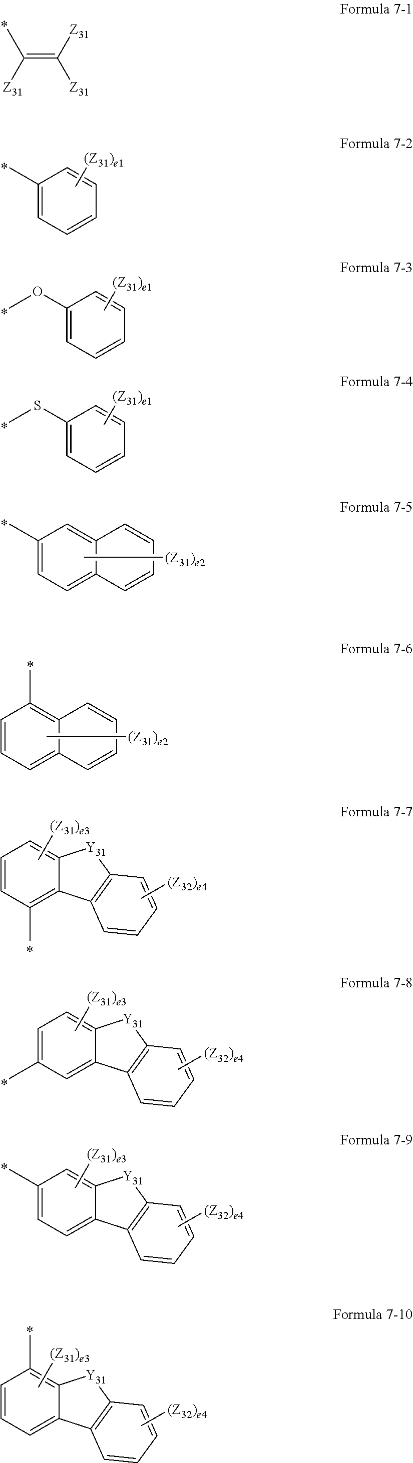 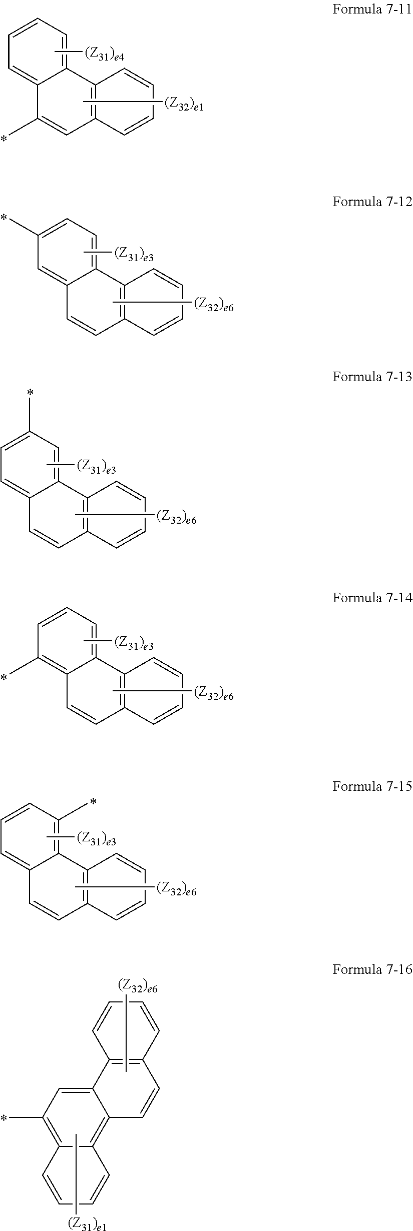 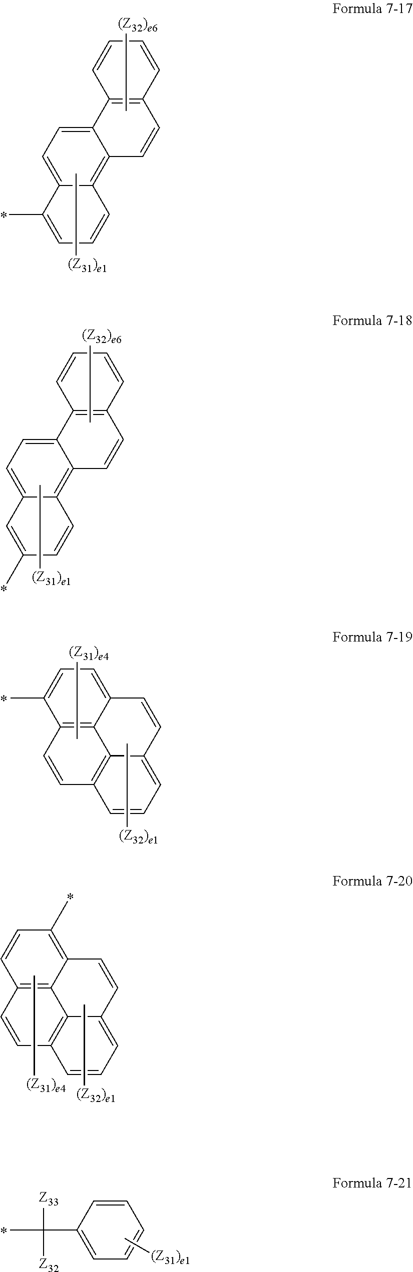
wherein, in Formulae 7-1 to 7-21,
Y₃₁ is O, S, C(Z₃₄)(Z₃₅), or N(Z₃₆);
Z₃₁ to Z₃₆ are each independently selected from:
a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, and a C₁-C₂₀ alkoxy group;
a C₁-C₂₀ alkyl group and a C₁-C₂₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, and a phosphoric acid group or a salt thereof;
a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a carbazolyl group, a benzocarbazolyl group, and a dibenzocarbazolyl group;
a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a carbazolyl group, a benzocarbazolyl group, and a dibenzocarbazolyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, and a naphthyl group; and
—Si(Q₃₁)(Q₃₂)(Q₃₃), —B(Q₃₄)(Q₃₅), and N(Q₃₆)(Q₃₇),
wherein Q₃₁ to Q₃₇ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, and a carbazolyl group;
e1 is an integer selected from 1 to 5, e2 is an integer selected from 1 to 7, e3 is an integer selected from 1 to 3, e4 is an integer selected from 1 to 4, e6 is an integer selected from 1 to 6, and * indicates a binding site to a neighboring atom.

12. The organic light-emitting device as claimed in claim 1, wherein R₁₂ to R₁₅, R₂₁, R₂₂, R₃₅ to R₃₈, and R₄₂ are each independently selected from a hydrogen, a deuterium, —F, —Cl, —Br, —I, a methyl group, an ethyl group, a propyl group, an iso-propyl group, a butyl group, an iso-butyl group, a sec-butyl group, a tert-butyl group, a methoxy group, an ethoxy group, an iso-a propoxy group, a butoxy group, an iso-butoxy group, a sec-butoxy group, a tert-butoxy group, —Si(CH₃)₃, —Si(Ph)₃, —N(Ph₂)₂, —B(Ph)₂, and a group represented by one of the following Formulae 8-1 to 8-18: 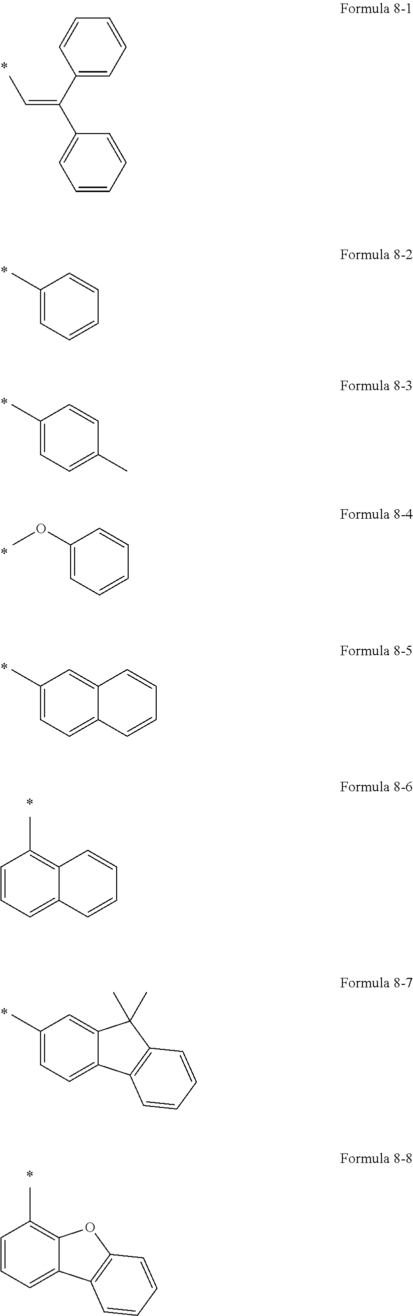 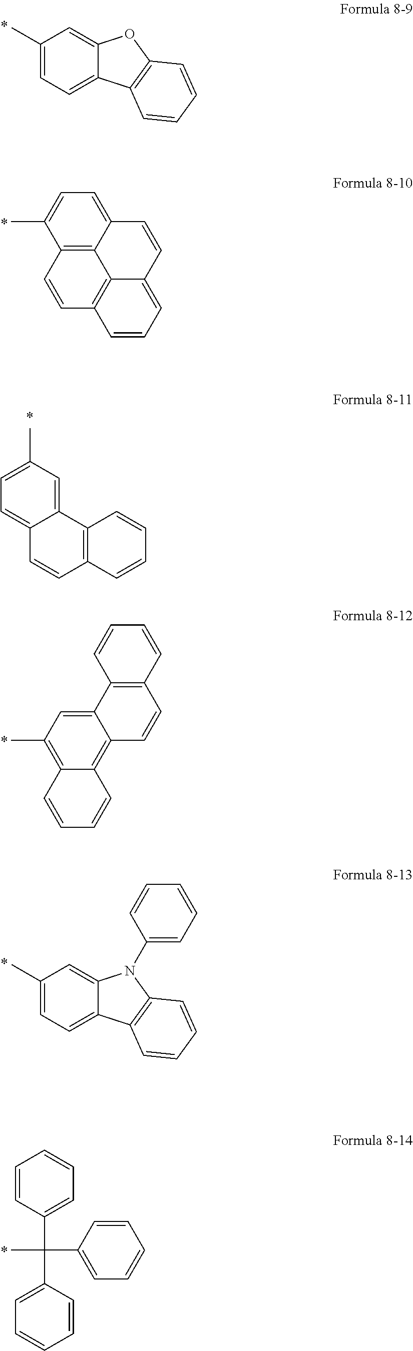 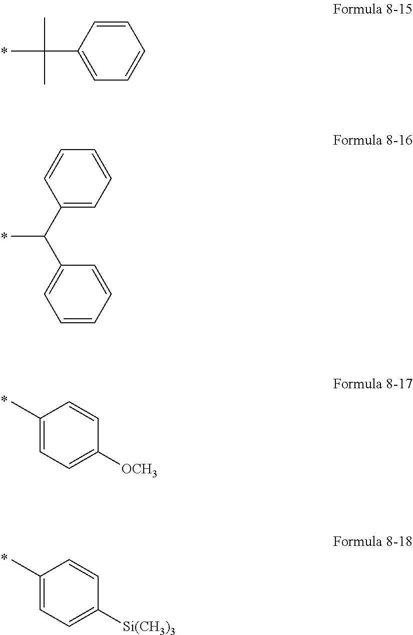
wherein, in Formulae 8-1 to 8-18, * indicates a binding site to a neighboring atom.

13. The organic light-emitting device as claimed in claim 1, wherein R₃₁ to R₃₄ and R₄₁ are each independently selected from:
a hydrogen, a deuterium, —F, —Cl, —Br, —I, a hydroxyl group, a cyano group, a nitro group, an amino group, an amidino group, a hydrazine group, a hydrazone group, a C1-C20 alkyl group, and a C1-C20 alkoxy group;
a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, a triazinyl group, a benzocarbazolyl group, and a dibenzocarbazolyl group; and
a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, a triazinyl group, a benzocarbazolyl group, and a dibenzocarbazolyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, a triazinyl group, a benzocarbazolyl group, a dibenzocarbazolyl group, and —Si(Q₃₁)(Q₃₂)(Q₃₃),
wherein Q₃₁ to Q₃₃ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group.

14. The organic light-emitting device as claimed in claim 1, wherein R₃₁ to R₃₄ and R₄₁ are each independently selected from a hydrogen, a deuterium, —F, —Cl, —Br, —I, a hydroxyl group, a cyano group, a nitro group, an amino group, an amidino group, a hydrazine group, a hydrazone group, a C₁-C₂₀ alkyl group, a C₁-C₂₀ alkoxy group, and a group represented by one of the following Formulae 9-1 to 9-16: 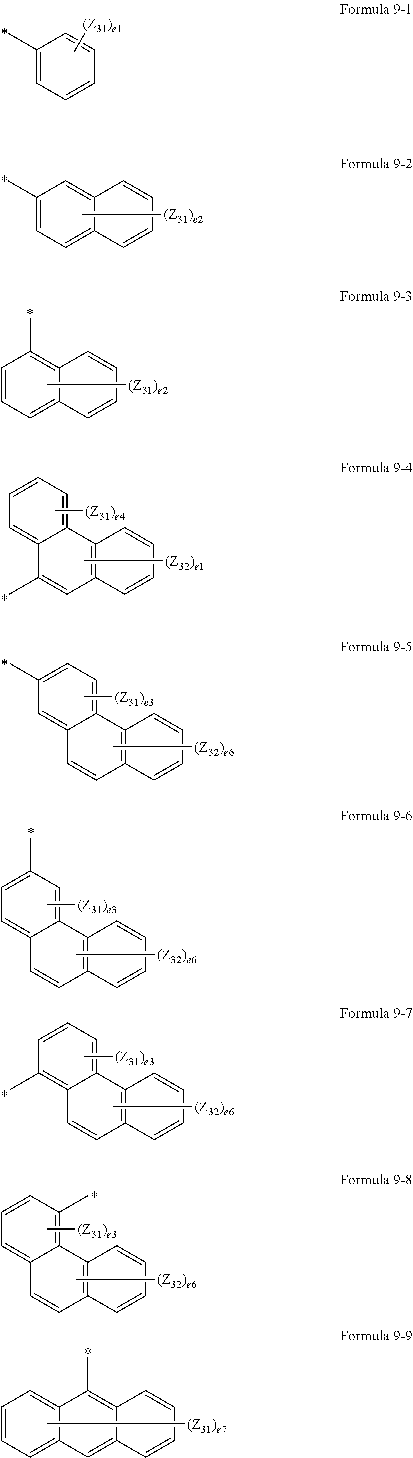 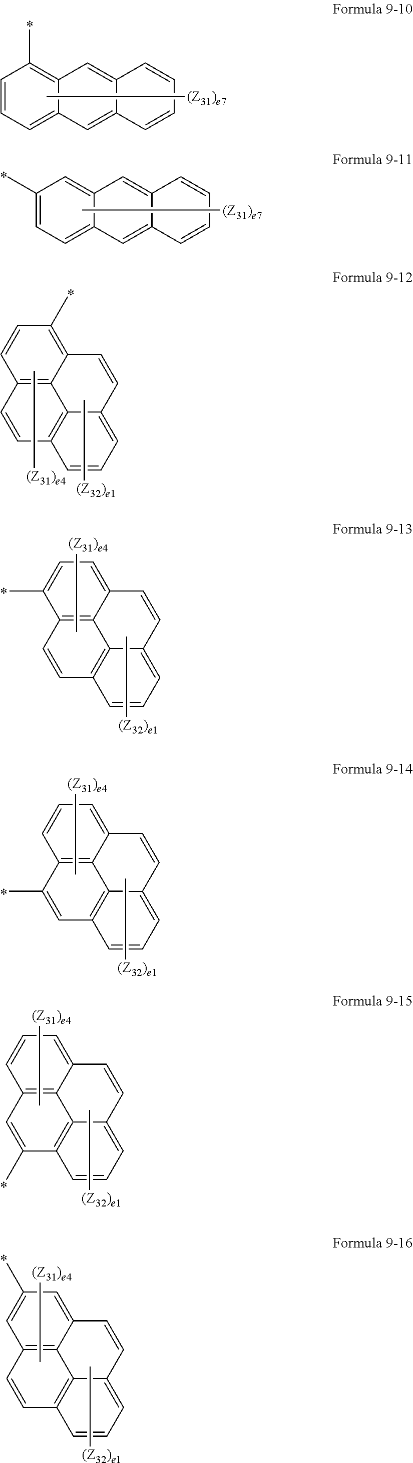
wherein, in Formulae 9-1 to 9-16,
Z₃₁ and Z₃₂ are each independently selected from:
a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, and a C₁-C₂₀ alkoxy group;
a C₁-C₂₀ alkyl group and a C₁-C₂₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, and a phosphoric acid group or a salt thereof;
a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a carbazolyl group, a benzocarbazolyl group, and a dibenzocarbazolyl group;
a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a carbazolyl group, a benzocarbazolyl group, and a dibenzocarbazolyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, and a naphthyl group; and
—Si(Q₃₁)(Q₃₂)(Q₃₃),
wherein Q₃₁ to Q₃₃ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, and a carbazolyl group;
e1 is an integer selected from 1 to 5, e2 is an integer selected from 1 to 7, e3 is an integer selected from 1 to 3, e4 is an integer selected from 1 to 4, e6 is an integer selected from 1 to 6, e7 is an integer selected from 1 to 9, and * indicates a binding site to a neighboring atom.

15. The organic light-emitting device as claimed in claim 1, wherein R₃₁ to R₃₄ and R₄₁ are each independently selected from a hydrogen, a deuterium, —F, —Cl, —Br, —I, a hydroxyl group, a cyano group, a nitro group, an amino group, an amidino group, a hydrazine group, a hydrazone group, a C₁-C₂₀ alkyl group, a C₁-C₂₀ alkoxy group, and a group represented by one of the following Formulae 10-1 to 10-10: 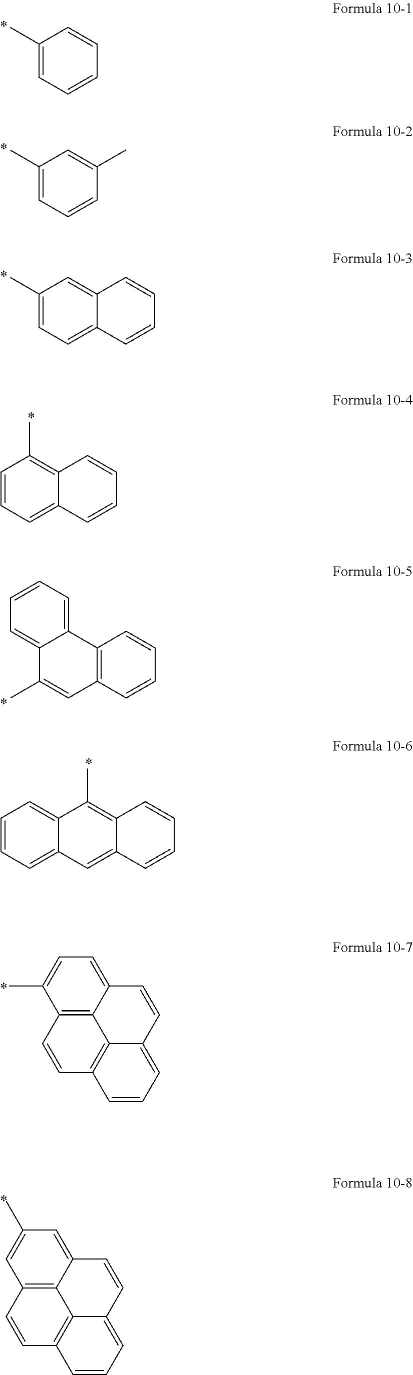 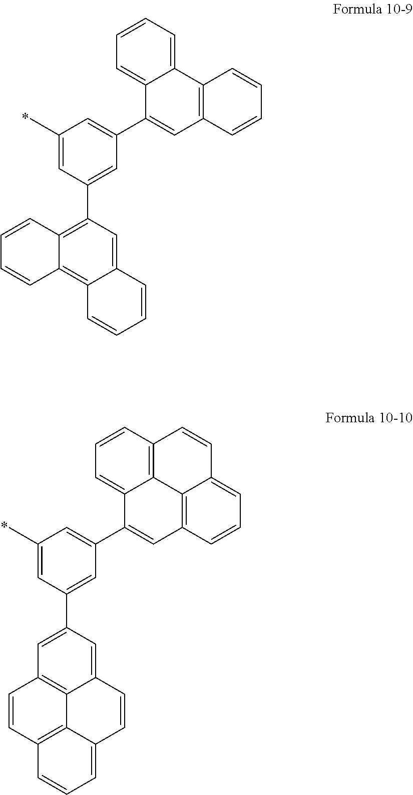
wherein, in Formulae 10-1 to 10-10, * indicates a binding site to a neighboring atom.

16. The organic light-emitting device as claimed in claim 1, wherein:
the first compound is represented by one of the following Formulae 1A to 1C, and
the second compound is represented by one of the following Formulae 2-1A to 2-1C, 2-2A, 2-3A, and 2-4A to 2-4D: 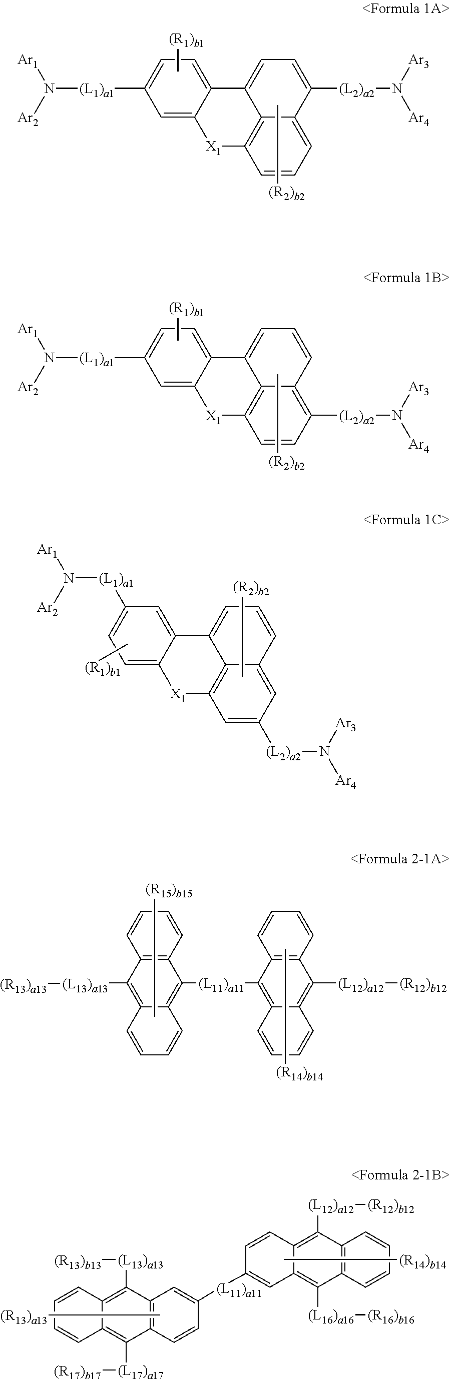 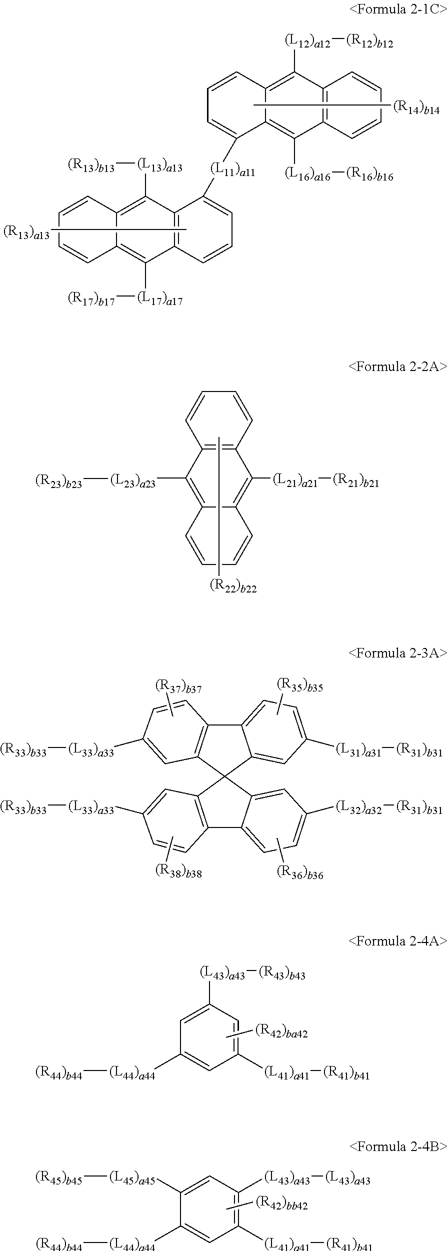 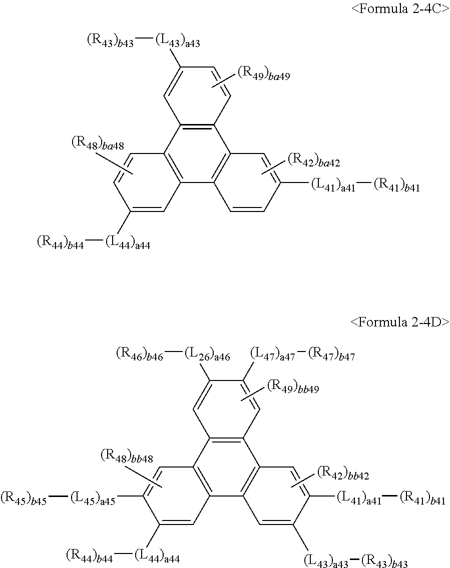
wherein in Formulae 1A to 1C, 2-1A to 2-1C, 2-2A, 2-3A, and 2-4A to 2-4D,
X₁, L₁, L₂, L₁₁ to L₁₃, L₂₁, L₃₁ to L₃₄, L₄₁, a1, a2, a11 to a13, a21, a31 to a34, a41, Ar₁ to Ar₄, R₁, R₂, R₁₂ to R₁₅, R₂₁, R₂₂, R₃₁ to R₃₈, R₄₁, R₄₂, b1, b2, b22, and b35 to b37 are defined the same as X₁, L₁, L₂, L₁₁ to L₁₃, L₂₁, L₃₁ to L₃₄, L₄₁, a1, a2, a11 to a13, a21, a31 to a34, a41, Ar₁ to Ar₄, R₁, R₂, R₁₂ to R₁₅, R₂₁, R₂₂, R₃₁ to R₃₈, R₄₁, R₄₂, b1, b2, b22, and b35 to b37 of Formulae 1 and 2-1 to 2-4;
L₁₆, L₁₇, and L₄₃ to L₄₇ are defined the same as L₁₁ of Formula 2-1;
a16, a17, and a43 to a47 are defined the same as a11 of Formula 2-1;
R₁₆ and R₁₇ are defined the same as R₁₂ of Formula 2-1;
R₄₃ to R₄₇ are defined the same as R₄₁ of Formula 2-4;
ba42, ba48, and ba49 are each independently selected from 1, 2, and 3, and
bb42, bb48, and bb49 are each independently selected from 1 and 2.

17. The organic light-emitting device as claimed in claim 1, wherein
the first compound is one of the following Compounds 1 to 83, and
the second compound is one of the following Compounds H-1 to H-65:

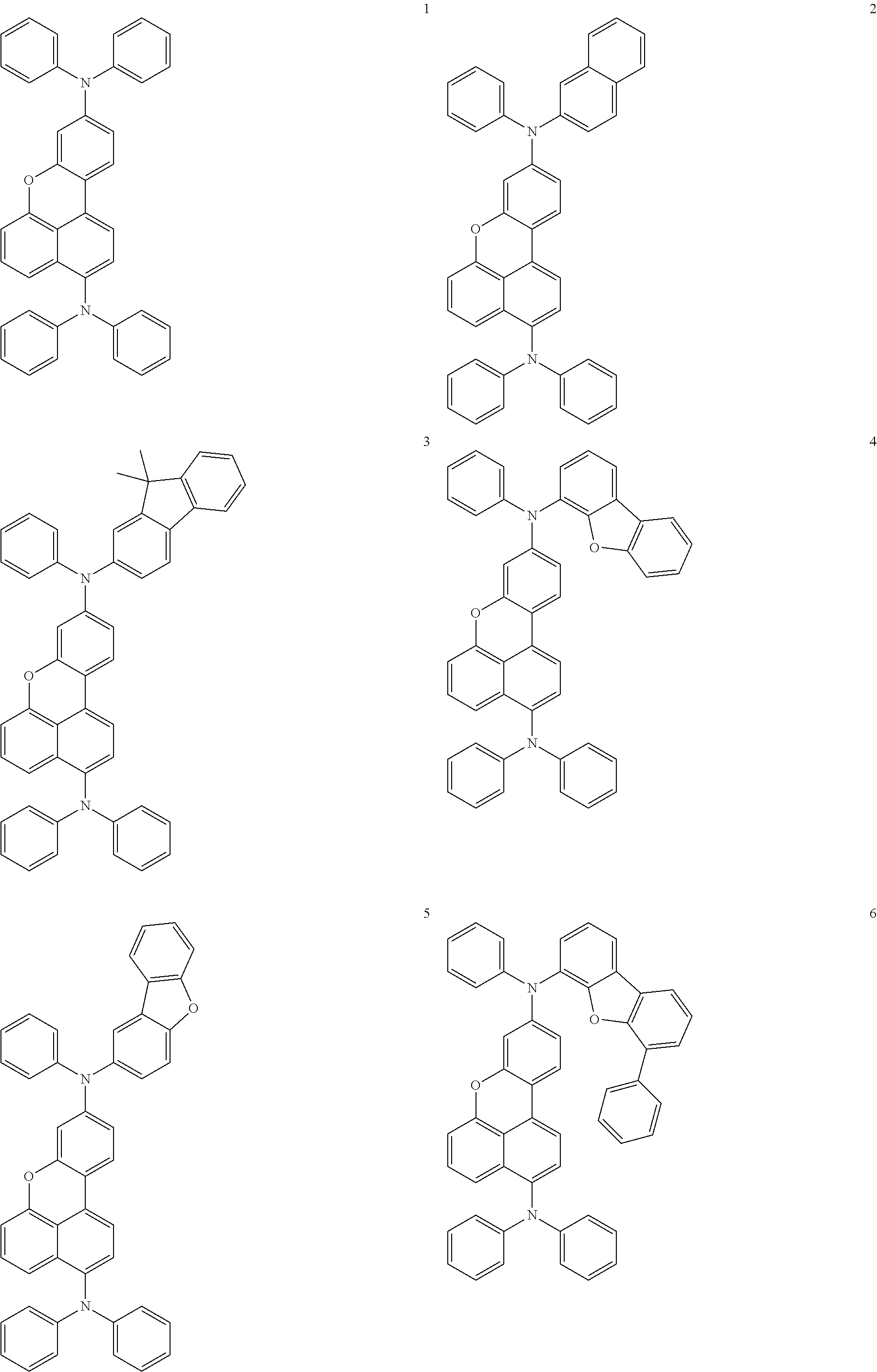

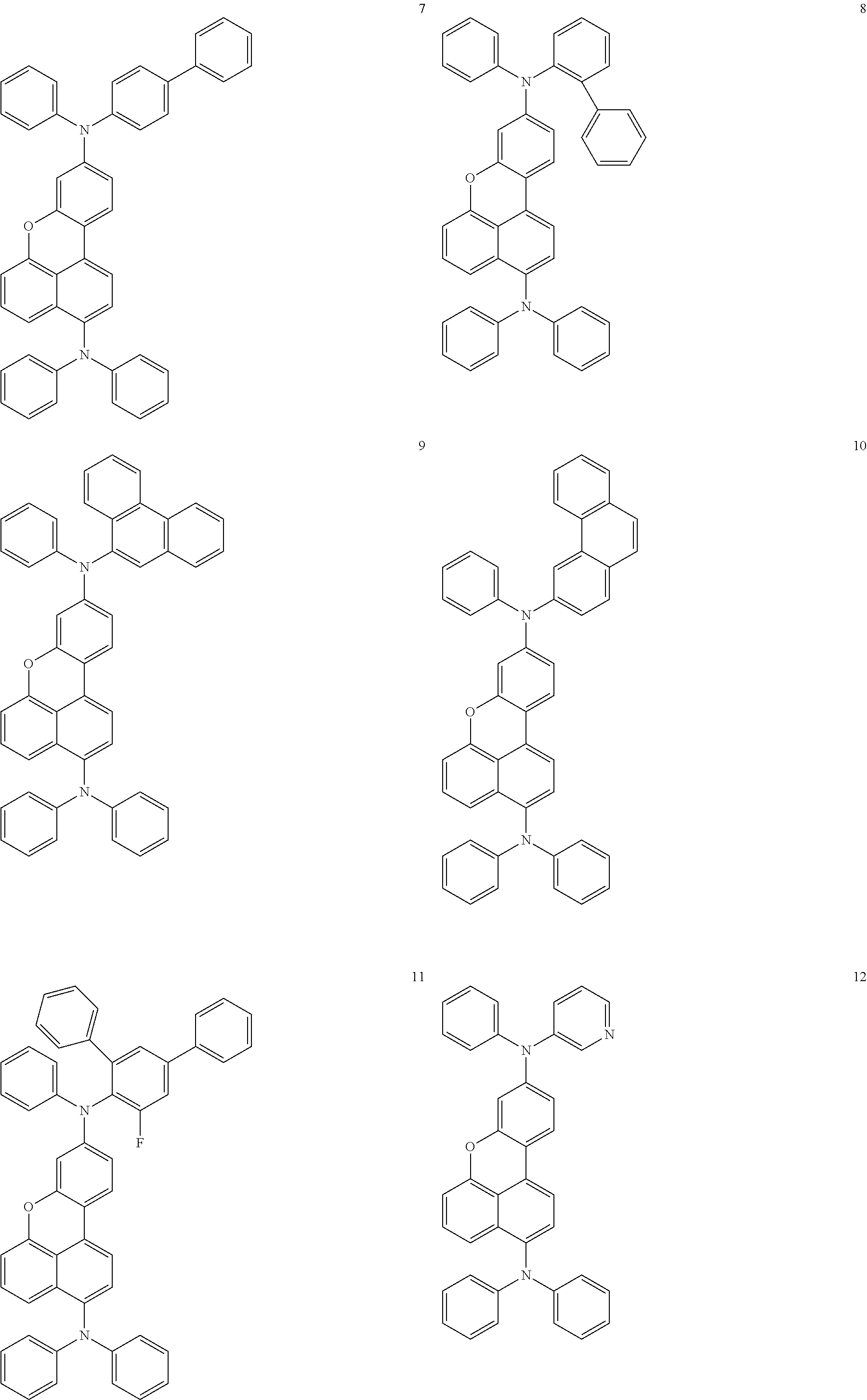 [SMILES: c1ccc(-c2ccc(N(c3ccccc3)c3ccc4c(c3)Oc3cccc5c(N(c6ccccc6)c6ccccc6)ccc-4c35)cc2)cc1 ; c1ccc(-c2ccccc2N(c2ccccc2)c2ccc3c(c2)Oc2cccc4c(N(c5ccccc5)c5ccccc5)ccc-3c24)cc1 ; c1ccc(N(c2ccccc2)c2ccc3c4c(cccc24)Oc2cc(N(c4ccccc4)c4cc5ccccc5c5ccccc45)ccc2-3)cc1 ; c1ccc(N(c2ccc3c(c2)Oc2cccc4c(N(c5ccccc5)c5ccccc5)ccc-3c24)c2ccc3ccc4ccccc4c3c2)cc1 ; Fc1cc(-c2ccccc2)cc(-c2ccccc2)c1N(c1ccccc1)c1ccc2c(c1)Oc1cccc3c(N(c4ccccc4)c4ccccc4)ccc-2c13 ; c1ccc(N(c2cccnc2)c2ccc3c(c2)Oc2cccc4c(N(c5ccccc5)c5ccccc5)ccc-3c24)cc1]

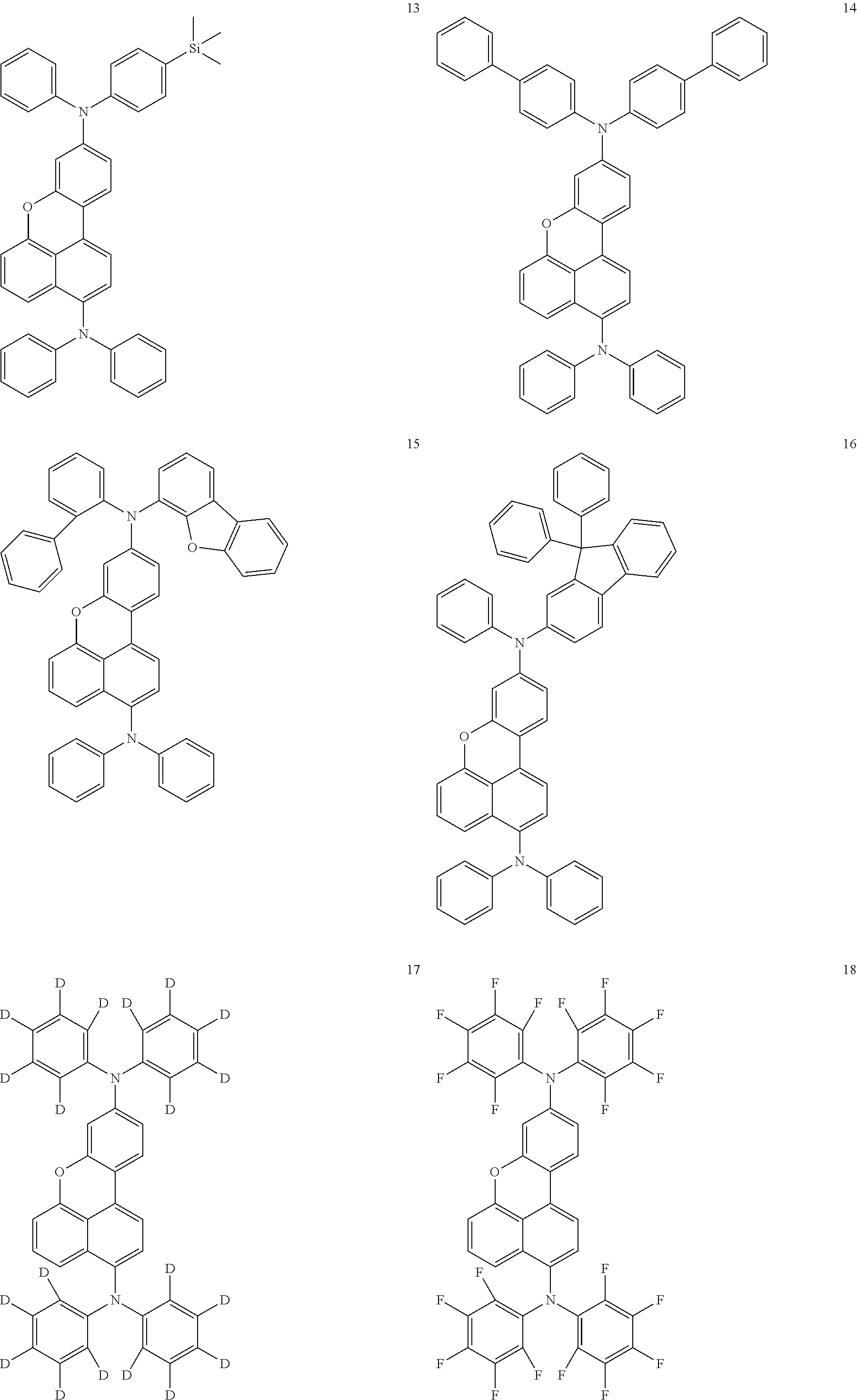

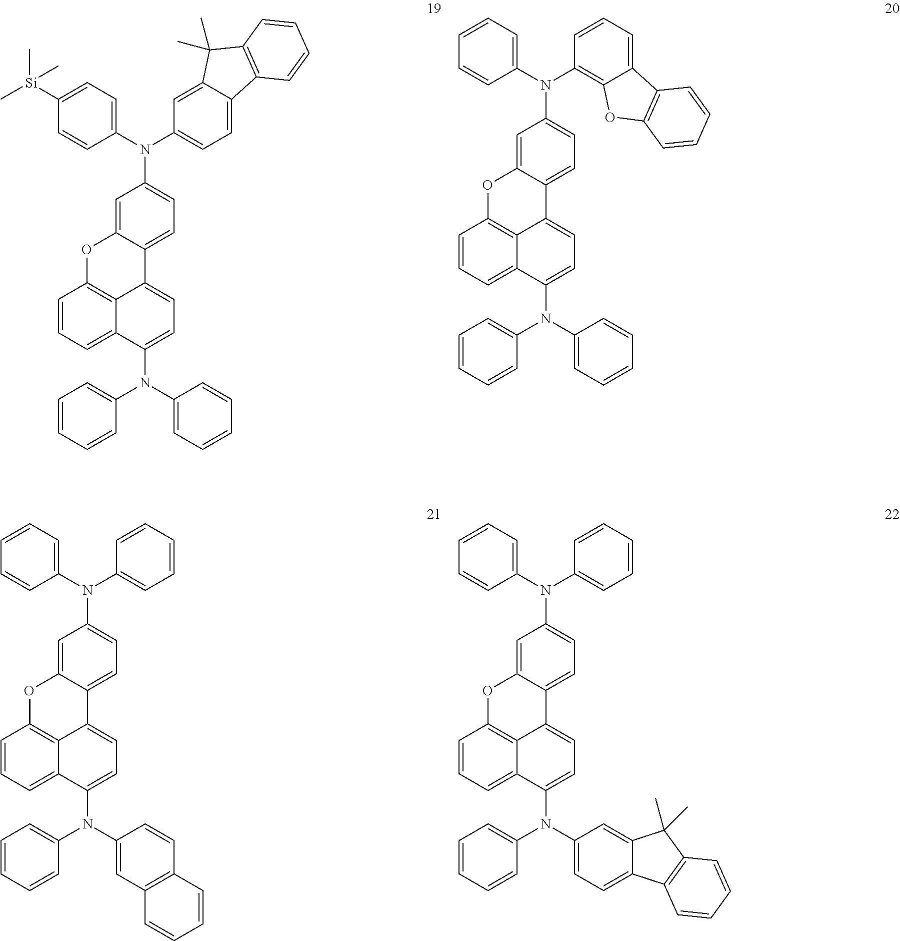 [SMILES: CC1(C)c2ccccc2-c2ccc(N(c3ccc([Si](C)(C)C)cc3)c3ccc4c(c3)Oc3cccc5c(N(c6ccccc6)c6ccccc6)ccc-4c35)cc21 ; c1ccc(N(c2ccccc2)c2ccc3c4c(cccc24)Oc2cc(N(c4ccccc4)c4cccc5c4oc4ccccc45)ccc2-3)cc1 ; c1ccc(N(c2ccccc2)c2ccc3c(c2)Oc2cccc4c(N(c5ccccc5)c5ccc6ccccc6c5)ccc-3c24)cc1 ; CC1(C)c2ccccc2-c2ccc(N(c3ccccc3)c3ccc4c5c(cccc35)Oc3cc(N(c5ccccc5)c5ccccc5)ccc3-4)cc21]

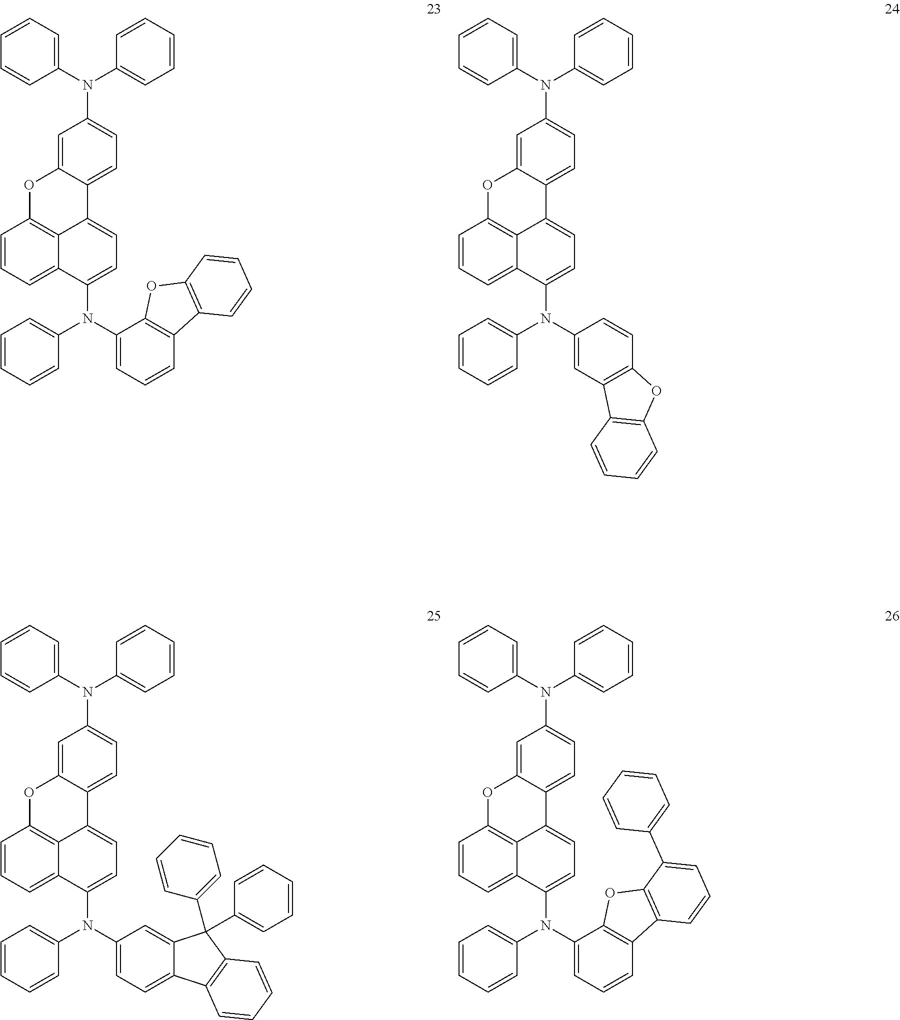 [SMILES: c1ccc(N(c2ccccc2)c2ccc3c(c2)Oc2cccc4c(N(c5ccccc5)c5cccc6c5oc5ccccc56)ccc-3c24)cc1 ; c1ccc(N(c2ccccc2)c2ccc3c(c2)Oc2cccc4c(N(c5ccccc5)c5ccc6oc7ccccc7c6c5)ccc-3c24)cc1 ; c1ccc(N(c2ccccc2)c2ccc3c(c2)Oc2cccc4c(N(c5ccccc5)c5ccc6c(c5)C(c5ccccc5)(c5ccccc5)c5ccccc5-6)ccc-3c24)cc1 ; c1ccc(-c2cccc3c2oc2c(N(c4ccccc4)c4ccc5c6c(cccc46)Oc4cc(N(c6ccccc6)c6ccccc6)ccc4-5)cccc23)cc1]

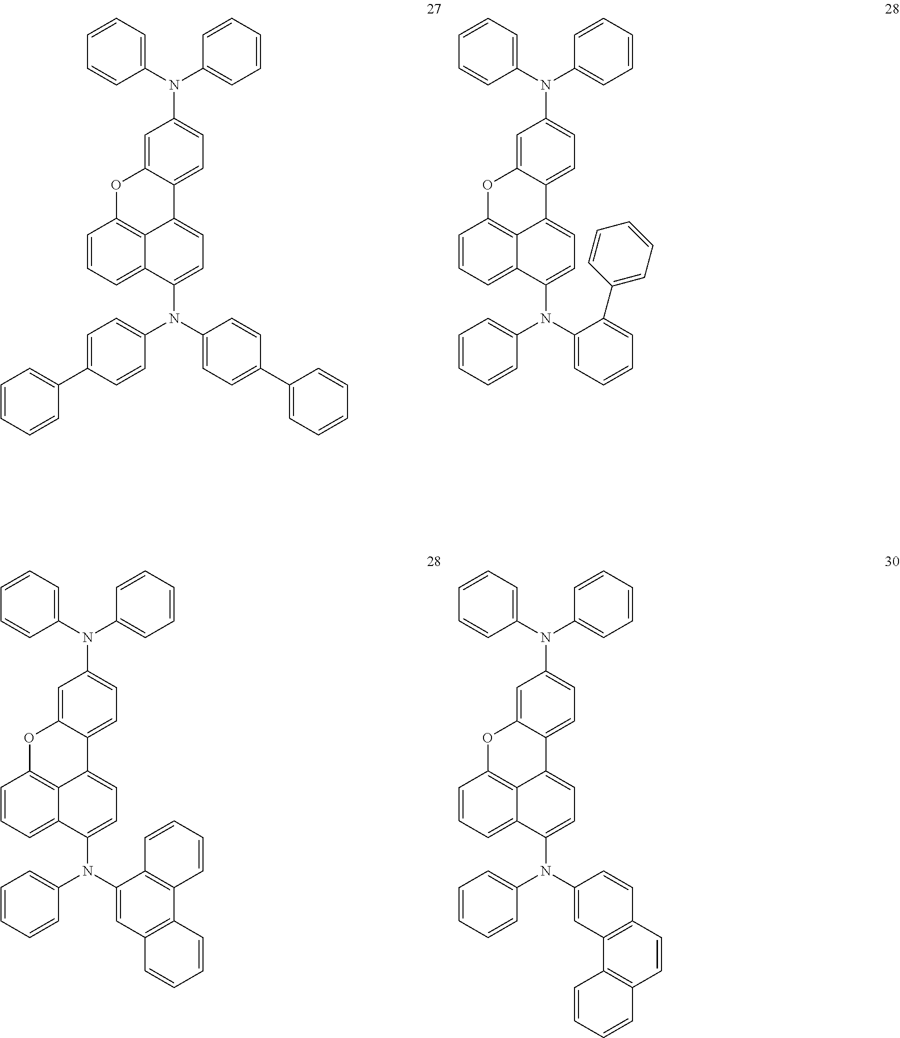 [SMILES: c1ccc(-c2ccc(N(c3ccc(-c4ccccc4)cc3)c3ccc4c5c(cccc35)Oc3cc(N(c5ccccc5)c5ccccc5)ccc3-4)cc2)cc1 ; c1ccc(-c2ccccc2N(c2ccccc2)c2ccc3c4c(cccc24)Oc2cc(N(c4ccccc4)c4ccccc4)ccc2-3)cc1 ; c1ccc(N(c2ccccc2)c2ccc3c(c2)Oc2cccc4c(N(c5ccccc5)c5cc6ccccc6c6ccccc56)ccc-3c24)cc1 ; c1ccc(N(c2ccccc2)c2ccc3c(c2)Oc2cccc4c(N(c5ccccc5)c5ccc6ccc7ccccc7c6c5)ccc-3c24)cc1]

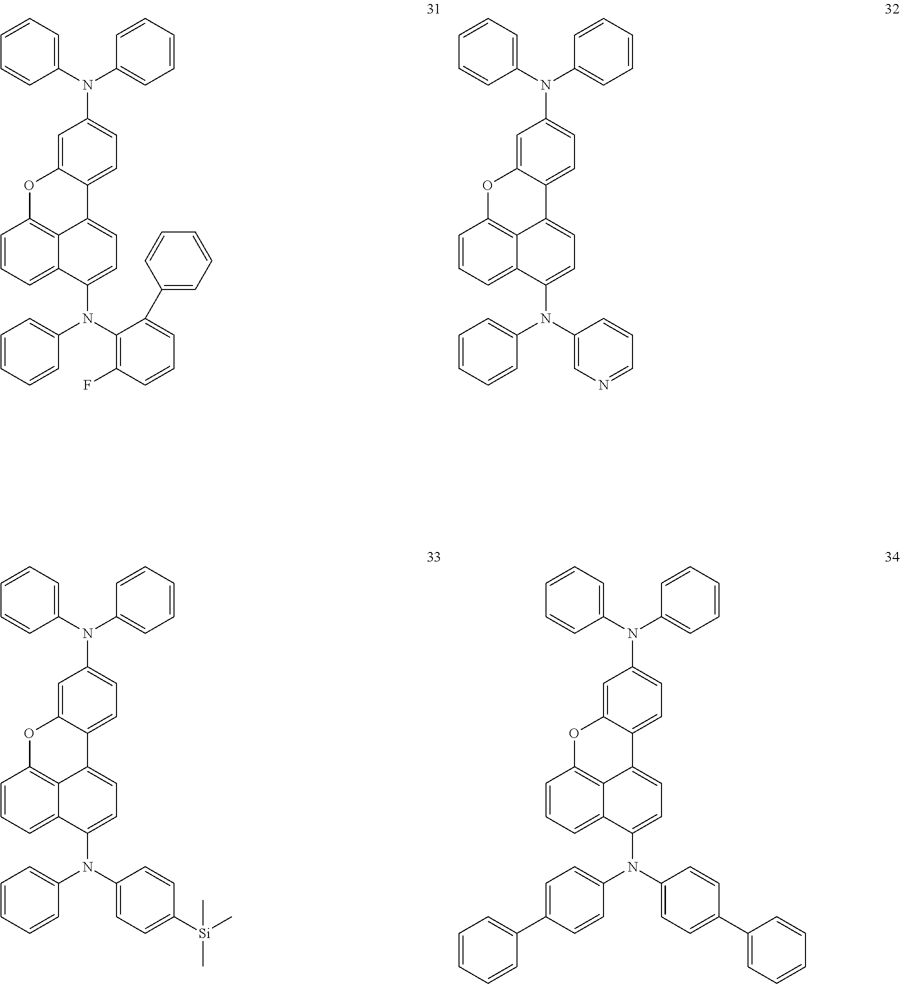 [SMILES: Fc1cccc(-c2ccccc2)c1N(c1ccccc1)c1ccc2c3c(cccc13)Oc1cc(N(c3ccccc3)c3ccccc3)ccc1-2 ; c1ccc(N(c2ccccc2)c2ccc3c(c2)Oc2cccc4c(N(c5ccccc5)c5cccnc5)ccc-3c24)cc1 ; C[Si](C)(C)c1ccc(N(c2ccccc2)c2ccc3c4c(cccc24)Oc2cc(N(c4ccccc4)c4ccccc4)ccc2-3)cc1 ; c1ccc(-c2ccc(N(c3ccc(-c4ccccc4)cc3)c3ccc4c5c(cccc35)Oc3cc(N(c5ccccc5)c5ccccc5)ccc3-4)cc2)cc1]

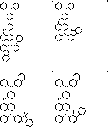 [SMILES: c1ccc(-c2ccccc2N(c2ccc3c4c(cccc24)Oc2cc(-c4ccc(N(c5ccccc5)c5ccccc5)cc4)ccc2-3)c2cccc3c2oc2ccccc23)cc1 ; c1ccc(N(c2ccccc2)c2ccc3c(c2)Oc2cccc4c(N(c5ccccc5)c5cccc6c5oc5ccccc56)ccc-3c24)cc1 ; CC1(C)c2ccccc2-c2ccc(N(c3ccccc3)c3ccc4c5c(cccc35)Oc3cc(N(c5ccccc5)c5ccc6ccccc6c5)ccc3-4)cc21 ; c1ccc(N(c2ccc3c(c2)Oc2cccc4c(N(c5ccccc5)c5cccc6c5oc5ccccc56)ccc-3c24)c2ccc3ccccc3c2)cc1]

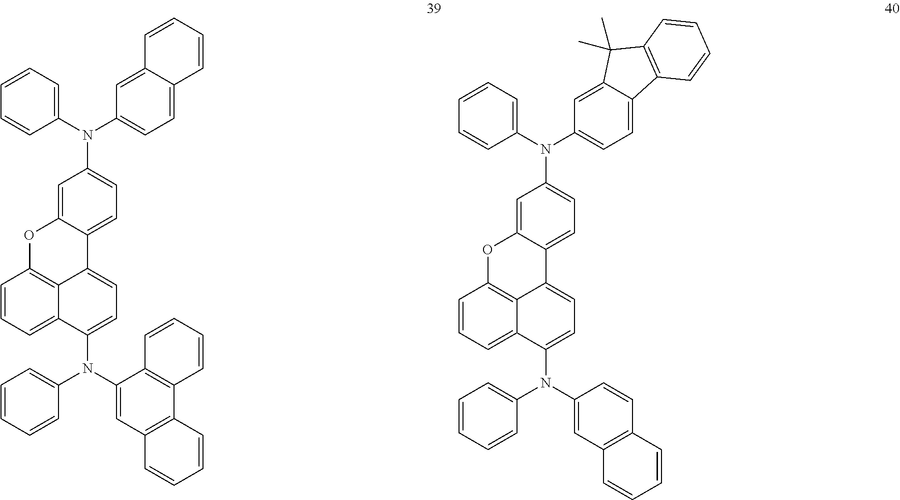 [SMILES: c1ccc(N(c2ccc3c(c2)Oc2cccc4c(N(c5ccccc5)c5cc6ccccc6c6ccccc56)ccc-3c24)c2ccc3ccccc3c2)cc1 ; CC1(C)c2ccccc2-c2ccc(N(c3ccccc3)c3ccc4c(c3)Oc3cccc5c(N(c6ccccc6)c6ccc7ccccc7c6)ccc-4c35)cc21]

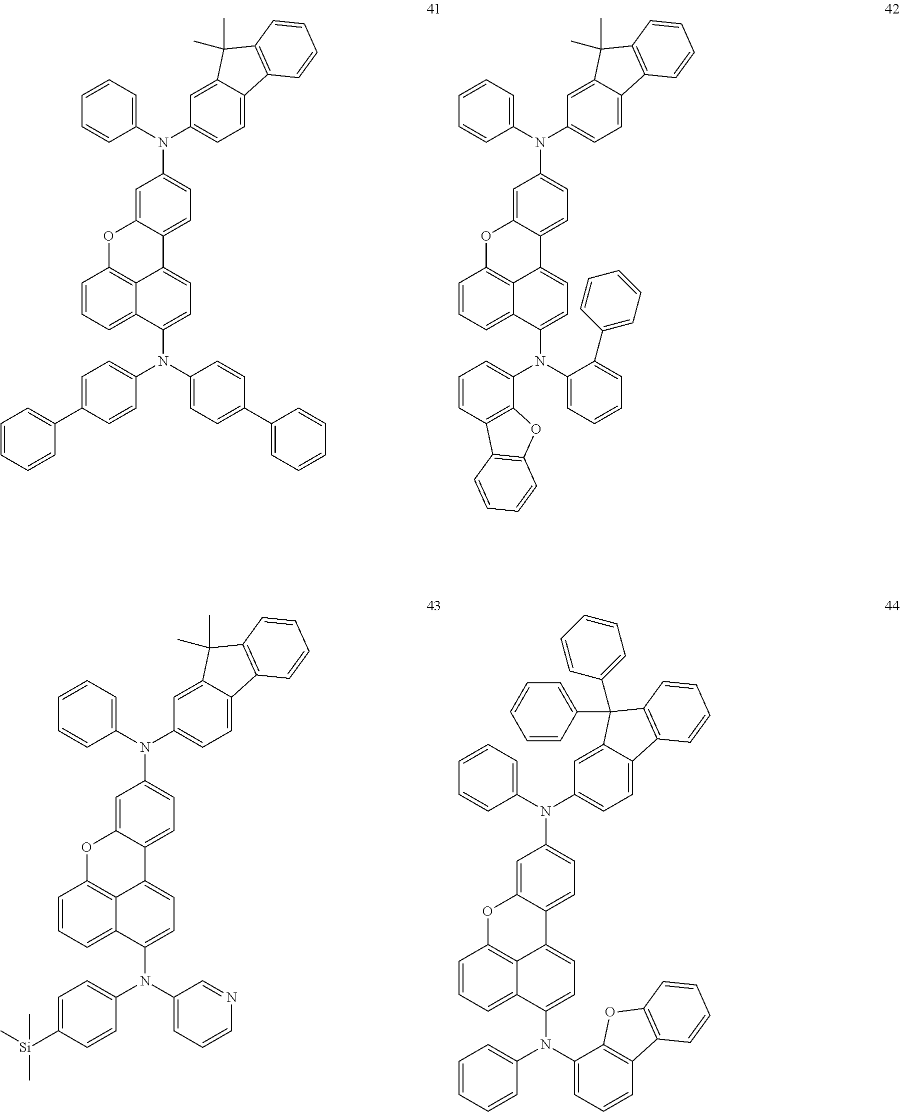 [SMILES: CC1(C)c2ccccc2-c2ccc(N(c3ccccc3)c3ccc4c(c3)Oc3cccc5c(N(c6ccc(-c7ccccc7)cc6)c6ccc(-c7ccccc7)cc6)ccc-4c35)cc21 ; CC1(C)c2ccccc2-c2ccc(N(c3ccccc3)c3ccc4c(c3)Oc3cccc5c(N(c6ccccc6-c6ccccc6)c6cccc7c6oc6ccccc67)ccc-4c35)cc21 ; CC1(C)c2ccccc2-c2ccc(N(c3ccccc3)c3ccc4c(c3)Oc3cccc5c(N(c6ccc([Si](C)(C)C)cc6)c6cccnc6)ccc-4c35)cc21 ; c1ccc(N(c2ccc3c(c2)Oc2cccc4c(N(c5ccccc5)c5cccc6c5oc5ccccc56)ccc-3c24)c2ccc3c(c2)C(c2ccccc2)(c2ccccc2)c2ccccc2-3)cc1]

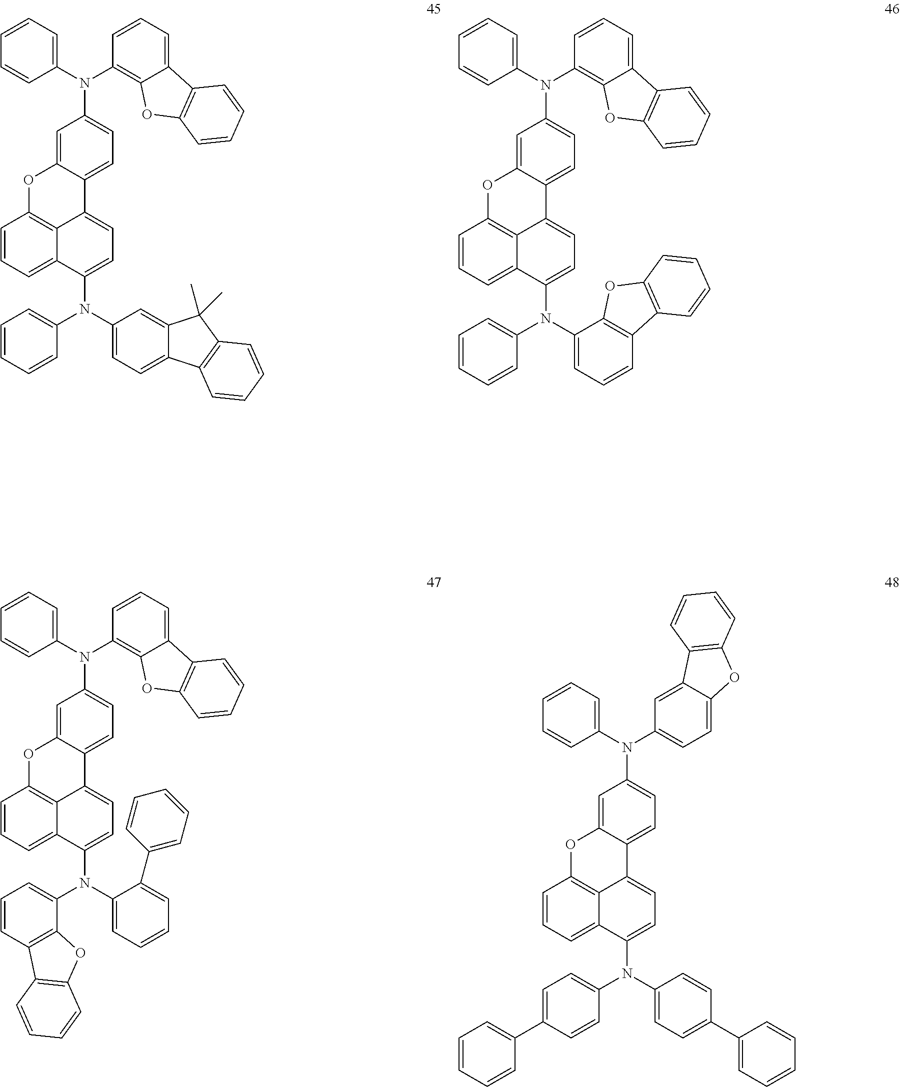 [SMILES: CC1(C)c2ccccc2-c2ccc(N(c3ccccc3)c3ccc4c5c(cccc35)Oc3cc(N(c5ccccc5)c5cccc6c5oc5ccccc56)ccc3-4)cc21 ; c1ccc(N(c2ccc3c(c2)Oc2cccc4c(N(c5ccccc5)c5cccc6c5oc5ccccc56)ccc-3c24)c2cccc3c2oc2ccccc23)cc1 ; c1ccc(-c2ccccc2N(c2ccc3c4c(cccc24)Oc2cc(N(c4ccccc4)c4cccc5c4oc4ccccc45)ccc2-3)c2cccc3c2oc2ccccc23)cc1 ; c1ccc(-c2ccc(N(c3ccc(-c4ccccc4)cc3)c3ccc4c5c(cccc35)Oc3cc(N(c5ccccc5)c5ccc6oc7ccccc7c6c5)ccc3-4)cc2)cc1]

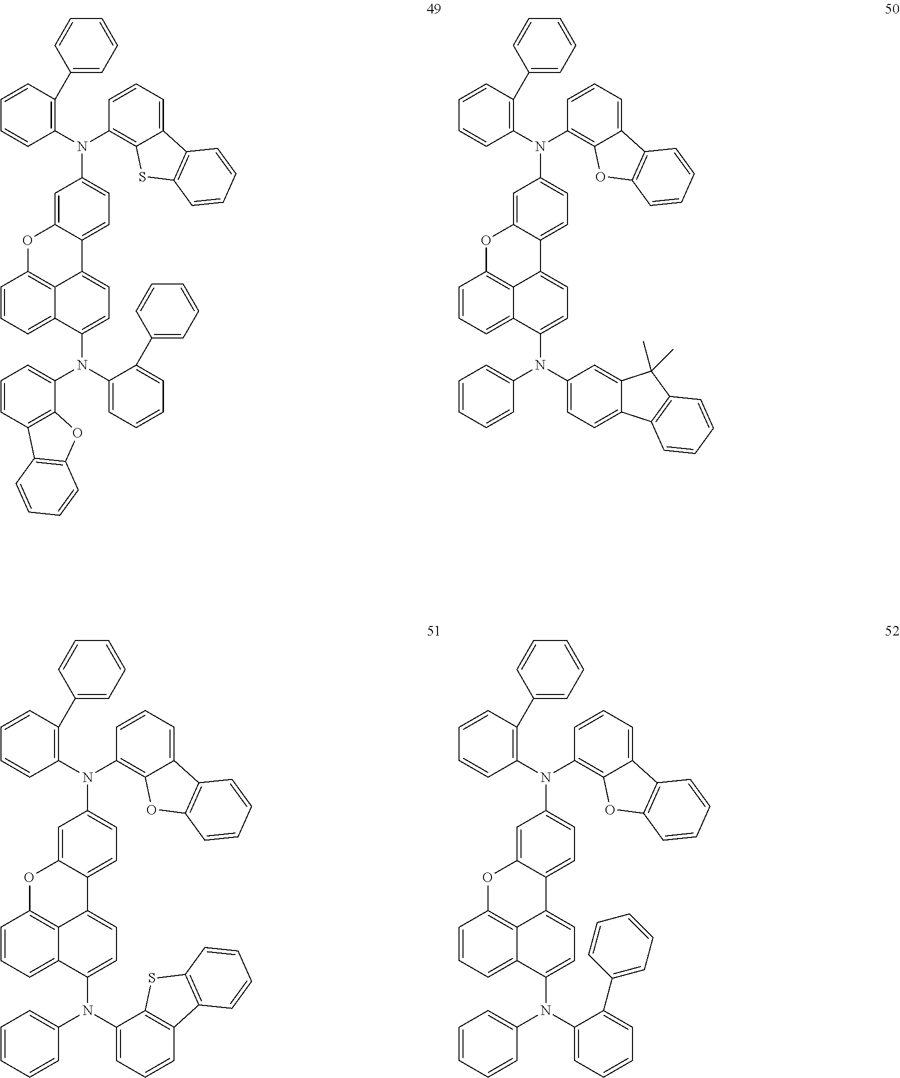 [SMILES: c1ccc(-c2ccccc2N(c2ccc3c4c(cccc24)Oc2cc(N(c4ccccc4-c4ccccc4)c4cccc5c4sc4ccccc45)ccc2-3)c2cccc3c2oc2ccccc23)cc1 ; CC1(C)c2ccccc2-c2ccc(N(c3ccccc3)c3ccc4c5c(cccc35)Oc3cc(N(c5ccccc5-c5ccccc5)c5cccc6c5oc5ccccc56)ccc3-4)cc21 ; c1ccc(-c2ccccc2N(c2ccc3c(c2)Oc2cccc4c(N(c5ccccc5)c5cccc6c5sc5ccccc56)ccc-3c24)c2cccc3c2oc2ccccc23)cc1 ; c1ccc(-c2ccccc2N(c2ccccc2)c2ccc3c4c(cccc24)Oc2cc(N(c4ccccc4-c4ccccc4)c4cccc5c4oc4ccccc45)ccc2-3)cc1]

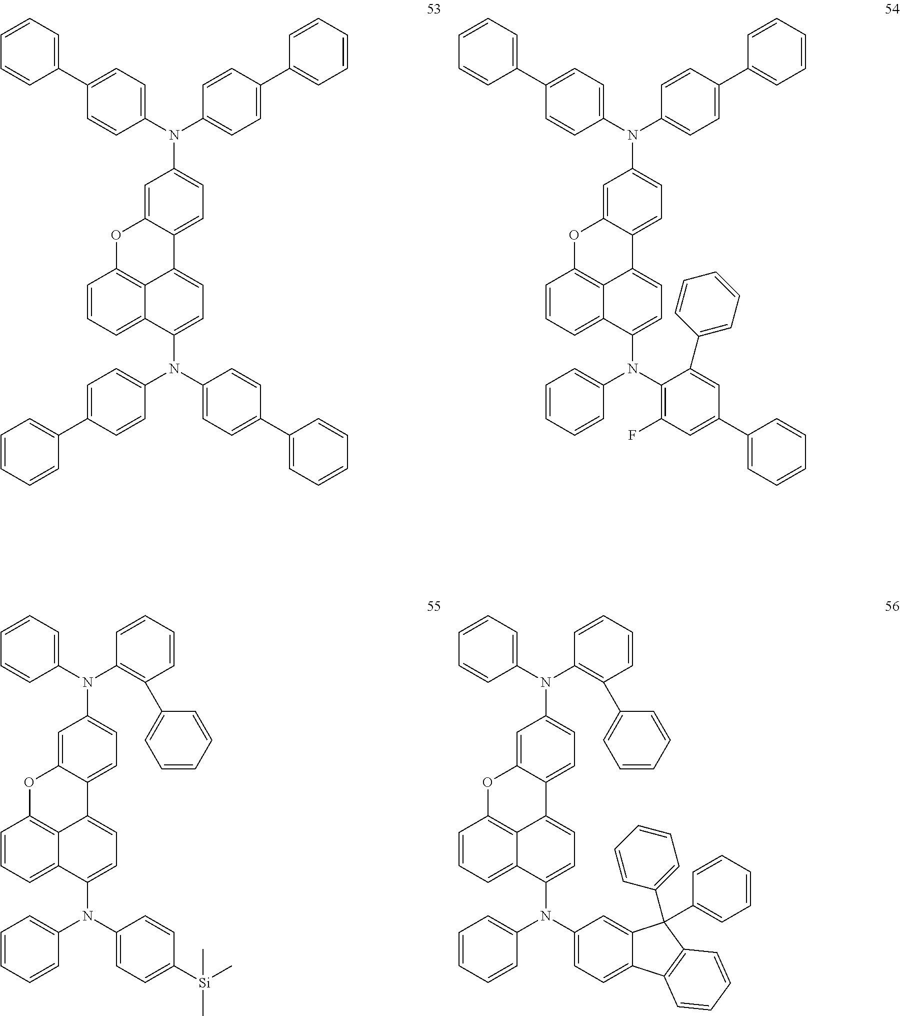 [SMILES: c1ccc(-c2ccc(N(c3ccc(-c4ccccc4)cc3)c3ccc4c(c3)Oc3cccc5c(N(c6ccc(-c7ccccc7)cc6)c6ccc(-c7ccccc7)cc6)ccc-4c35)cc2)cc1 ; Fc1cc(-c2ccccc2)cc(-c2ccccc2)c1N(c1ccccc1)c1ccc2c3c(cccc13)Oc1cc(N(c3ccc(-c4ccccc4)cc3)c3ccc(-c4ccccc4)cc3)ccc1-2 ; C[Si](C)(C)c1ccc(N(c2ccccc2)c2ccc3c4c(cccc24)Oc2cc(N(c4ccccc4)c4ccccc4-c4ccccc4)ccc2-3)cc1 ; c1ccc(-c2ccccc2N(c2ccccc2)c2ccc3c(c2)Oc2cccc4c(N(c5ccccc5)c5ccc6c(c5)C(c5ccccc5)(c5ccccc5)c5ccccc5-6)ccc-3c24)cc1]

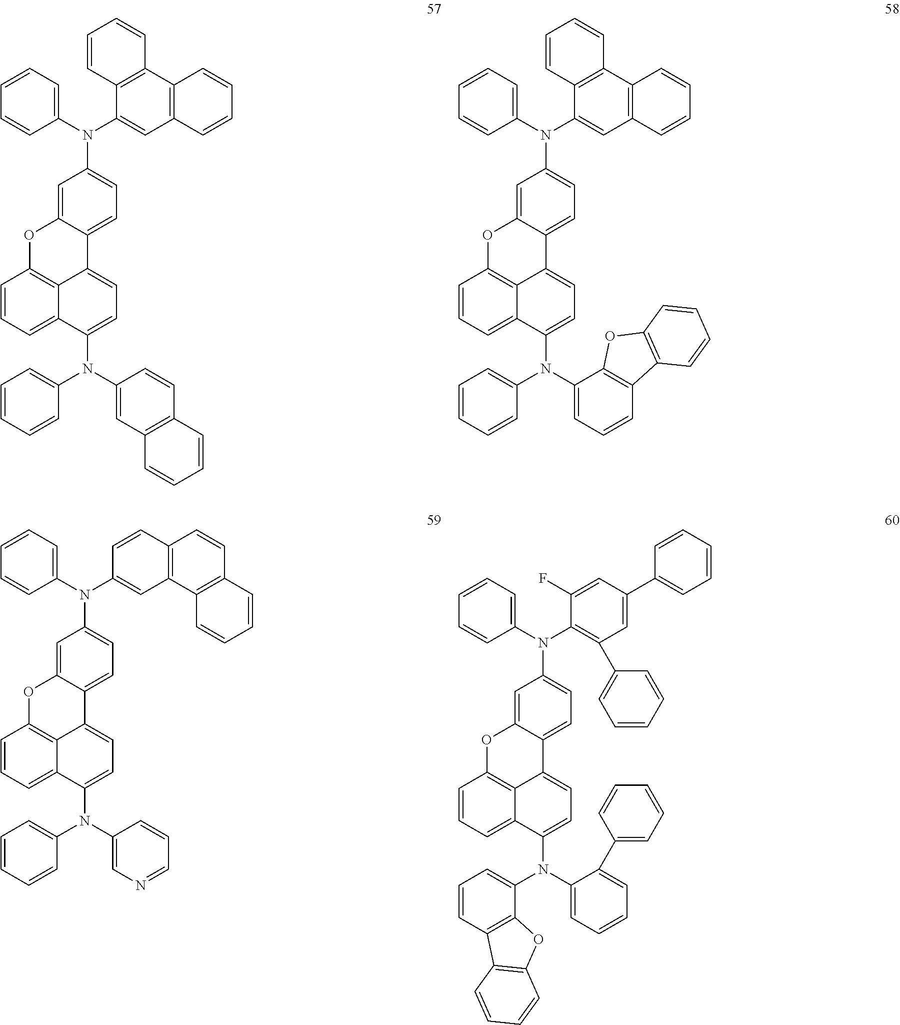 [SMILES: c1ccc(N(c2ccc3ccccc3c2)c2ccc3c4c(cccc24)Oc2cc(N(c4ccccc4)c4cc5ccccc5c5ccccc45)ccc2-3)cc1 ; c1ccc(N(c2ccc3c(c2)Oc2cccc4c(N(c5ccccc5)c5cccc6c5oc5ccccc56)ccc-3c24)c2cc3ccccc3c3ccccc23)cc1 ; c1ccc(N(c2ccc3c(c2)Oc2cccc4c(N(c5ccccc5)c5cccnc5)ccc-3c24)c2ccc3ccc4ccccc4c3c2)cc1 ; Fc1cc(-c2ccccc2)cc(-c2ccccc2)c1N(c1ccccc1)c1ccc2c(c1)Oc1cccc3c(N(c4ccccc4-c4ccccc4)c4cccc5c4oc4ccccc45)ccc-2c13]

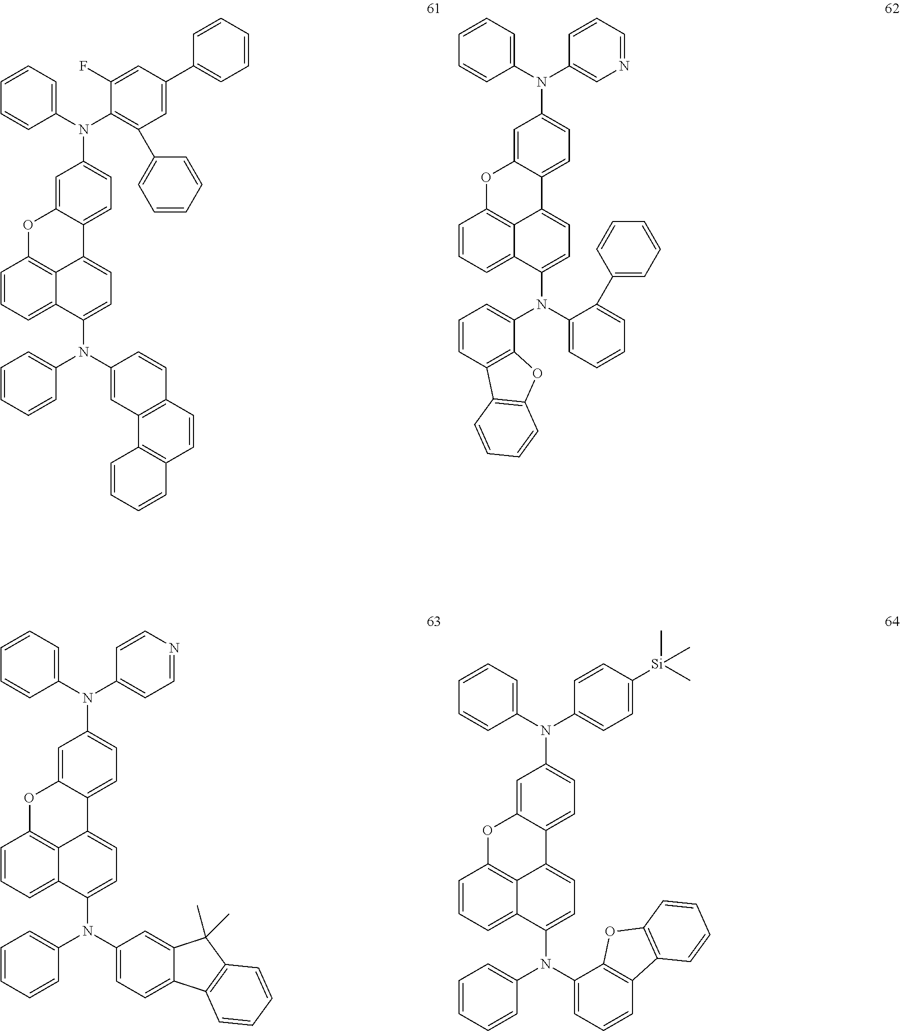 [SMILES: Fc1cc(-c2ccccc2)cc(-c2ccccc2)c1N(c1ccccc1)c1ccc2c(c1)Oc1cccc3c(N(c4ccccc4)c4ccc5ccc6ccccc6c5c4)ccc-2c13 ; c1ccc(-c2ccccc2N(c2ccc3c4c(cccc24)Oc2cc(N(c4ccccc4)c4cccnc4)ccc2-3)c2cccc3c2oc2ccccc23)cc1 ; CC1(C)c2ccccc2-c2ccc(N(c3ccccc3)c3ccc4c5c(cccc35)Oc3cc(N(c5ccccc5)c5ccncc5)ccc3-4)cc21 ; C[Si](C)(C)c1ccc(N(c2ccccc2)c2ccc3c(c2)Oc2cccc4c(N(c5ccccc5)c5cccc6c5oc5ccccc56)ccc-3c24)cc1]

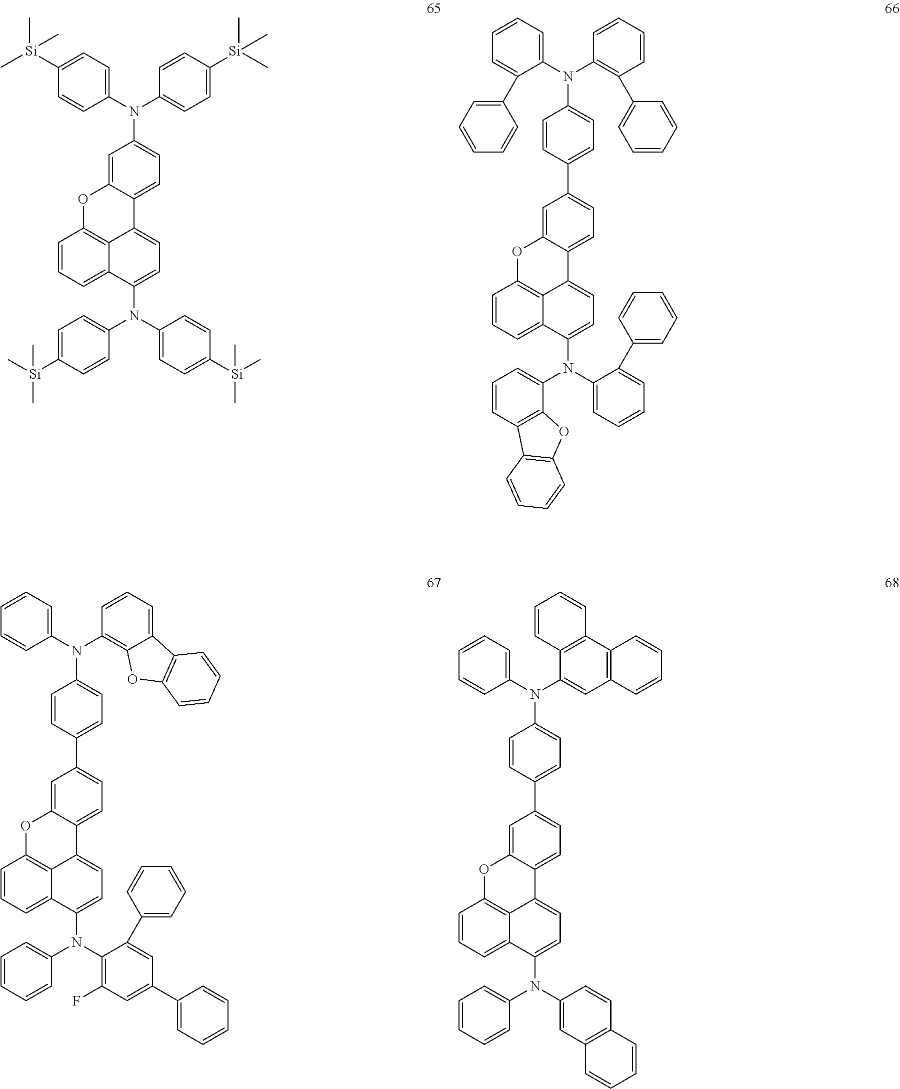

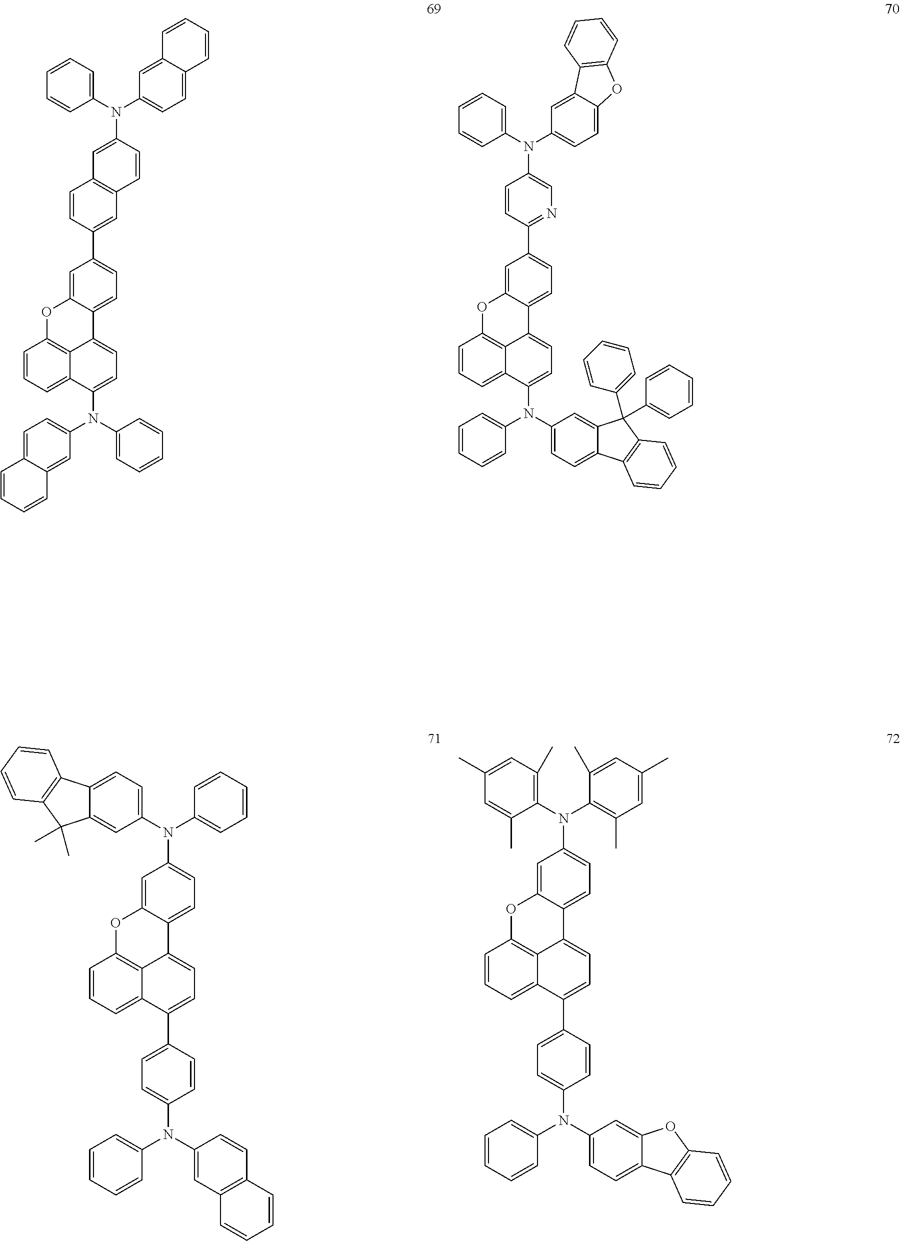 [SMILES: c1ccc(N(c2ccc3ccccc3c2)c2ccc3cc(-c4ccc5c(c4)Oc4cccc6c(N(c7ccccc7)c7ccc8ccccc8c7)ccc-5c46)ccc3c2)cc1 ; c1ccc(N(c2ccc(-c3ccc4c(c3)Oc3cccc5c(N(c6ccccc6)c6ccc7c(c6)C(c6ccccc6)(c6ccccc6)c6ccccc6-7)ccc-4c35)nc2)c2ccc3oc4ccccc4c3c2)cc1 ; CC1(C)c2ccccc2-c2ccc(N(c3ccccc3)c3ccc4c(c3)Oc3cccc5c(-c6ccc(N(c7ccccc7)c7ccc8ccccc8c7)cc6)ccc-4c35)cc21 ; Cc1cc(C)c(N(c2ccc3c(c2)Oc2cccc4c(-c5ccc(N(c6ccccc6)c6ccc7c(c6)oc6ccccc67)cc5)ccc-3c24)c2c(C)cc(C)cc2C)c(C)c1]

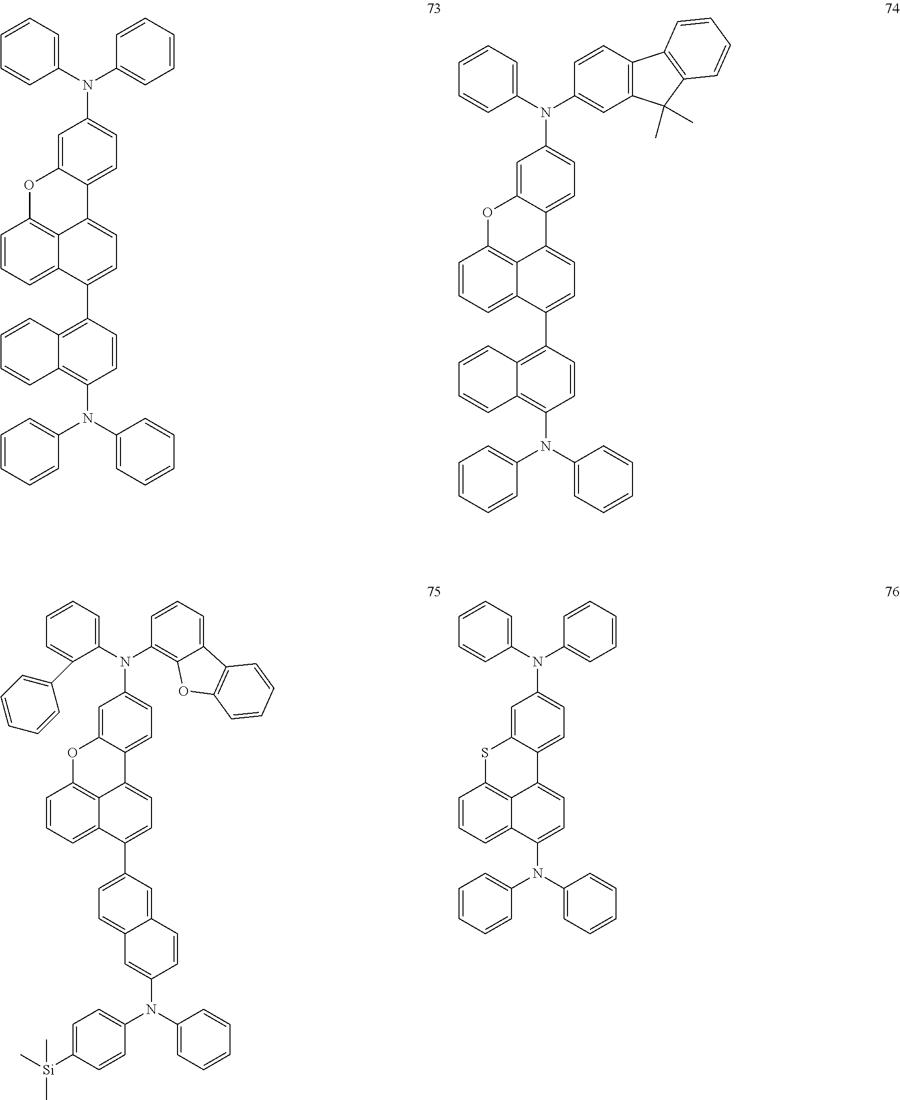 [SMILES: c1ccc(N(c2ccccc2)c2ccc3c(c2)Oc2cccc4c(-c5ccc(N(c6ccccc6)c6ccccc6)c6ccccc56)ccc-3c24)cc1 ; CC1(C)c2ccccc2-c2ccc(N(c3ccccc3)c3ccc4c(c3)Oc3cccc5c(-c6ccc(N(c7ccccc7)c7ccccc7)c7ccccc67)ccc-4c35)cc21 ; C[Si](C)(C)c1ccc(N(c2ccccc2)c2ccc3cc(-c4ccc5c6c(cccc46)Oc4cc(N(c6ccccc6-c6ccccc6)c6cccc7c6oc6ccccc67)ccc4-5)ccc3c2)cc1 ; c1ccc(N(c2ccccc2)c2ccc3c(c2)Sc2cccc4c(N(c5ccccc5)c5ccccc5)ccc-3c24)cc1]

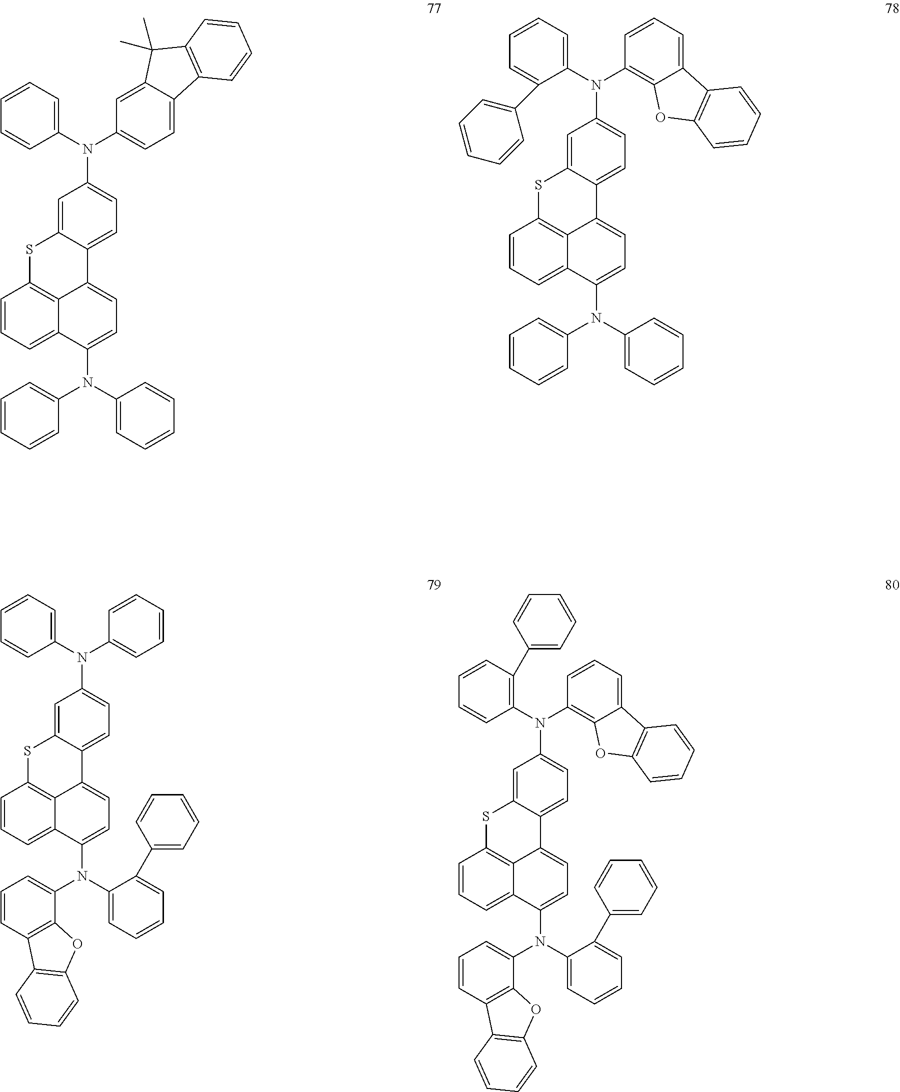 [SMILES: CC1(C)c2ccccc2-c2ccc(N(c3ccccc3)c3ccc4c(c3)Sc3cccc5c(N(c6ccccc6)c6ccccc6)ccc-4c35)cc21 ; c1ccc(-c2ccccc2N(c2ccc3c(c2)Sc2cccc4c(N(c5ccccc5)c5ccccc5)ccc-3c24)c2cccc3c2oc2ccccc23)cc1 ; c1ccc(-c2ccccc2N(c2ccc3c4c(cccc24)Sc2cc(N(c4ccccc4)c4ccccc4)ccc2-3)c2cccc3c2oc2ccccc23)cc1 ; c1ccc(-c2ccccc2N(c2ccc3c(c2)Sc2cccc4c(N(c5ccccc5-c5ccccc5)c5cccc6c5oc5ccccc56)ccc-3c24)c2cccc3c2oc2ccccc23)cc1]

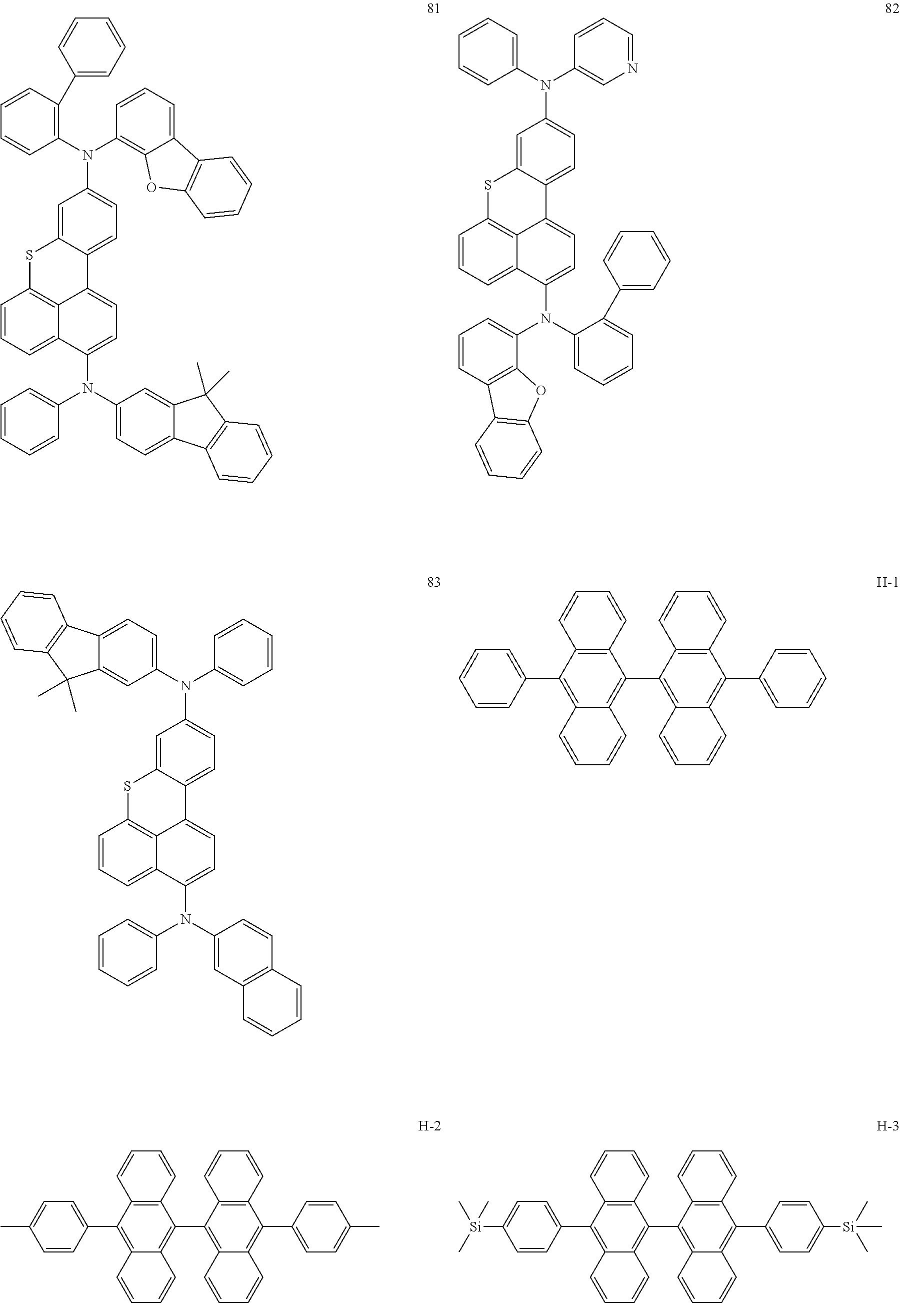

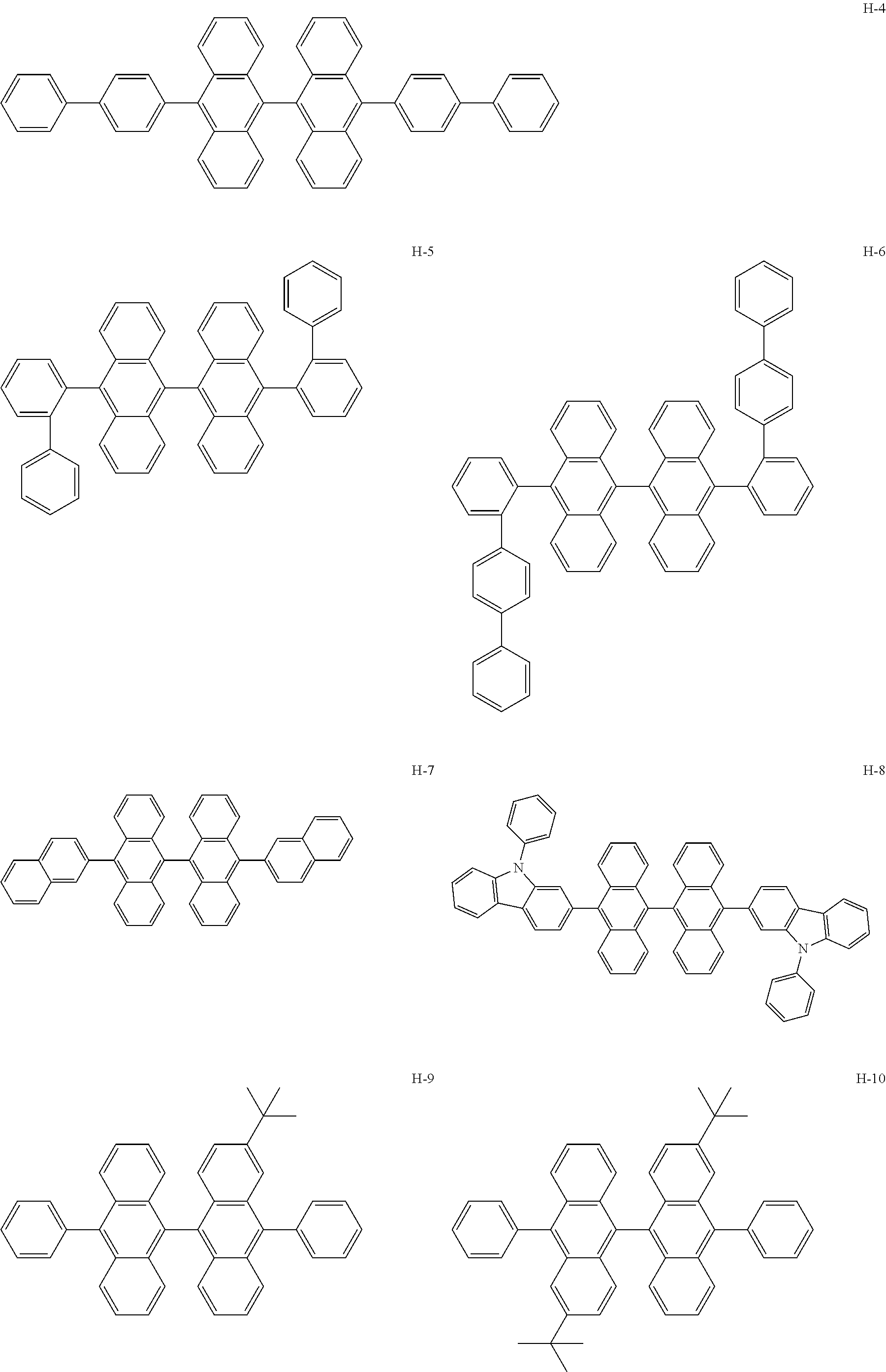

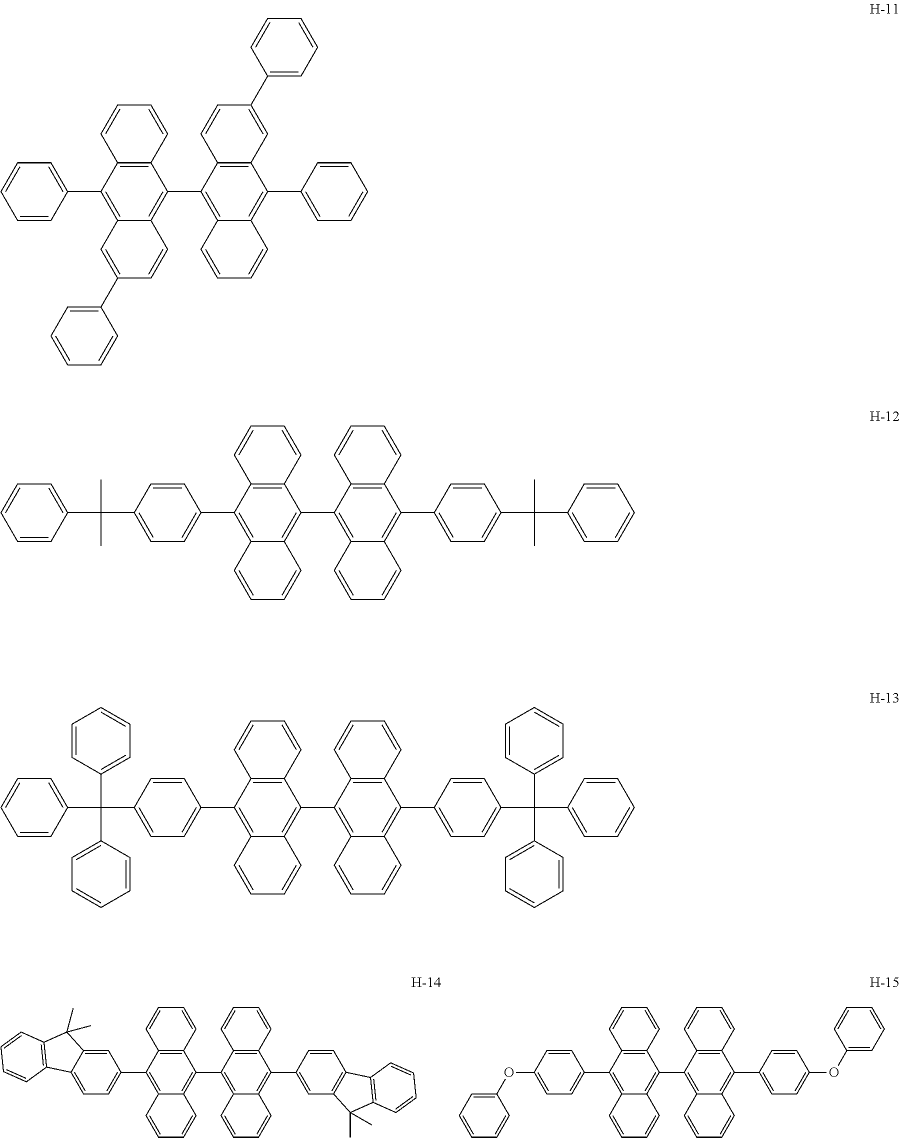

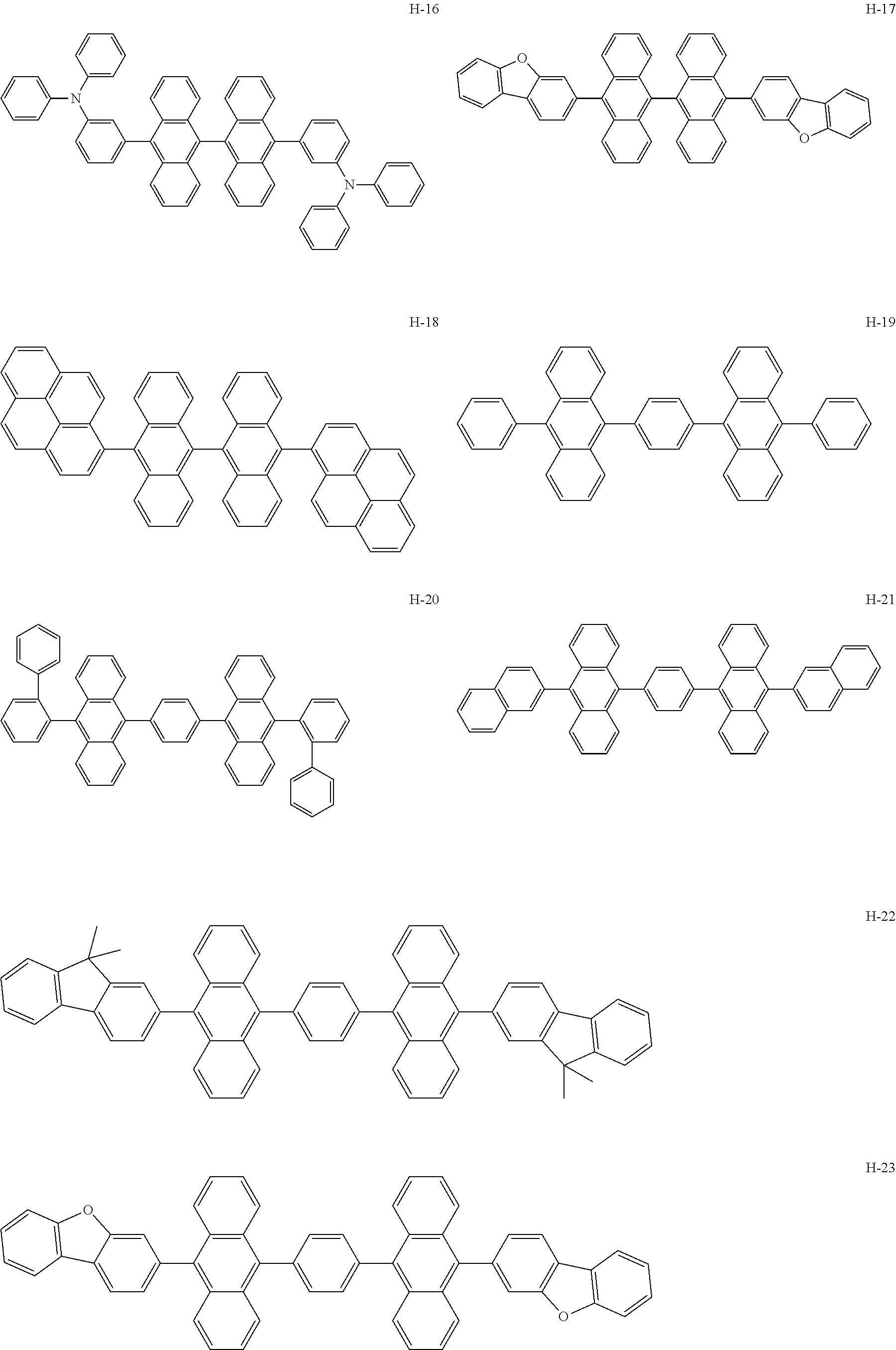

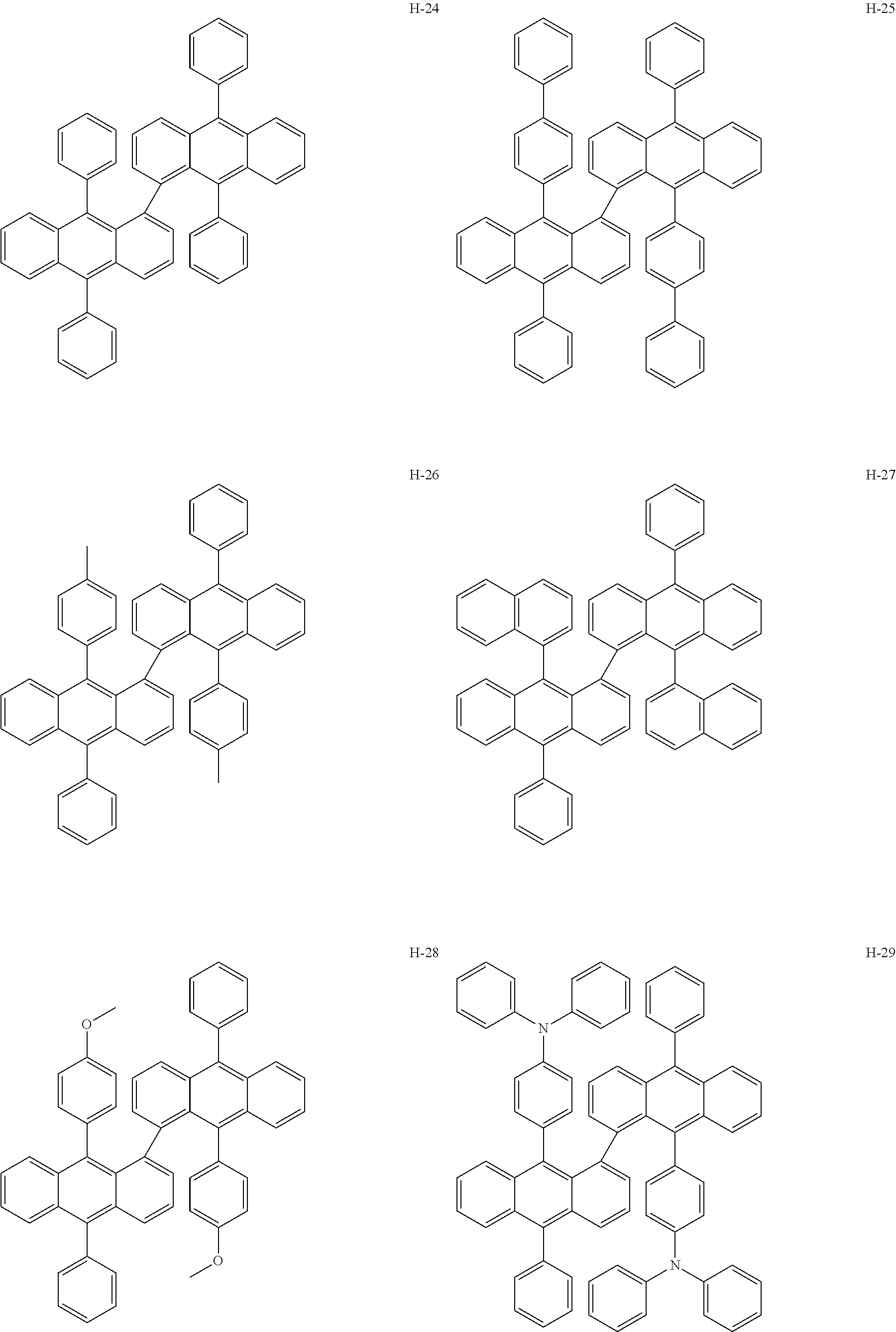

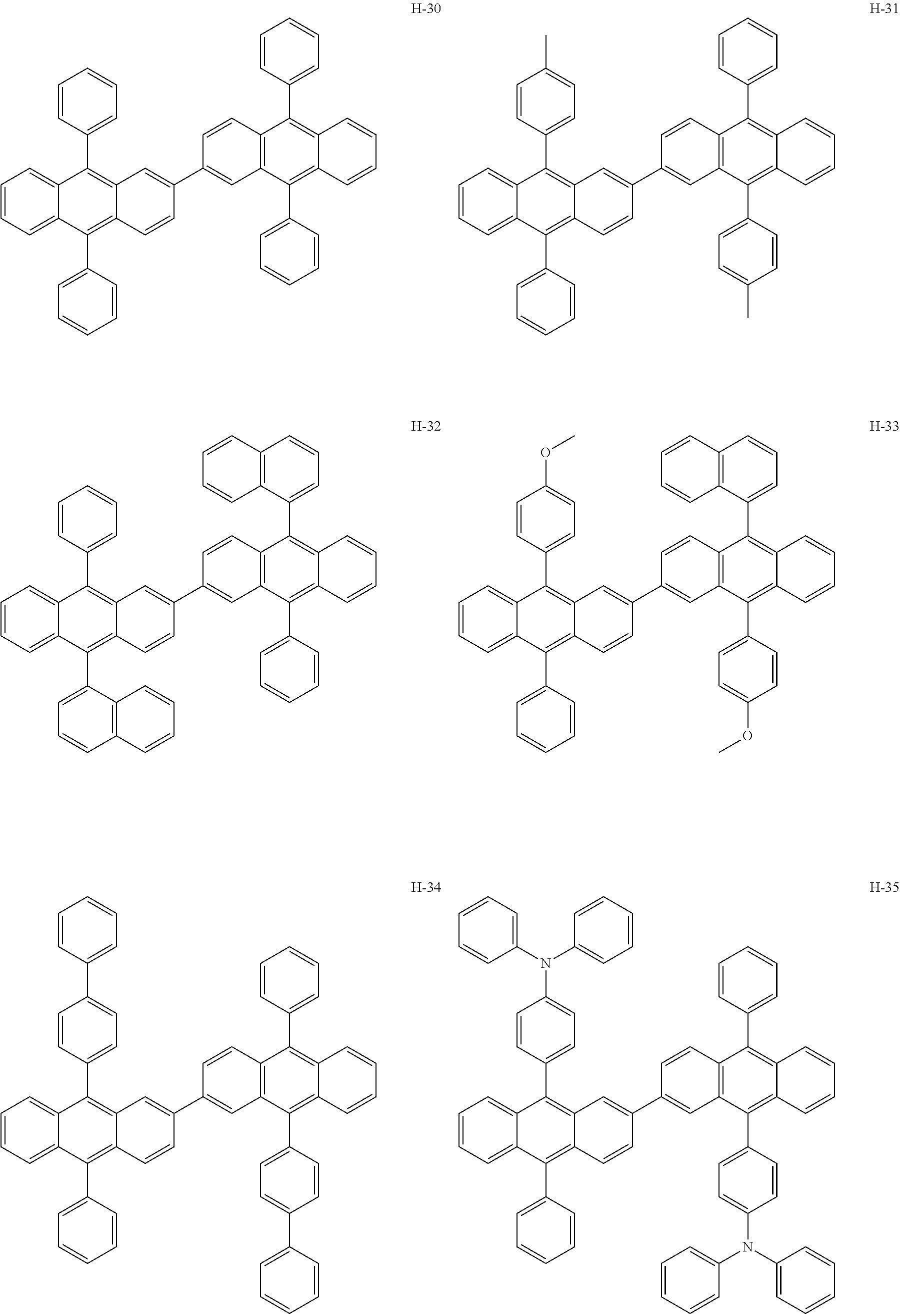

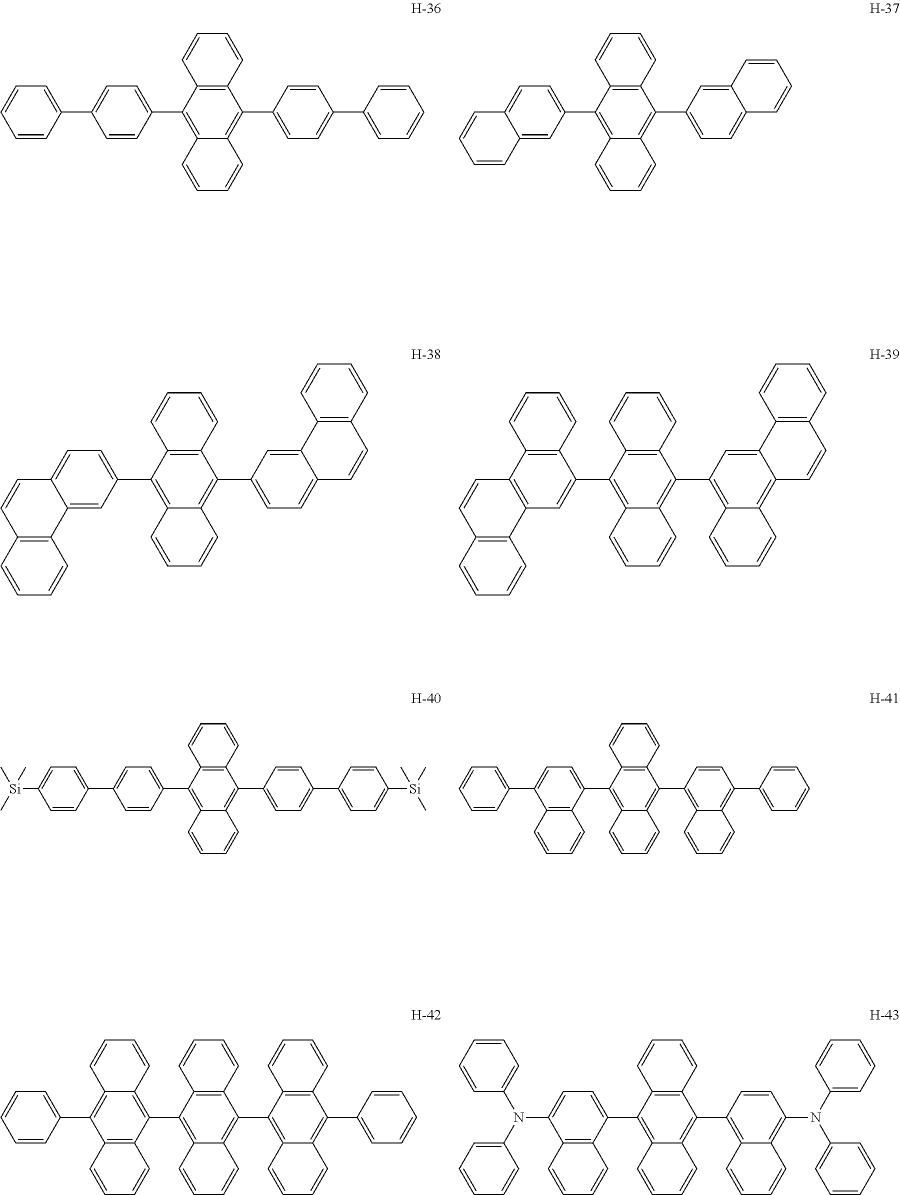

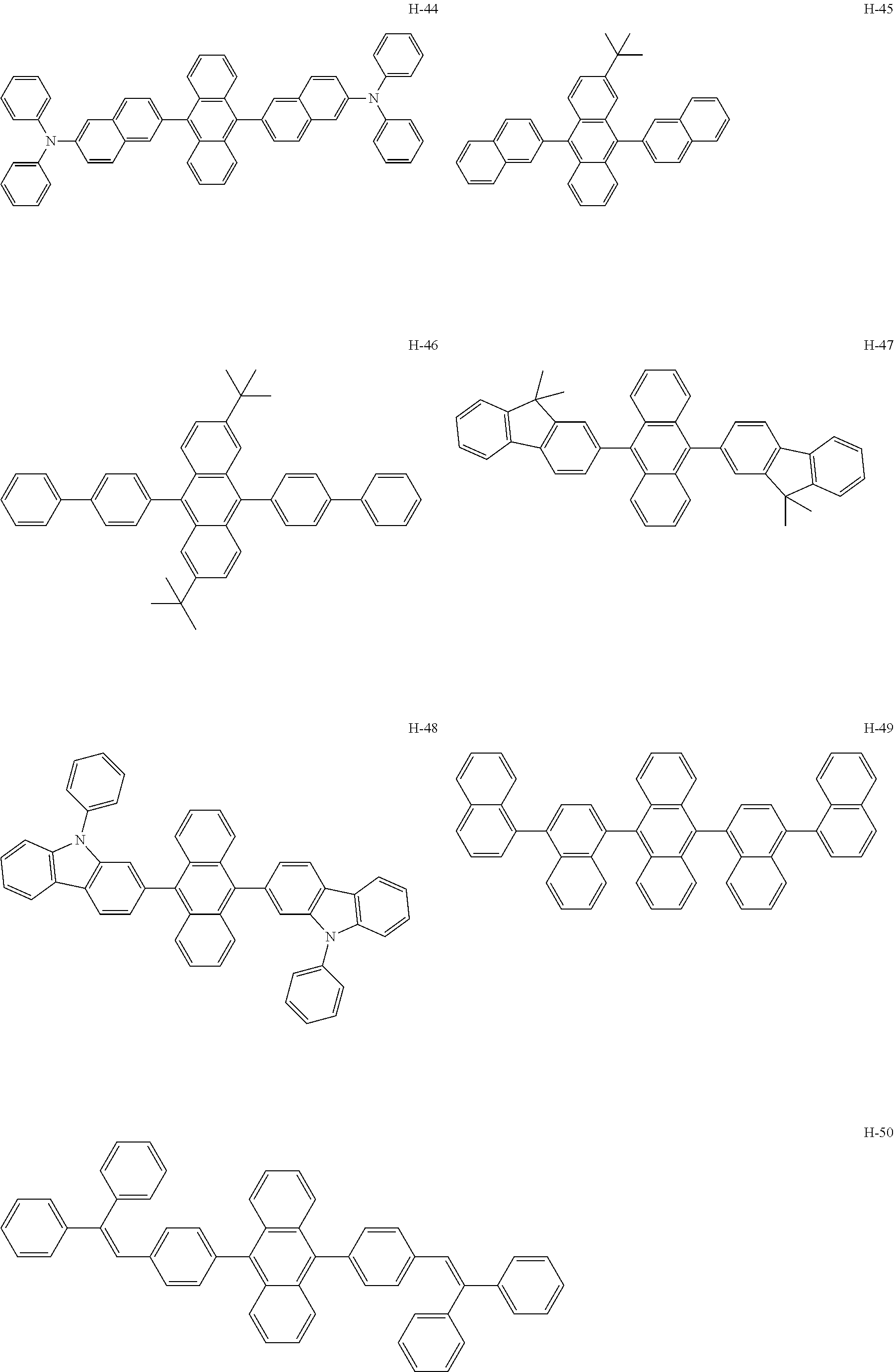

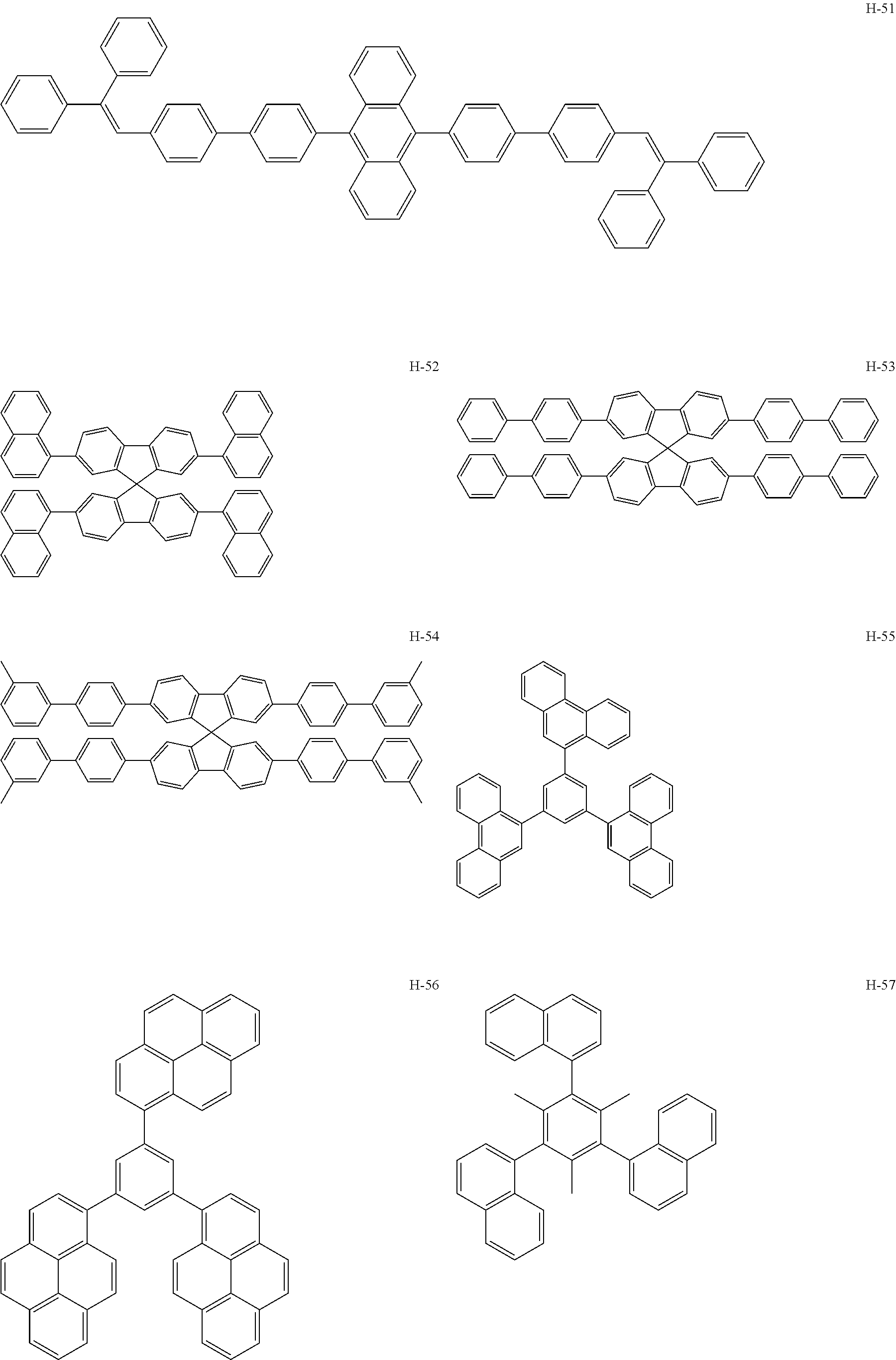

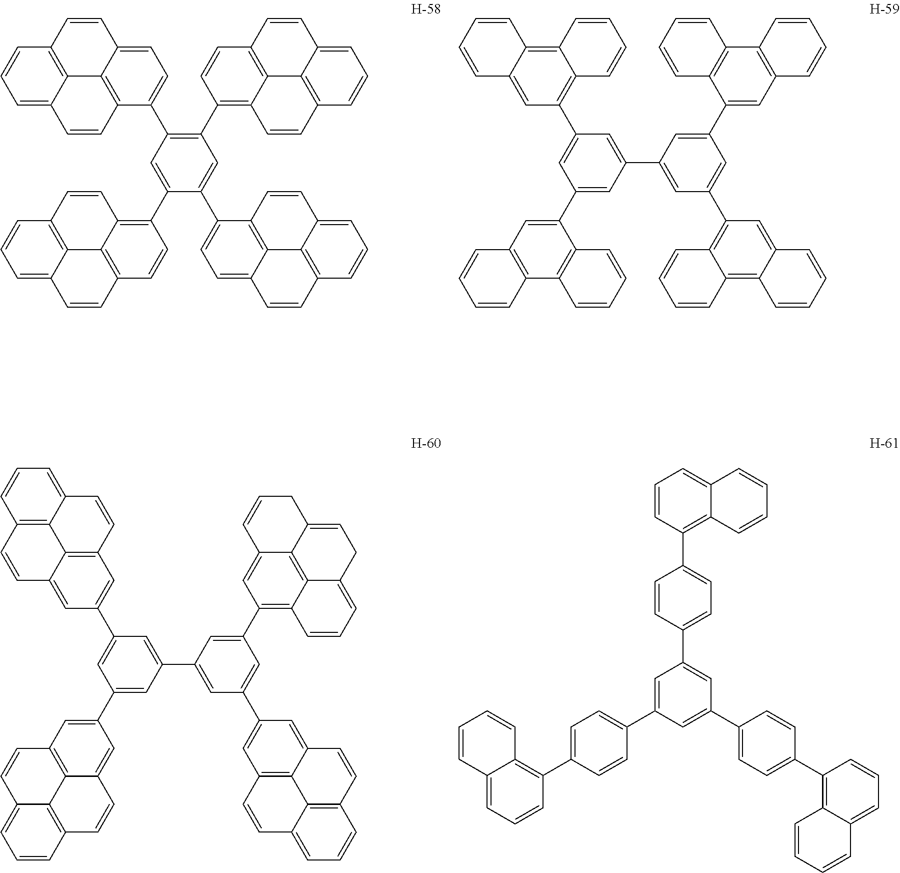

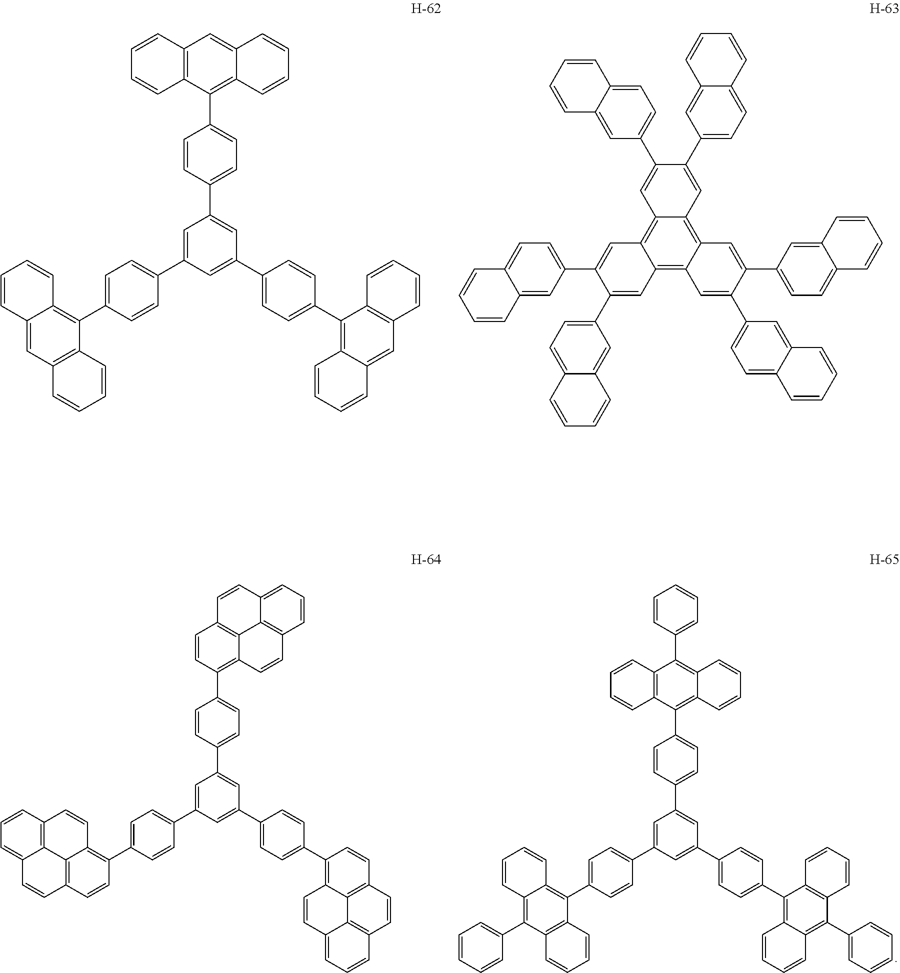

18. The organic light-emitting device as claimed in claim 1, wherein the first compound and the second compound are included in the emission layer.

19. The organic light-emitting device as claimed in claim 1, wherein a weight ratio of the first compound to the second compound is in a range of 1:99 to 20:80.

20. The organic light-emitting device as claimed in claim 1, wherein
the first compound is a dopant, and
the second compound is a host.
